(19) United States
(12) Patent Application Publication
(10) Pub. No.: US 2025/0351322 A1
(43) Pub. Date: Nov. 13, 2025

(54) MEMORY DEVICE AND METHOD OF OPERATING THE SAME

(71) Applicant: TAIWAN SEMICONDUCTOR MANUFACTURING COMPANY, LTD., Hsinchu (TW)

(72) Inventors: Yi-Hsin NIEN, Hsinchu (TW); Chih-Yu LIN, Hsinchu (TW); Hidehiro FUJIWARA, Hsinchu (TW); Yen-Huei CHEN, Hsinchu (TW)

(21) Appl. No.: 19/280,836

(22) Filed: Jul. 25, 2025

Related U.S. Application Data
(63) Continuation of application No. 18/746,931, filed on Jun. 18, 2024.
(60) Provisional application No. 63/617,295, filed on Jan. 3, 2024.

(51) Int. Cl. H10B 10/00; G06F 30/392

(52) U.S. Cl. CPC H10B 10/12; G06F 30/392

(57) ABSTRACT

An integrated circuit chip includes a first and second memory cell array, and a first and second bit line. The first memory cell array has a first width and a first height. Each memory cell in the first memory cell array includes a first number of transistors. The second memory cell array has a second width and a second height. Each memory cell in the second memory cell array includes the first number of transistors. The first bit line overlaps and is coupled to the first memory cell array, and is on a first metal layer above a front-side of a substrate. The second bit line overlaps and is coupled to the second memory cell array, and is on the first metal layer. At least the first width is different from the second width, or the first height is different from the second height.

### PRIORITY CLAIM

The present application is a continuation of U.S. application Ser. No. 18/746,931, filed Jun. 18, 2024, which claims the benefit of U.S. Provisional Application No. 63/617,295, filed Jan. 3, 2024, which is herein incorporated by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory circuit, in accordance with some embodiments.

FIG. 2A is a circuit diagram of a memory circuit, in accordance with some embodiments.

FIG. 2B is a circuit diagram of a memory circuit, in accordance with some embodiments.

FIGS. 3A-3B are corresponding circuit diagrams of corresponding memory cells 300A and 300B usable in FIGS. 1 and 2A-2B, in accordance with some embodiments.

FIGS. 4A-4C are corresponding schematic diagrams of a corresponding memory circuit 400A-400C, in accordance with some embodiments.

FIG. 5A is a corresponding schematic diagram of a corresponding memory circuit 500A, in accordance with some embodiments.

FIG. 5B is a corresponding schematic diagram of a corresponding memory circuit 500B, in accordance with some embodiments.

FIG. 5C is a cross-sectional view of an integrated circuit as intersected by plane A-A′.

FIG. 5D is a cross-sectional view of an integrated circuit as intersected by plane B-B′.

FIG. 5E is a cross-sectional view of an integrated circuit as intersected by plane C-C′.

FIG. 5F is a cross-sectional view of an integrated circuit as intersected by plane D-D′.

FIG. 6 is a corresponding schematic diagram of a corresponding memory circuit 600, in accordance with some embodiments.

FIGS. 7A-7B are corresponding schematic diagrams of a corresponding memory circuit 700A-700B, in accordance with some embodiments.

FIG. 8 is a corresponding schematic diagram of a corresponding memory circuit, in accordance with some embodiments.

FIG. 9 is a corresponding schematic diagram of a corresponding memory circuit, in accordance with some embodiments.

FIG. 10 is a schematic diagram of a memory circuit, in accordance with some embodiments.

FIG. 11 is a schematic diagram of a memory circuit, in accordance with some embodiments.

FIG. 12 is a schematic diagram of a memory circuit, in accordance with some embodiments.

FIG. 13 is a schematic diagram of a memory circuit, in accordance with some embodiments.

FIG. 14 is a schematic diagram of a memory circuit, in accordance with some embodiments.

FIG. 15 is a functional flow chart of a method of manufacturing an integrated circuit, in accordance with some embodiments.

FIG. 16 is a flow chart of a method of manufacturing an integrated circuit, in accordance with some embodiments.

FIG. 17 is a flowchart of a method of generating a layout design of an integrated circuit, in accordance with some embodiments.

FIG. 18 is a schematic view of a system for designing an IC layout design and manufacturing an IC circuit, in accordance with some embodiments.

FIG. 19 is a block diagram of an IC manufacturing system, and an IC manufacturing flow associated therewith, in accordance with at least one embodiment of the present disclosure.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit chip includes a first memory cell array. In some embodiments, the first memory cell array has a first width in a first direction, and a first height in a second direction. In some embodiments, the second direction is different from the first direction.

In some embodiments, the integrated circuit chip further includes a second memory cell array. In some embodiments, the second memory cell array has a second width in the first direction, and a second height in the second direction.

In some embodiments, the integrated circuit chip further includes a first set of bit lines extending in the first direction. In some embodiments, the first set of bit lines is coupled to the first memory cell array. In some embodiments, the first set of bit lines overlaps the first memory cell array.

In some embodiments, the first set of bit lines is on at least a first metal layer above a front-side of a substrate.

In some embodiments, the integrated circuit chip further includes a second set of bit lines extending in the first direction. In some embodiments, the second set of bit lines is coupled to the second memory cell array. In some embodiments, the second set of bit lines overlaps the second memory cell array. In some embodiments, the second set of bit lines is on at least the first metal layer.

In some embodiments, at least the first width is different from the second width, or the first height is different from the second height.

In some embodiments, the integrated circuit chip further includes a first set of word lines extending in the second direction. In some embodiments, the first set of word lines extends in the second direction. In some embodiments, the first set of word lines is coupled to the first memory cell array. In some embodiments, the first set of word lines overlaps the first memory cell array. In some embodiments, the first set of word lines is on at least a second metal layer. In some embodiments, the second metal layer is different from the first metal layer.

In some embodiments, the integrated circuit chip further includes a second set of word lines extending in the second direction.

In some embodiments, the second set of word lines extends in the second direction. In some embodiments, the second set of word lines is coupled to the second memory cell array. In some embodiments, the second set of word lines overlaps the second memory cell array. In some embodiments, the second set of word lines is on at least the second metal layer.

In some embodiments, at least the first width is different from the second width, or the first height is different from the second height. In some embodiments, since at least the first width is different from the second width, or the first height is different from the second height, the first memory cell array and the second memory cell array have different corresponding electrical characteristics.

In some embodiments, by integrated circuit chip including the first memory cell array and the second memory cell array with different corresponding electrical characteristics causes integrated circuit chip to have a more flexible design than other approaches with the same type of cell with the same type of electrical characteristics, thereby resulting in improved performance than other approaches.

In some embodiments, the different corresponding electrical characteristics include one or more of a resistance/capacitance of the first set of bit lines, a resistance/capacitance of the second set of bit lines, a resistance/capacitance of the first set of word lines or a resistance/capacitance of the second set of word bit lines.

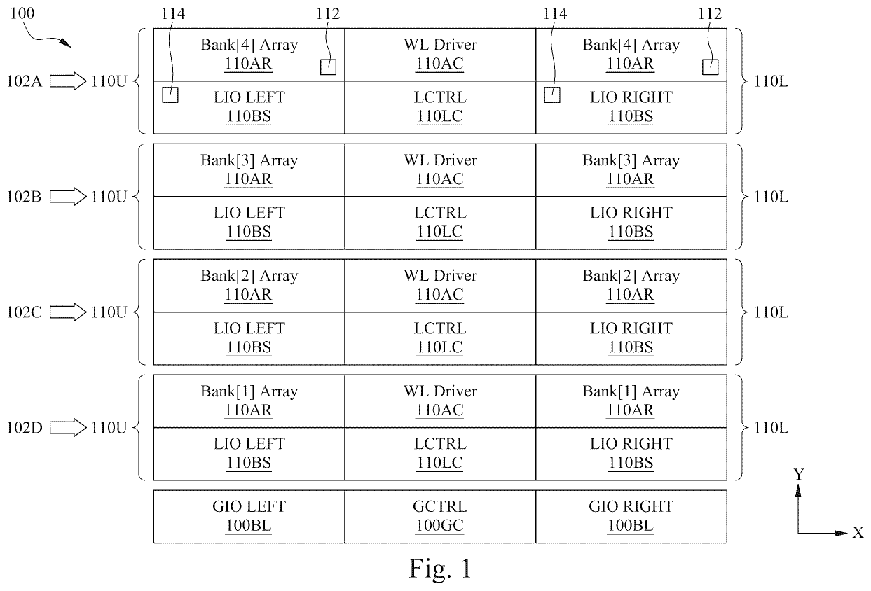

FIG. 1 is a block diagram of a memory circuit 100, in accordance with some embodiments.

FIG. 1 is simplified for the purpose of illustration. In some embodiments, memory circuit 100 includes various elements in addition to those depicted in FIG. 1 or is otherwise arranged to perform the operations discussed below.

Memory circuit 100 is an IC that includes memory partitions 102A-102D, a global control circuit 100GC and global input output (GIO) circuits 100BL.

Each memory partition 102A-102D includes memory banks 110U and 110L adjacent to a word line (WL) driver circuit 110AC and a local control circuit 110LC. Each memory bank 110U and 110L includes a memory cell array 110AR and a local input output (LIO) circuit 110BS.

A memory partition, e.g., a memory partition 102A-102D, is a portion of memory circuit 100 that includes a subset of memory devices (not shown in FIG. 1) and adjacent circuits configured to selectively access the subset of memory devices in program and read operations. In the FIG. 1 embodiment, memory circuit 100 includes a total of four partitions. In some embodiments, memory circuit 100 includes a total number of partitions greater or fewer than four.

GIO circuit 100BL is configured to control access to one or more electrical paths, e.g., bit lines, to each memory device of the corresponding memory bank 110U or 110L of each memory partition 102A-102D, e.g., by generating one or more bit line signals. In some embodiments, GIO circuit 100BL includes a global bit line driver circuit. In some embodiments, GIO circuit 100BL is coupled to each memory bank 110U and 110L by a corresponding global bit line (not shown).

Global control circuit 100GC is configured to control some or all of program and read operations on each memory partition 102A-102D, e.g., by generating and/or outputting one or more control and/or enable signals.

In some embodiments, global control circuit 100GC includes one or more analog circuits configured to interface with memory partitions 102A-102D, cause data to be programmed in one or more memory devices, and/or use data received from one or more memory devices in one or more circuit operations. In some embodiments, global control circuit 100GC includes one or more global address decoder or pre-decoder circuits configured to output one or more address signals to the WL driver circuit 110AC of each memory partition 102A-102D.

Each WL driver circuit 110AC is configured to generate word line signals on corresponding word lines WL. In some embodiments, each WL driver circuit 110AC is configured to output word line signals on corresponding word lines WL to the adjacent memory banks 110U and 110L of the corresponding memory partition 102A-102D.

Each local control circuit 110LC is an electronic circuit configured to receive one or more address signals. Each local control circuit 110LC is configured to generate signals corresponding to adjacent subsets of memory devices identified by the one or more address signals. In some embodiments, the adjacent subsets of memory devices correspond to columns of memory devices. In some embodiments, each local control circuit 110LC is configured to generate each signal as a complementary pair of signals. In some embodiments, each local control circuit 110LC is configured to output the signals to corresponding word line driver circuits within the adjacent WL driver circuit 110AC of the corresponding memory partition 102A-102D. In some embodiments, the local control circuit 110LC includes a bank decoder circuit.

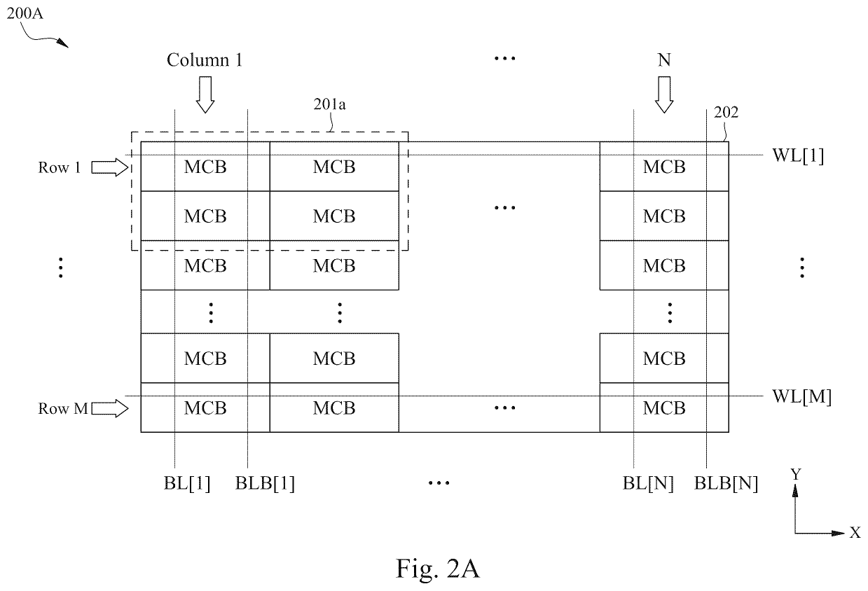

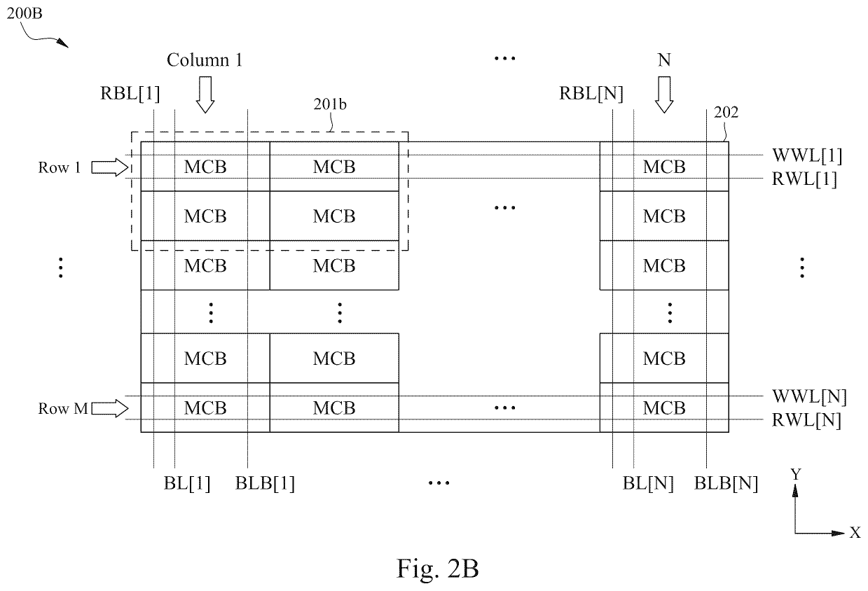

Each LIO circuit 110BS is configured to selectively access one or more bit lines (shown in FIGS. 2A-2B) coupled to adjacent subsets of memory devices of the corresponding memory cell array 110AR responsive to GIO circuit 100BL, e.g., based on one or more BL control signals. In some embodiments, the adjacent subsets of memory devices correspond to rows of memory devices. In some embodiments, the LIO circuit 110BS includes a bit line selection circuit.

Each LIO circuit 110BS includes one or more circuits 114. For ease of illustration, circuit 114 is not shown in memory bank 110U and 110L of memory partitions 102B, 102C and 102D. In some embodiments, each circuit 114 includes at least a sense amplifier circuit. In some embodiments, during a read operation, the sense amplifier circuit is configured to read data from at least one memory cell 112 in a corresponding column of memory cells in the corresponding memory cell array 110AR, in accordance with some embodiments. In some embodiments, each circuit 114 in LIO circuit 110BS is coupled to a corresponding column of memory devices 112 in memory cell array 110AR.

Each memory bank 110U and 110L includes the corresponding memory cell array 110AR including memory cells or memory devices 112 configured to be accessed in program and read operations by the adjacent LIO circuit 110BS and the adjacent WL driver circuit 110AC.

Each memory cell array 110AR includes an array of memory devices 112 having N rows and M columns, where M and N are positive integers. The rows of cells in memory cell array 102 are arranged in a first direction X. The columns of cells in memory cell array 102 are arranged in a second direction Y. The second direction Y is different from the first direction X. In some embodiments, the second direction Y is perpendicular to the first direction X. In some embodiments, each memory cell array 110AR is divided into an upper region and a lower region (not shown). In some embodiments, each column of memory devices 112 in memory cell array 110AR is coupled to a corresponding circuit 114 in LIO circuit 110BS.

Memory device 112 is shown in memory bank 110U and 110L of memory partition 102A. For ease of illustration, memory device 112 is not shown in memory bank 110U and 110L of memory partitions 102B, 102C and 102D.

Memory device 112 is an electrical, electromechanical, electromagnetic, or other device configured to store bit data represented by logical states. At least one logical state of memory device 112 is capable of being programmed in a write operation and detected in a read operation. In some embodiments, a logical state corresponds to a voltage level of an electrical charge stored in a given memory device 112. In some embodiments, a logical state corresponds to a physical property, e.g., a voltage, a current, a resistance or a magnetic orientation, of a component of a given memory device 112.

In some embodiments, memory device 112 includes one or more single port (SP) static random access memory (SRAM) cells. In some embodiments, memory device 112 includes one or more dual port (DP) SRAM cells. In some embodiments, memory device 112 includes one or more multi-port SRAM cells. Different types of memory cells in memory device 112 are within the contemplated scope of the present disclosure. In some embodiments, memory device 112 includes one or more dynamic random access memory (DRAM) cells. In some embodiments, memory device 112 includes one or more one-time programmable (OTP) memory devices such as electronic fuse (eFuse) or anti-fuse devices, flash memory devices, random-access memory (RAM) devices, resistive RAM devices, ferroelectric RAM devices, magneto-resistive RAM devices, erasable programmable read only memory (EPROM) devices, electrically erasable programmable read only memory (EEPROM) devices, or the like. In some embodiments, memory device 112 is an OTP memory device including one or more OTP memory cells.

Other configurations of memory circuit 100 are within the scope of the present disclosure.

FIG. 2A is a circuit diagram of a memory circuit 200A, in accordance with some embodiments.

Memory circuit 200A is an embodiment of memory cell array 110AR of FIG. 1, and similar detailed description is therefore omitted.

Components that are the same or similar to those in one or more of FIGS. 1-19 are given the same reference numbers, and detailed description thereof is thus omitted.

Memory circuit 200A comprises a memory cell array 202 having M rows and N columns of memory cells MCB, where N is a positive integer corresponding to the number of columns in memory cell array 202 and M is a positive integer corresponding to the number of rows in memory cell array 202. The rows of cells in memory cell array 202 are arranged in the first direction X. The columns of cells in memory cell array 202 are arranged in the second direction Y.

In some embodiments, each memory cell MCB in memory cell array 202 is configured to store a bit of data. In some embodiments, memory circuit 200A is logic based memory.

The number of rows M in memory cell array 202 is equal to or greater than 1. The number of columns N in memory cell array 202 is equal to or greater than 1. Different types of memory cells MCB in memory cell array 202 are within the contemplated scope of the present disclosure.

Memory circuit 200A further comprises N bit lines BL[1], . . . BL[N] (collectively referred to as “bit line BL”). Each column 1, . . . , N in memory cell array 202 is overlapped and coupled to a corresponding bit line BL[1], . . . , BL[N]. Each bit line BL extends in the second direction Y and over a column of cells (e.g., column 1, . . . , N).

Memory circuit 200A further comprises N bit line bars BLB[1], . . . BLB[N] (collectively referred to as “bit line bar BLB”). Each column 1, . . . , N in memory cell array 202 is overlapped and coupled to a corresponding bit line bar BLB[1], . . . , BLB[N]. Each bit line bar BLB extends in the second direction Y and over a column of cells (e.g., column 1, . . . , N).

Memory circuit 200A further comprises M word lines WL[1], . . . WL[M] (collectively referred to as “word line WL”). Each row 1, . . . , M in memory cell array 202 is overlapped and coupled to a corresponding word line WL[1], . . . , WL[M]. Each word line WL extends in the first direction X and over a row of cells (e.g., row 1, . . . , M).

Memory circuit 200A includes a region 201a. Region 201a includes 2 rows of memory cells MCB, and 2 columns of memory cells MCB. Region 201a includes rows 1 and 2 of memory circuit 200A, and columns 1 and 2 of memory circuit 200A. Other numbers of rows or columns of region 201a are within the scope of the present disclosure. In some embodiments, region 201a is located in other rows or columns of memory circuit 200A.

Other configurations of memory circuit 200A are within the scope of the present disclosure. In some embodiments, one or more of bit lines BL, bit line bars BLB or word lines WL are not included in memory circuit 200A. In some embodiments, one or more of bit lines BL, bit line bars BLB or word lines WL are replaced with a corresponding source line SL. In some embodiments, one or more source lines SL is added.

FIG. 2B is a circuit diagram of a memory circuit 200B, in accordance with some embodiments.

Memory circuit 200B is a variation of memory circuit 200A of FIG. 2A, and similar detailed description is therefore omitted. In comparison with memory circuit 200A of FIG. 2A, word lines WL of FIG. 2A are replaced by write word lines WWL of FIG. 2B, and similar detailed description is therefore omitted. In comparison with memory circuit 200A of FIG. 2A, the M word lines WL[1], . . . WL[M] of FIG. 2A are replaced by M corresponding write word lines WWL[1], . . . WWL[M] (collectively referred to as “write word line WWL”) of FIG. 2B, and similar detailed description is therefore omitted.

In comparison with memory circuit 200A of FIG. 2A, memory circuit 200B further comprises N read bit lines RBL[1], . . . RBL[N] and M read word lines RWL[1], . . . RWL[M], and similar detailed description is therefore omitted.

Memory circuit 200B is an embodiment of memory cell array 110AR of FIG. 1, and similar detailed description is therefore omitted.

Memory circuit 200A comprises memory cell array 202, bit line BL, bit line bar BLB, and write word line WWL.

Memory circuit 200B further comprises N read bit lines RBL[1], . . . RBL[N] (collectively referred to as “read bit line RBL”). Each column 1, . . . , N in memory cell array 202 is overlapped and coupled to a corresponding read bit line RBL[1], . . . , RBL[N]. Each read bit line RBL extends in the second direction Y and over a column of cells (e.g., column 1, . . . , N).

Memory circuit 200B further comprises M read word lines RWL[1], . . . RWL[M] (collectively referred to as “read word line RWL”). Each row 1, . . . , M in memory cell array 202 is overlapped and coupled to a corresponding read word line RWL[1], . . . , RWL[M]. Each read word line RWL extends in the first direction X and over a row of cells (e.g., row 1, . . . , M).

Memory circuit 200B includes a region 201b. Region 201b includes 2 rows of memory cells MCB, and 2 columns of memory cells MCB. Region 201b includes rows 1 and 2 of memory circuit 200B, and columns 1 and 2 of memory circuit 200B. Other numbers of rows or columns of region 201b are within the scope of the present disclosure. In some embodiments, region 201b is located in other rows or columns of memory circuit 200B.

Other configurations of memory circuit 200B are within the scope of the present disclosure. In some embodiments, one or more of bit lines BL, bit line bars BLB, read bit lines RBL, write word lines WWL or read word lines RWL are not included in memory circuit 200B. In some embodiments, one or more of bit lines BL, bit line bars BLB, read bit lines RBL, write word lines WWL or read word lines RWL are replaced with a corresponding source line SL. In some embodiments, one or more source lines SL is added.

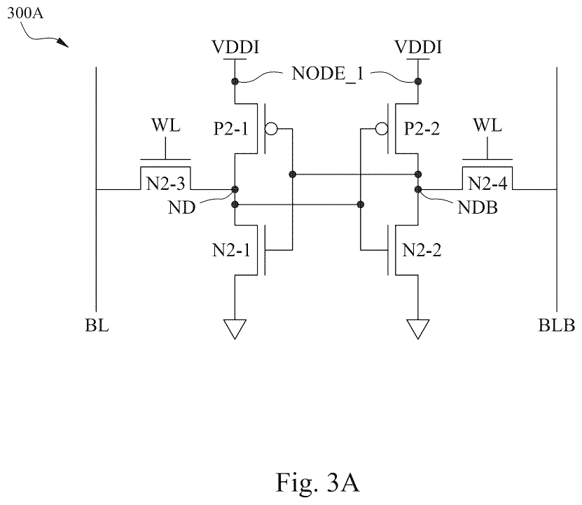

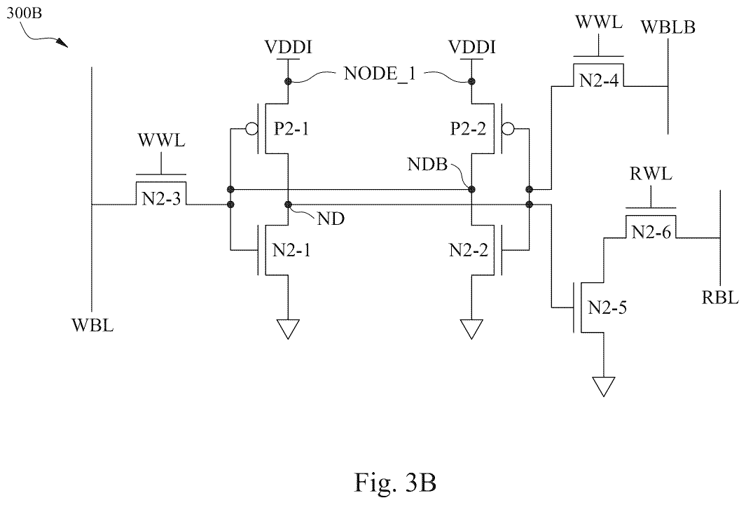

FIGS. 3A-3B are corresponding circuit diagrams of corresponding memory cells 300A and 300B usable in FIGS. 1 and 2A-2B, in accordance with some embodiments.

FIG. 3A is a circuit diagram of a memory cell 300A usable in FIGS. 1 and 2A-2B, in accordance with some embodiments.

At least one of memory cell 300A or 300B is usable as one or more memory cells MCB in at least one of memory cell array 110AR of FIG. 1 or memory device 112 of FIG. 1.

At least one of memory cell 300A or 300B is usable as one or more memory cells MCB in at least one of memory circuit 200A of FIG. 2A or memory circuit 200A of FIG. 2B.

Memory cell 300A is a six transistor (6T) single port (SP) SRAM memory cell used for illustration. In some embodiments, memory cell 300A employs a number of transistors other than eight. Other types of memory are within the scope of various embodiments.

Memory cell 300A comprises two P field effect transistors (PFET) transistors P2-1 and P2-2, and four NFET transistors N2-1, N2-2, N2-3, and N2-4. PFET transistors P2-1 and P2-2, and NFET transistors N2-1 and N2-2 form a cross latch or a pair of cross-coupled inverters. For example, PFET transistor P2-1 and NFET transistor N2-1 form a first inverter, while PFET transistor P2-2 and NFET transistor N2-2 form a second inverter.

A source terminal of each of PFET transistors P2-1 and P2-2 is configured as a voltage supply node NODE_1. Each voltage supply node NODE_1 is coupled to a first voltage supply VDDI.

Each of a drain terminal of PFET transistor P2-1, a drain terminal of NFET transistor N2-1, a gate terminal of PFET transistor P2-2, a gate terminal of NFET transistor N2-2, and a source terminal of NFET transistor N2-3 are coupled together, and are configured as a storage node ND.

Each of a drain terminal of PFET transistor P2-2, a drain terminal of NFET transistor N2-2, a gate terminal of PFET transistor P2-1, a gate terminal of NFET transistor N2-1, and a source terminal of NFET transistor N2-4 are coupled together, and are configured as a storage node NDB.

A source terminal of each of NFET transistors N2-1 and N2-2 is configured as a supply reference voltage node (not labelled) having a supply reference voltage VSS. The source terminal of each of NFET transistors N2-1 and N2-2 is also coupled to reference voltage supply VSS.

A word line WL is coupled with a gate terminal of each of NFET transistors N2-3 and N2-4.

Word line WL is also called a write control line because NFET transistors N2-3 and N2-4 are configured to be controlled by a signal on word line WL in order to transfer data between bit lines BL, BLB and corresponding nodes ND, NDB.

A drain terminal of NFET transistor N2-3 is coupled to a bit line BL. A drain terminal of NFET transistor N2-4 is coupled to a bit line BLB.

Bit lines BL and bit line bars BLB are configured as both data input and output for memory cell 200A. In some embodiments, in a write operation, applying a logical value to a bit line BL and the opposite logical value to the bit line bar BLB enables writing the logical values on the bit lines and bit line bars to memory cell 200A. Each of bit line BL and bit line bar BLB is called a data line because the data carried on bit line BL and bit line bar BLB are written to and read from corresponding nodes ND and NDB.

Other configurations of memory cell 300A are within the scope of the present disclosure.

FIG. 3B is a circuit diagram of a memory cell 300B usable in FIGS. 1 and 2A-2B, in accordance with some embodiments.

Memory cell 300B is a variation of memory cell 300A of FIG. 3A, and similar detailed description is therefore omitted. In comparison with memory cell 300A of FIG. 3A, memory cell 300B further includes NFET transistors N2-5 and N2-6, and similar detailed description is therefore omitted.

Memory cell 300B is an eight transistor (8T) one read/one write (1R/1 W) two port (2P) SRAM memory cell used for illustration. In some embodiments, memory cell 300B employs a number of transistors other than eight. Other types of memory cells are within the scope of various embodiments.

In comparison with memory cell 300A of FIG. 3A, write word line WWL replaces word line WL, and similar detailed description is therefore omitted.

Memory cell 300B comprises PFET transistors P2-1 and P2-2, and NFET transistors N2-1, N2-2, N2-3, N2-4, N2-5 and N2-6.

Each of a drain terminal of PFET transistor P2-1, a drain terminal of NFET transistor N2-1, a gate terminal of PFET transistor P2-2, a gate terminal of NFET transistor N2-2, a source terminal of NFET transistor N2-4 and a gate terminal of NFET transistor N2-5 are coupled together, and are configured as a storage node ND.

Each of a drain terminal of PFET transistor P2-2, a drain terminal of NFET transistor N2-2, a gate terminal of PFET transistor P2-1, a gate terminal of NFET transistor N2-1, and a source terminal of NFET transistor N2-3 are coupled together, and are configured as a storage node NDB.

A drain terminal of NFET transistor N2-3 is coupled to a write bit line WBL. A drain terminal of NFET transistor N2-4 is coupled to a write bit line bar WBLB.

A source terminal of NFET transistor N2-5 is configured as a supply reference voltage node (not labelled) having a supply reference voltage VSS. The source terminal of NFET transistor N2-5 is also coupled to reference voltage supply VSS.

Each of a drain terminal of NFET transistor N2-5 and a source terminal of NFET transistor N2-6 are coupled together.

A drain terminal of NFET transistor N2-6 is coupled to a read bit line RBL.

A write word line WWL is coupled with a gate terminal of each of NFET transistors N2-3 and N2-4. Write word line WWL is also called a write control line because NFET transistors N2-3 and N2-4 are configured to be controlled by a signal on write word line WWL in order to transfer data between write bit lines WBL, WBLB and corresponding nodes ND, NDB.

A read word line RWL is coupled with a gate terminal of NFET transistor N2-6. Read word line RWL is also called a read control line because NFET transistor N2-6 is configured to be controlled by a signal on read word line RWL in order to transfer data to read bit line RBL.

In some embodiments, NFET transistor N2-5 is referred to as a read pull-down (RPD) transistor. In some embodiments, NFET transistor N2-6 is referred to as a read pass gate (RPG) transistor.

Other configurations of memory cell 300B are within the scope of the present disclosure.

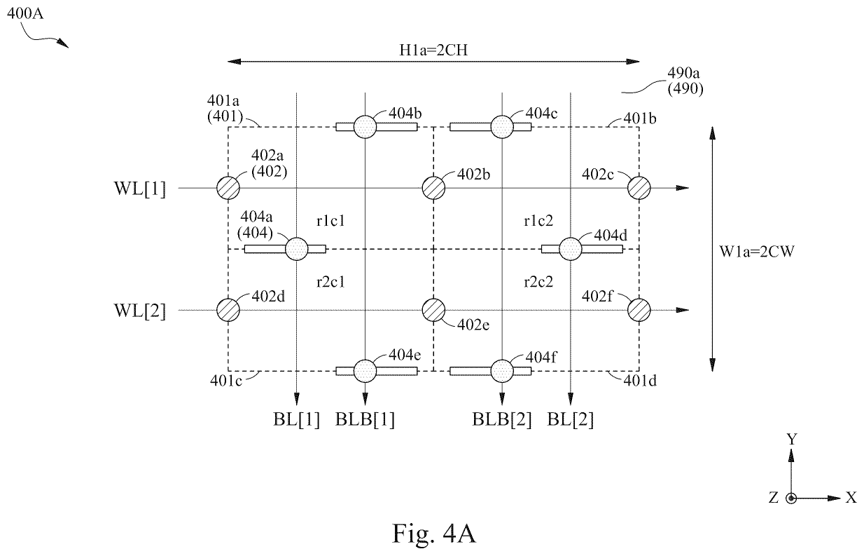

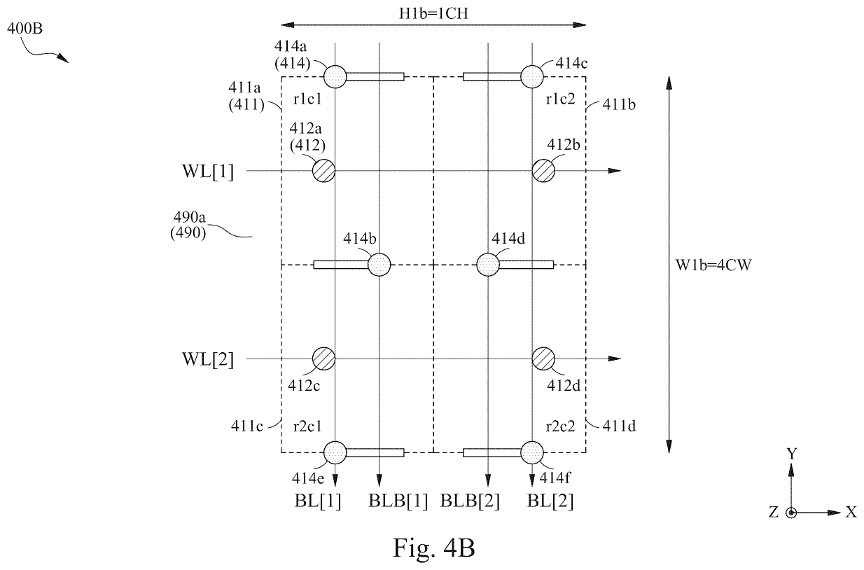

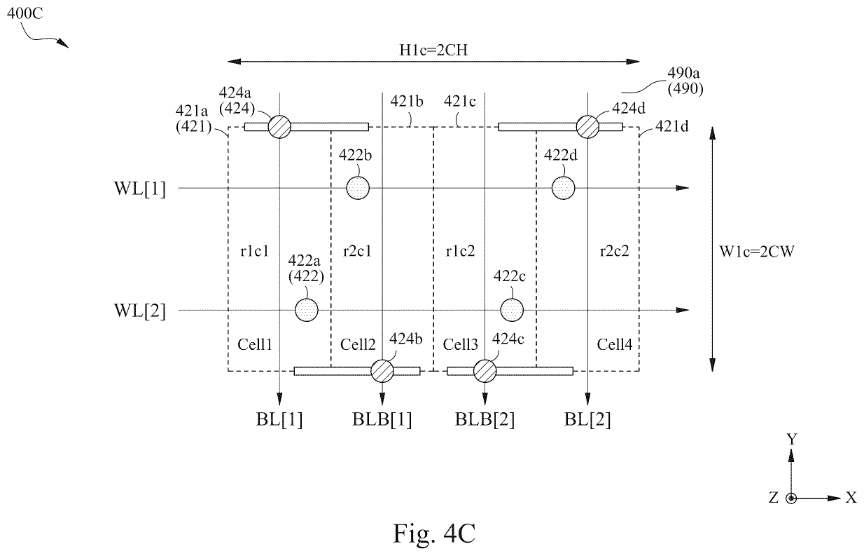

FIGS. 4A-4C are corresponding schematic diagrams of a corresponding memory circuit 400A-400C, in accordance with some embodiments.

FIG. 4A is a schematic diagram of a memory circuit 400A, in accordance with some embodiments.

Memory circuit 400A relates to memory cell array 202 of FIG. 2A. Memory circuit 400A is an embodiment of region 201a of memory circuit 200A of FIG. 2A, and similar detailed description is therefore omitted. In some embodiments, memory circuit 400A is an embodiment of regions of memory circuit 200A other than region 201a of memory circuit 200A of FIG. 2A.

Memory circuit 400A comprises a memory cell array 401. Memory circuit 400A is a schematic representation of two adjacent columns and two adjacent rows of a memory cell array 401. In some embodiments, memory circuit 400 is a schematic representation of columns 1 and 2 of memory cell array 202 of FIG. 2A, and rows 1 and 2 of memory cell array 202 of FIG. 2A, and similar detailed description is therefore omitted. In some embodiments, memory circuit 400 is a schematic representation of other columns or other rows of memory cell array 202 of FIG. 2A rather than columns 1 and 2 or rows 1 and 2 of memory cell array 202 of FIG. 2A, and similar detailed description is therefore omitted.

Memory circuits 400A-400C is manufactured by a corresponding layout design similar to memory circuits 400A-400C. For brevity FIGS. 4A, 4B, 4C, 5A-5B, 6, 7A, 7B, 8, 9, 10, 11, 12, 13, 14 and 15 are described as corresponding integrated circuit 400A, 400B, 400C, 500A-500B, 600, 700A, 700B, 800, 900, 1000, 1100, 1200, 1300, 1400 and 1500, but in some embodiments, each of FIGS. 4A, 4B, 4C, 5A-5B, 6, 7A, 7B, 8, 9, 10, 11, 12, 13, 14 and 15 is also a corresponding layout design, and each structural element of integrated circuit 400A, 400B, 400C, 500, 600, 700A, 700B, 800, 900, 1000, 1100, 1200, 1300, 1400 and 1500 is a corresponding layout pattern, and structural relationships including alignment, lengths and widths, as well as configurations and layers of a corresponding layout design of integrated circuit 400A, 400B, 400C, 500A-500B, 600, 700A, 700B, 800, 900, 1000, 1100, 1200, 1300, 1400 and 1500 are similar to the structural relationships and configurations and layers of integrated circuit 400A, 400B, 400C, 500A-500B, 600, 700A, 700B, 800, 900, 1000, 1100, 1200, 1300, 1400 and 1500, and similar detailed description will not be described for brevity.

Memory cell array 401 is similar to memory cell array 202 of FIG. 2A, and similar detailed description is therefore omitted.

Memory cell array 401 comprises memory cells 401a, 401b, 401c and 401d.

Memory cell 401a is in row 1 and column 1 of memory cell array 401, and is designated in FIG. 4A as “r1c1.” Memory cell 401b is in row 1 and column 2 of memory cell array 401, and is designated in FIG. 4A as “r1c2.” Memory cell 401c is in row 2 and column 1 of memory cell array 401, and is designated in FIG. 4A as “r2c1.” Memory cell 401d is in row 2 and column 2 of memory cell array 401, and is designated in FIG. 4A as “r2c2.”

Memory cell array 401 is shown as a 2×2 memory cell array in FIG. 4A. Other numbers of rows and columns are within the scope of the present disclosure.

Memory cell array 401 has a height Hla in the first direction X. In some embodiments, the height Hla is equal to 2CH, where CH is a scaled cell height in the first direction X of at least one of memory cell 401a, 401b, 401c, or 401d in memory cell array 401. In some embodiments, the cell height of memory cells in one of memory cell array 401, 411, 421, 701 or 721 or memory circuit 500A-500B, 600, 800 or 900 is scaled (e.g., scaled cell height) with a corresponding cell height of another memory cell in memory cell array 401, 411, 421, 701 or 721 or memory circuit 500A-500B, 600, 800 or 900.

Memory cell array 401 has a width W1a in the second direction Y. In some embodiments, the width W1a is equal to 2CW, where CW is a scaled cell width in the second direction Y of at least one of memory cell 401a, 401b, 401c, or 401d in memory cell array 401. In some embodiments, the cell width of memory cells in one of memory cell array 401, 411, 421, 701 or 721 or memory circuit 500A-500B, 600, 800 or 900 is scaled (e.g., scaled cell width) with a corresponding cell width of another memory cell in memory cell array 401, 411, 421, 701 or 721 or memory circuit 500A-500B, 600, 800 or 900.

In some embodiments, memory cell array 401 has a width in the second direction Y equal to 2 contacted polysilicon pitches (e.g., 2CPP).

In some embodiments, memory cell array 401 has an aspect ratio ARla that is equal to 1:1. (e.g., W1a/H1a).

Memory circuit 400A further comprises bit lines BL[1] and BL[2] (collectively referred to as a “set of bit lines BL”), bit line bars BLB[1] and BLB[2] (collectively referred to as a “set of bit line bars BLB”) and word lines WL[1] and WL[2] (collectively referred to as a “set of word lines WL”).

In some embodiments, memory cells 401a, 401b, 401c and 401d are similar to corresponding memory cells MCB in the same corresponding rows and same corresponding columns of region 201a of FIG. 2A, and similar detailed description is therefore omitted. In some embodiments, each of memory cells 401a, 401b, 401c and 401d is memory cell 300A of FIG. 3A, and similar detailed description is therefore omitted.

In some embodiments, bit lines BL[1] and BL[2] are similar to corresponding bit lines BL[1] and BL[2] of FIG. 2A, and similar detailed description is therefore omitted.

In some embodiments, bit line bars BLB[1] and BLB[2] are similar to corresponding bit line bars BLB[1] and BLB[2] of FIG. 2A, and similar detailed description is therefore omitted.

In some embodiments, word lines WL[1] and WL[2] are similar to corresponding word lines WL[1] and WL[2] of FIG. 2A, and similar detailed description is therefore omitted.

The set of bit lines BL and the set of bit line bars BLB extend in the second direction Y.

Bit line BL[1] and bit line bar BLB[1] overlap memory cells 401a and 401c. Bit line BL[1] is electrically coupled to memory cells 401a and 401c by a via 404a. Bit line bar BLB[1] is electrically coupled to memory cell 401a by a via 404b and to memory cell 401c by a via 404e.

Bit line BL[2] and bit line bar BLB[2] overlap memory cells 401b and 401d. Bit line BL[2] is electrically coupled to memory cells 401b and 401d by a via 404d. Bit line bar BLB[2] is electrically coupled to memory cell 401b by a via 404c and to memory cell 401d by a via 404f.

In some embodiments, the set of bit lines BL is in a metal two (M2) layer of at least one of memory circuit 400A, 400B, 400C, 700A or 700B. In some embodiments, the set of bit lines BL is in a metal one (M1) layer of at least one of memory circuit 400A, 400B, 400C, 700A or 700B. Other metal layers for the set of bit lines BL are within the scope of the present disclosure.

In some embodiments, the set of bit line bars BLB is in the M2 layer of at least one of memory circuit 400A, 400B, 400C, 700A or 700B. In some embodiments, the set of bit line bars BLB is in the M1 layer of at least one of memory circuit 400A, 400B, 400C, 700A or 700B. Other metal layers for the set of bit line bars BLB are within the scope of the present disclosure.

Other configurations, arrangements on other metal layers or quantities of bit lines in the set of bit lines BL are within the scope of the present disclosure.

Other configurations, arrangements on other metal layers or quantities of bit line bars in the set of bit line bars BLB are within the scope of the present disclosure.

The set of word lines WL extend in the first direction X.

Word line WL[1] overlaps memory cells 401a and 401b. Word line WL[1] is electrically coupled to memory cell 401a by vias 402a and 402b. Word line WL[1] is electrically coupled to memory cell 401b by vias 402b and 402c.

Word line WL[2] overlaps memory cells 401c and 401d. Word line WL[2] is electrically coupled to memory cell 401c by vias 402d and 402e. Word line WL[2] is electrically coupled to memory cell 401d by vias 402e and 402f.

In some embodiments, the set of word lines WL is in an M1 layer of at least one of memory circuit 400A, 400B, 400C, 700A or 700B. In some embodiments, the set of word lines WL is in a metal zero (M0) layer of at least one of memory circuit 400A, 400B, 400C, 700A or 700B. In some embodiments, the set of word lines WL is in a M2 layer of at least one of memory circuit 400A, 400B, 400C, 700A or 700B. Other metal layers for the set of word lines WL are within the scope of the present disclosure.

In some embodiments, the set of word lines WL is in a polysilicon (POLY) layer at least one of memory circuit 400A, 400B, 400C, 700A or 700B.

In some embodiments, the POLY layer is below the M0 layer and M1 layer. In some embodiments, the M0 layer is below the M1 layer and M2 layer. In some embodiments, the M1 layer is below the M2 layer. In some embodiments, the term “layer(s)” and the term “level(s)” are used interchangeably.

Other configurations, arrangements on other metal layers or quantities of word lines in the set of word lines WL are within the scope of the present disclosure.

Memory circuit 400A further comprises one or more of vias 402a, 402b, 402c, 402d, 402e or 402f (collectively referred to as a “set of vias 402”).

In some embodiments, the set of vias 402 is manufactured by a corresponding set of via patterns (not shown) of a corresponding layout design of memory circuit 400A-400C or 700A-700B.

In some embodiments, vias 402a, 402b, 402c, 402d of the set of vias 402 are manufactured by corresponding via patterns (not shown) of the set of via patterns (not shown) of a corresponding layout design of memory circuit 400A-400C or 700A-700B.

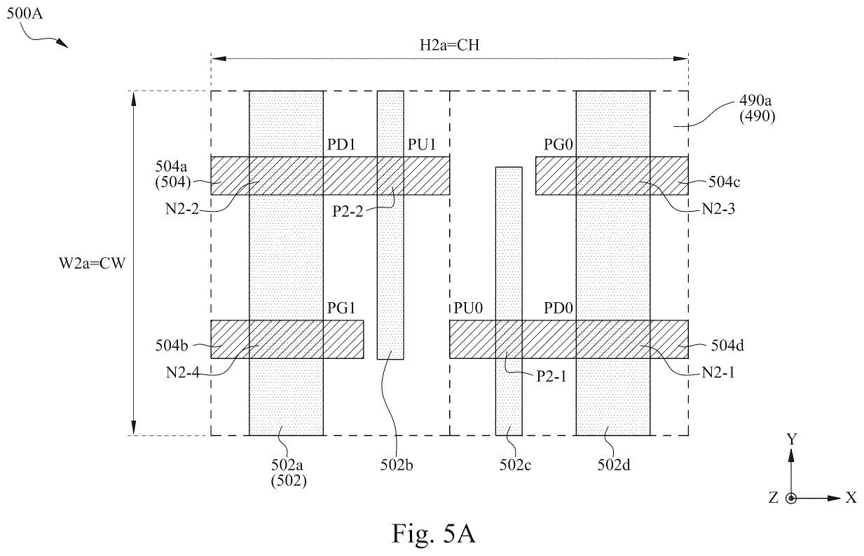

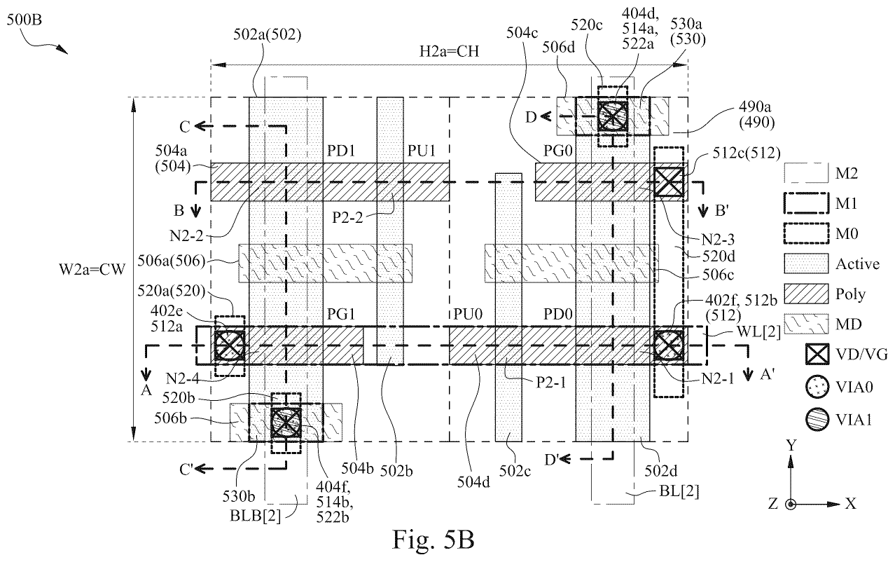

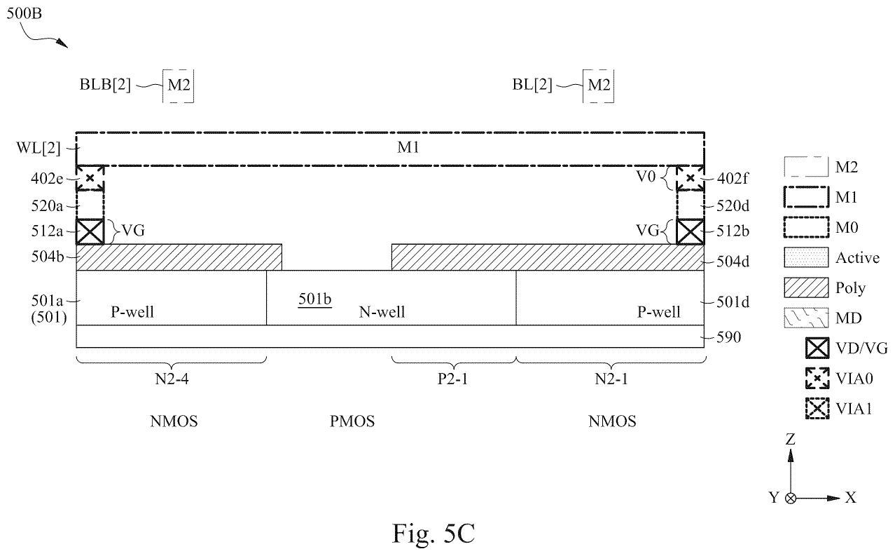

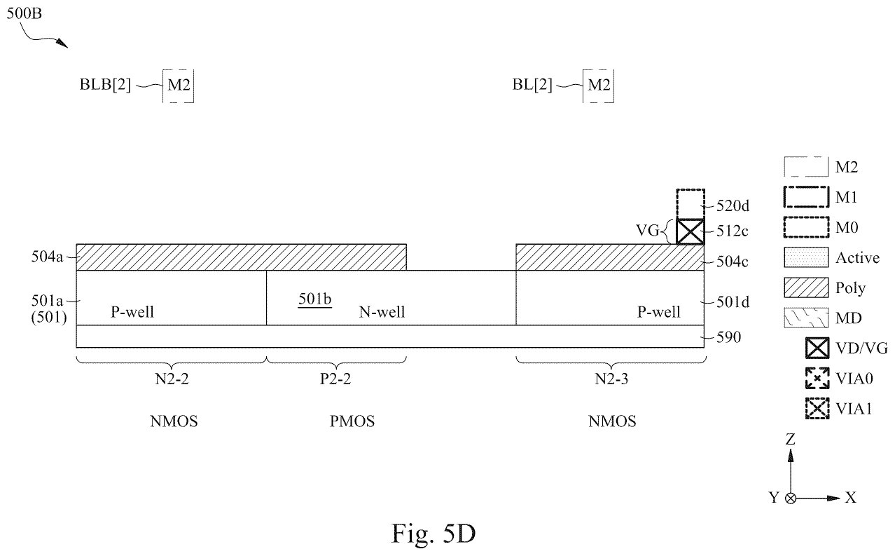

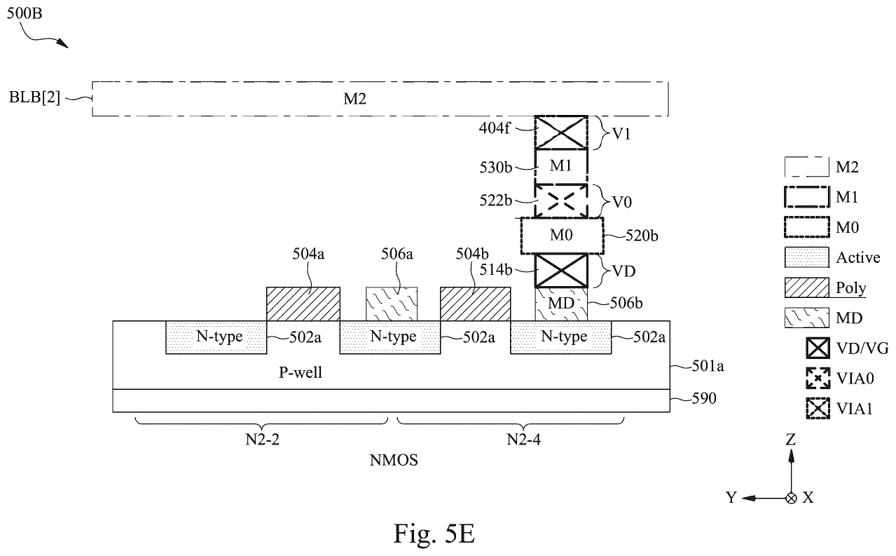

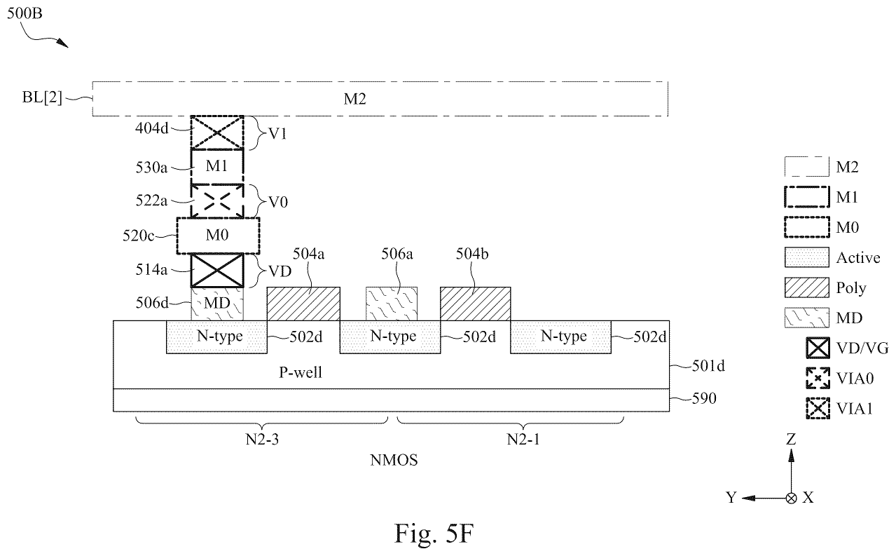

The set of vias 402 is between the set of word lines WL and underlying layers (e.g., shown in FIG. 5A-5F, 6, 8 or 9) of memory cell array 401. In some embodiments, the set of vias 402 is between the set of word lines WL and at least one memory cell 401a, 401b, 401c or 401d of memory cell array 401.

In some embodiments, vias 402a and 402b are between word line WL[1] and memory cell 401a. In some embodiments, vias 402b and 402c are between word line WL[1] and memory cell 401b.

In some embodiments, vias 402d and 402e are between word line WL[2] and memory cell 401c. In some embodiments, vias 402e and 402f are between word line WL[2] and memory cell 401d.

The set of vias 402 is positioned at one or more of a via over diffusion (VD) level, a via over gate (VG) level, a via over M0 (V0) level or a via over M1 (V1) level of memory circuit 400A, 400B, 400C, 500A-500B, 600, 700A, 700B, 800 or 900.

In some embodiments, the VD level is above at least one of an oxide diffusion (OD) level, the POLY level or the metal over diffusion (MD) level. In some embodiments, the VG level is above at least one of the OD level, the POLY level or the MD level. In some embodiments, the V0 level is above at least one of the OD level, the POLY level, the MD level or the M0 level. In some embodiments, the V1 level is above at least one of the OD level, the POLY level, the MD level, the M0 level or the M1 level.

In some embodiments, the VD level is below at least one of the M0 level, the M1 level or the M2 level. In some embodiments, the VG level is below at least one of the M0 level, the M1 level or the M2 level. In some embodiments, the V0 level is below at least one of the M1 level or the M2 level.

In some embodiments, the V1 level is below at least the M2 level. Other levels are within the scope of the present disclosure.

Other configurations, arrangements on other levels or quantities of vias in at least the set of vias 402 are within the scope of the present disclosure.

Memory circuit 400A further comprises one or more of vias 404a, 404b, 404c, 404d, 404e or 404f (collectively referred to as a “set of vias 404”).

In some embodiments, the set of vias 404 is manufactured by a corresponding set of via patterns (not shown) of a corresponding layout design of memory circuit 400A-400C or 700A-700B.

In some embodiments, vias 404a, 404b, 404c, 404d of the set of vias 404 are manufactured by corresponding via patterns (not shown) of the set of via patterns (not shown) of a corresponding layout design of memory circuit 400A-400C or 700A-700B.

The set of vias 404 is between at least one of the set of bit lines BL or the set of bit line bars BLB and underlying layers (e.g., shown in FIG. 5A-5F, 6, 8 or 9) of memory cell array 401. In some embodiments, the set of vias 404 is between at least one of the set of bit lines BL or the set of bit line bars BLB and at least one memory cell 401a, 401b, 401c or 401d of memory cell array 401.

In some embodiments, via 404a is between bit line BL[1] and memory cells 401a and 401c.

In some embodiments, via 404b is between bit line bar BLB[1] and memory cell 401a, and via 404e is between bit line bar BLB[1] and memory cell 401c.

In some embodiments, via 404d is between bit line BL[2] and memory cells 401b and 401d.

In some embodiments, via 404c is between bit line bar BLB[2] and memory cell 401b, and via 404f is between bit line bar BLB[2] and memory cell 401d.

The set of vias 404 is positioned at one or more of the VD level, the VG level, the V0 level or the V1 level of memory circuit 400A, 400B, 400C, 500A-500B, 600, 700A, 700B, 800 or 900. In some embodiments, the V1 level is above at least one of the OD level, the POLY level, the MD level, the M0 level or the M1 level.

In some embodiments, the V1 level is below the M2 level.

Other levels for at least one of the set of vias 402 or 404 are within the scope of the present disclosure.

Other configurations, arrangements on other levels or quantities of vias in at least the set of vias 404 are within the scope of the present disclosure.

Other configurations of memory circuit 400A are within the scope of the present disclosure.

FIG. 4B is a schematic diagram of a memory circuit 400B, in accordance with some embodiments.

Memory circuit 400B relates to memory cell array 202 of FIG. 2A. Memory circuit 400B is an embodiment of region 201a of memory circuit 200A of FIG. 2A, and similar detailed description is therefore omitted. In some embodiments, memory circuit 400B is an embodiment of regions of memory circuit 200A other than region 201a of memory circuit 200A of FIG. 2A.

Memory circuit 400B is a variation of memory circuit 400A of FIG. 4A, and similar detailed description is therefore omitted. In comparison with memory circuit 400A of FIG. 4A, a memory cell array 411 of FIG. 4B replaces memory cell array 401 of FIG. 4A, and similar detailed description is therefore omitted.

Memory circuit 400B comprises a memory cell array 411. Memory cell array 411 is similar to memory cell array 202 of FIG. 2A or memory cell array 401 of FIG. 4A, and similar detailed description is therefore omitted.

Memory cell array 411 comprises memory cells 411a, 411b, 411c and 411d. In some embodiments, at least one of memory cell 411a, 411b, 411c or 411d is similar to at least one of memory cell 401a, 401b, 401c or 401d of memory cell array 401 of FIG. 4A, and similar detailed description is therefore omitted.

Memory cell 411a is in row 1 and column 1 of memory cell array 411, and is designated in FIG. 4B as “r1c1.” Memory cell 411b is in row 1 and column 2 of memory cell array 411, and is designated in FIG. 4B as “r1c2.” Memory cell 411c is in row 2 and column 1 of memory cell array 411, and is designated in FIG. 4B as “r2c1.” Memory cell 411d is in row 2 and column 2 of memory cell array 411, and is designated in FIG. 4B as “r2c2.”

Memory cell array 411 is shown as a 2×2 memory cell array in FIG. 4B. Other numbers of rows and columns are within the scope of the present disclosure.

Memory cell array 411 has a height H1b in the first direction X. In some embodiments, the height H1b is equal to 1CH, where 0.5CH is the scaled cell height in the first direction X of at least one of memory cell 411a, 411b, 411c, or 411d in memory cell array 411.

Memory cell array 411 has a width W1b in the second direction Y. In some embodiments, the width W1b is equal to 4CW, where 2CW is the scaled cell width in the second direction Y of at least one of memory cell 411a, 411b, 411c, or 411d in memory cell array 411.

In some embodiments, memory cell array 411 has a width in the second direction Y equal to 4 contacted polysilicon pitches (e.g., 4CPP).

In some embodiments, memory cell array 411 has an aspect ratio AR1b that is equal to 4:1. (e.g., W1b/H1b).

Memory circuit 400B further comprises the set of bit lines BL, the set of bit line bars BLB and the set of word lines WL.

In some embodiments, memory cells 411a, 411b, 411c and 411d are similar to corresponding memory cells MCB in the same corresponding rows and same corresponding columns of region 201a of FIG. 2A, and similar detailed description is therefore omitted. In some embodiments, each of memory cells 411a, 411b, 411c and 411d is memory cell 300A of FIG. 3A, and similar detailed description is therefore omitted.

The set of bit lines BL and the set of bit line bars BLB extend in the second direction Y.

Bit line BL[1] and bit line bar BLB[1] overlap memory cells 411a and 411c. Bit line bar BLB[1] is electrically coupled to memory cells 411a and 411c by a via 414b. Bit line BL[1] is electrically coupled to memory cell 411a by a via 414b, and to memory cell 411c by a via 414e.

Bit line BL[2] and bit line bar BLB[2] overlap memory cells 411b and 411d. Bit line bar BLB[2] is electrically coupled to memory cells 411b and 411d by a via 414d. Bit line BL[2] is electrically coupled to memory cell 411b by a via 414c, and to memory cell 411d by a via 414f.

Other configurations, arrangements on other metal layers or quantities of bit lines in the set of bit lines BL are within the scope of the present disclosure.

Other configurations, arrangements on other metal layers or quantities of bit line bars in the set of bit line bars BLB are within the scope of the present disclosure.

The set of word lines WL extend in the first direction X.

Word line WL[1] overlaps memory cells 411a and 411b. Word line WL[1] is electrically coupled to memory cell 411a by a via 412a. Word line WL[1] is electrically coupled to memory cell 411b by a via 412b.

Word line WL[2] overlaps memory cells 411c and 411d. Word line WL[2] is electrically coupled to memory cell 411c by a via 412c. Word line WL[2] is electrically coupled to memory cell 411d by a via 412d.

Other configurations, arrangements on other metal layers or quantities of word lines in the set of word lines WL are within the scope of the present disclosure.

Memory circuit 400B further comprises one or more of vias 412a, 412b, 412c or 412d (collectively referred to as a “set of vias 412”).

In some embodiments, the set of vias 412 is similar to the set of vias 402 of FIG. 4A, and similar detailed description is therefore omitted. In some embodiments, at least one of vias 412a, 412b, 412c or 412d is similar to at least one or more of vias 402a, 402b, 402c, 402d, 402e or 402f of the set of vias 402 of FIG. 4A, and similar detailed description is therefore omitted.

In some embodiments, via 412a is between word line WL[1] and memory cell 411a. In some embodiments, via 412b is between word line WL[1] and memory cell 411b.

In some embodiments, via 412c is between word line WL[2] and memory cell 411c. In some embodiments, via 412d is between word line WL[2] and memory cell 411d.

Other configurations, arrangements on other levels or quantities of vias in at least the set of vias 412 are within the scope of the present disclosure.

Memory circuit 400B further comprises one or more of vias 414a, 414b, 414c, 414d, 414e or 414f (collectively referred to as a “set of vias 414”).

In some embodiments, the set of vias 414 is similar to the set of vias 404 of FIG. 4A, and similar detailed description is therefore omitted. In some embodiments, at least one of vias 414a, 414b, 414c, 414d, 414e or 414f is similar to at least one or more of vias 404a, 404b, 404c, 404d, 404e or 404f of the set of vias 404 of FIG. 4A, and similar detailed description is therefore omitted.

In some embodiments, via 414b is between bit line bar BLB[1] and memory cells 411a and 411c. In some embodiments, via 414a is between bit line BL[1] and memory cell 411a, and via 414e is between bit line BL[1] and memory cell 411c.

In some embodiments, via 414d is between bit line bar BLB[2] and memory cells 411b and 411d. In some embodiments, via 414c is between bit line BL[2] and memory cell 411b, and via 414f is between bit line BL[2] and memory cell 411d.

Other configurations, arrangements on other levels or quantities of vias in at least the set of vias 414 are within the scope of the present disclosure.

Other configurations of memory circuit 400B are within the scope of the present disclosure.

FIG. 4C is a schematic diagram of a memory circuit 400C, in accordance with some embodiments.

Memory circuit 400C relates to memory cell array 202 of FIG. 2A. Memory circuit 400C is an embodiment of region 201a of memory circuit 200A of FIG. 2A, and similar detailed description is therefore omitted. In some embodiments, memory circuit 400C is an embodiment of regions of memory circuit 200A other than region 201a of memory circuit 200A of FIG. 2A.

Memory circuit 400C is a variation of memory circuit 400A of FIG. 4A or memory circuit 400B of FIG. 4B, and similar detailed description is therefore omitted. In comparison with memory circuit 400A of FIG. 4A, a memory cell array 421 of FIG. 4B replaces memory cell array 401 of FIG. 4A, and similar detailed description is therefore omitted.

Memory circuit 400C comprises a memory cell array 421. Memory cell array 421 is similar to memory cell array 202 of FIG. 2A, memory cell array 401 of FIG. 4A or memory cell array 411 of FIG. 4B, and similar detailed description is therefore omitted.

Memory cell array 421 comprises memory cells 421a, 421b, 421c and 421d. In some embodiments, at least one of memory cell 421a, 421b, 421c or 421d is similar to at least one of memory cell 401a, 401b, 401c or 401d of memory cell array 401 of FIG. 4A or at least one of memory cell 411a, 411b, 411c or 411d of memory cell array 411 of FIG. 4B, and similar detailed description is therefore omitted.

Memory cell 421a is in row 1 and column 1 of memory cell array 421, and is designated in FIG. 4C as “r1c1.” Memory cell 421b is in row 2 and column 1 of memory cell array 421, and is designated in FIG. 4C as “r2c1.” Memory cell 421c is in row 1 and column 2 of memory cell array 421, and is designated in FIG. 4C as “r1c2.” Memory cell 421d is in row 2 and column 2 of memory cell array 421, and is designated in FIG. 4C as “r2c2.”

Memory cell array 421 is shown as a 2×2 memory cell array in FIG. 4C. Other numbers of rows and columns are within the scope of the present disclosure.

Memory cell array 421 has a height H1c in the first direction X. In some embodiments, the height H1c is equal to 2CH, where CH is the scaled cell height in the first direction X of at least one of memory cell 421a, 421b, 421c, or 421d in memory cell array 421.

Memory cell array 421 has a width W1c in the second direction Y. In some embodiments, the width W1c is equal to 2CW, where 2CW is the scaled cell width in the second direction Y of at least one of memory cell 421a, 421b, 421c, or 421d in memory cell array 421.

In some embodiments, memory cell array 421 has a width in the second direction Y equal to 4 contacted polysilicon pitches (e.g., 4CPP).

In some embodiments, memory cell array 421 has an aspect ratio AR1c that is equal to 1:1. (e.g., W1c/H1c).

Memory circuit 400C further comprises the set of bit lines BL, the set of bit line bars BLB and the set of word lines WL.

In some embodiments, memory cells 421a, 421b, 421c and 421d are similar to corresponding memory cells MCB in the same corresponding rows and same corresponding columns of region 201a of FIG. 2A, and similar detailed description is therefore omitted. In some embodiments, each of memory cells 421a, 421b, 421c and 421d is memory cell 300A of FIG. 3A, and similar detailed description is therefore omitted.

The set of bit lines BL and the set of bit line bars BLB extend in the second direction Y.

Bit line BL[1] overlaps memory cell 421a. Bit line BL[1] is electrically coupled to memory cell 421a by a via 424a. In some embodiments, bit line BL[1] is electrically coupled to memory cell 421a and memory cell 421b (not shown), and the bit line BL[1] is shared between memory cell 421a and memory cell 421b. Stated differently, neighboring memory cells (e.g., memory cells 421b and 421a) in memory circuit 400C are configured to share BLs with each other.

Bit line bar BLB[1] overlaps memory cell 421b. Bit line bar BLB[1] is electrically coupled to memory cell 421b by a via 424b. In some embodiments, bit line bar BLB[1] is electrically coupled to memory cell 421b and memory cell 421a (not shown), and the bit line bar BLB[1] is shared between memory cell 421b and memory cell 421a. Stated differently, neighboring memory cells (e.g., memory cells 421b and 421a) in memory circuit 400C are configured to share BLBs with each other.

Bit line bar BLB[2] overlaps memory cell 421c. Bit line bar BLB[2] is electrically coupled to memory cell 421c by a via 424c. In some embodiments, bit line bar BLB[2] is electrically coupled to memory cell 421c and memory cell 421d (not shown), and the bit line bar BLB[2] is shared between memory cell 421c and memory cell 421d. Stated differently, neighboring memory cells (e.g., memory cells 421d and 421c) in memory circuit 400C are configured to share BLBs with each other.

Bit line BL[2] overlaps memory cell 421d. Bit line BL[2] is electrically coupled to memory cell 421d by a via 424d. In some embodiments, bit line BL[2] is electrically coupled to memory cell 421d and memory cell 421c (not shown), and the bit line BL[2] is shared between memory cell 421d and memory cell 421c. Stated differently, neighboring memory cells (e.g., memory cells 421d and 421c) in memory circuit 400C are configured to share BLs with each other.

Other configurations, arrangements on other metal layers or quantities of bit lines in the set of bit lines BL are within the scope of the present disclosure.

Other configurations, arrangements on other metal layers or quantities of bit line bars in the set of bit line bars BLB are within the scope of the present disclosure.

The set of word lines WL extend in the first direction X.

Word line WL[1] overlaps memory cells 421a, 421b, 421c and 421d. Word line WL[1] is electrically coupled to memory cell 421b (also labelled as “Cell2” in FIG. 4C) by a via 422b. Word line WL[1] is electrically coupled to memory cell 421d (also labelled as “Cell4” in FIG. 4C) by a via 422d.

Word line WL[2] overlaps memory cells 421a, 421b, 421c and 421d. Word line WL[2] is electrically coupled to memory cell 421a (also labelled as “Cell1” in FIG. 4C) by a via 422a. Word line WL[2] is electrically coupled to memory cell 421c (also labelled as “Cell3” in FIG. 4C) by a via 422c.

As shown in FIG. 4C, word line WL[1] is electrically coupled to memory cells 421b and 421d, and is therefore shared between memory cells 421b and 421d, and is referred to as an “interleaved or alternating word line.” As shown in FIG. 4C, word line WL[1] is electrically coupled to memory cells 421a and 421c, and is therefore shared between memory cells 421a and 421c, and is referred to as an “interleaved or alternating word line.” In some embodiments, by interleaving the set of WLs and sharing BLs or BLBs between neighboring memory cells causes memory circuit 400C to have a same aspect ratio (1:1) as memory circuit 400A, resulting in a more flexible cell compared to other approaches.

Other configurations, arrangements on other metal layers or quantities of word lines in the set of word lines WL are within the scope of the present disclosure.

Memory circuit 400C further comprises one or more of vias 422a, 422b, 422c or 422d (collectively referred to as a “set of vias 422”).

In some embodiments, the set of vias 422 is similar to the set of vias 402 of FIG. 4A or the set of vias 412 of FIG. 4B, and similar detailed description is therefore omitted. In some embodiments, at least one of vias 422a, 422b, 422c or 422d is similar to at least one or more of vias 402a, 402b, 402c, 402d, 402e or 402f of the set of vias 402 of FIG. 4A or at least one or more of vias 412a, 412b, 412c or 412d of the set of vias 412 of FIG. 4B, and similar detailed description is therefore omitted.

In some embodiments, via 422b is between word line WL[1] and memory cell 421b. In some embodiments, via 422d is between word line WL[1] and memory cell 421d.

In some embodiments, via 422a is between word line WL[2] and memory cell 421a. In some embodiments, via 422c is between word line WL[2] and memory cell 421c.

Other configurations, arrangements on other levels or quantities of vias in at least the set of vias 422 are within the scope of the present disclosure.

Memory circuit 400C further comprises one or more of vias 424a, 424b, 424c or 424d (collectively referred to as a “set of vias 424”).

In some embodiments, the set of vias 424 is similar to the set of vias 404 of FIG. 4A or the set of vias 414 of FIG. 4B, and similar detailed description is therefore omitted. In some embodiments, at least one of vias 424a, 424b, 424c or 424d is similar to at least one or more of vias 404a, 404b, 404c, 404d, 404e or 404f of the set of vias 404 of FIG. 4A or at least one or more of vias 414a, 414b, 414c, 414d, 414e or 414f of the set of vias 414 of FIG. 4B, and similar detailed description is therefore omitted.

In some embodiments, via 424a is between bit line BL[1] and memory cell 421a.

In some embodiments, via 424b is between bit line bar BLB[1] and memory cell 421b.

In some embodiments, via 424c is between bit line bar BLB[2] and memory cell 421c.

In some embodiments, via 424d is between bit line BL[2] and memory cell 421d.

Other configurations, arrangements on other levels or quantities of vias in at least the set of vias 424 are within the scope of the present disclosure.

Other configurations of memory circuit 400C are within the scope of the present disclosure.

FIG. 5A is a corresponding schematic diagram of a corresponding memory circuit 500A, in accordance with some embodiments.

Memory circuit 500A relates to memory cell array 202 of FIG. 2A. Memory circuit 500A is an embodiment of one memory cell (e.g., memory cell 401a, 401b, 401c or 401d) of memory cell array 401 of FIG. 4A, and similar detailed description is therefore omitted.

Memory circuit 500A is manufactured by a corresponding layout design similar to memory circuit 500A.

Memory circuit 500A has a height H2a in the first direction X. In some embodiments, the height H2a is equal to CH, where CH is a scaled cell height in the first direction X of at least circuit 500A.

Memory circuit 500A has a width W2a in the second direction Y. In some embodiments, the width W2a is equal to CW, where CW is a scaled cell width in the second direction Y of at least memory circuit 500A.

In some embodiments, memory circuit 500A has a width in the second direction Y equal to 2 contacted polysilicon pitches (e.g., 2CPP).

In some embodiments, memory circuit 500A is usable as at least one memory cell 401a, 401b, 401c or 401d of memory cell array 401 of FIG. 4A, and similar detailed description is therefore omitted.

Memory circuit 500A includes one or more active regions 502a, 502b, 502c or 502d (collectively referred to as a “set of active regions 502”) extending in the second direction Y. The set of active regions 502 is embedded in a well 501a, 501b, 501c or 501d (collectively referred to as a “set of wells 501”). The set of wells 501 is in a substrate 490. In some embodiments, at least one of well 501a or 501d is a P-well, and at least one of well 501b or 501c is an N-well. In some embodiments, well 501b and 501c is a continuous well. In some embodiments, at least well 501b or 501c includes dopants of a first type, and at least well 501a or 501d include dopants of a second type different from the first type. In some embodiments, the first type is an N-type dopant and the second type is a P-type dopant. In some embodiments, the first type is a P-type dopant and the second type is an N-type dopant.

In some embodiments, the set of active regions 502 is manufactured by a corresponding set of active region patterns (not shown) of a corresponding layout design of memory circuit 500A-500B, 600, 800 or 900. In some embodiments, active regions 502a, 502b, 502c or 502d of the set of active regions 502 are manufactured by corresponding active region patterns (not shown) of the set of active region patterns (not shown) of a corresponding layout design of memory circuit 500A-500B, 600, 800 or 900.

Each of active regions 502a, 502b, 502c and 502d of the set of active regions 502 are separated from one another in the first direction X.

In some embodiments, at least one of the set of active regions 502 is located on a front-side 490a of memory circuit 400A, 400B, 400C, 500A-500B, 600, 700A, 700B, 800, 900, 1000, 1100, 1200, 1300, 1400 or 1500. In some embodiments, the front-side 490a is part of a substrate 490.

In some embodiments, at least one of the set of active regions 502 corresponds to source and drain regions of one or more complementary FET (CFET) transistors. In some embodiments, at least one of the set of active regions 502 corresponds to source and drain regions of one or more nanosheet transistors or nanowire transistors. Other transistor types are within the scope of the present disclosure.

In some embodiments, at least one of the set of active regions 502 corresponds to source and drain regions of one or more finFET transistors.

In some embodiments, the set of active regions 502 are referred to as an oxide diffusion (OD) region which defines the source or drain diffusion regions of at least one of memory cell 300A or 300B or memory circuit 400A, 400B, 400C, 500A-500B, 600, 700A, 700B, 800, 900, 1000, 1100, 1200, 1300, 1400 or 1500.

In some embodiments, active regions 502a or 502d are source and drain regions of NFET transistors of at least one of memory cell 300A or memory circuit 400A, 400B, 400C, 500A-500B, 600, 700A, 700B, 800, 900, 1000, 1100, 1200, 1300, 1400 or 1500, and active regions 502b or 502c are source and drain regions of PFET transistors of at least one of memory cell 300A or 300B or memory circuit 400A, 400B, 400C, 500A-500B, 600, 700A, 700B, 800, 900, 1000, 1100, 1200, 1300, 1400 or 1500.

In some embodiments, active regions 502a or 502d are source and drain regions of PFET transistors of at least one of memory cell 300A or memory circuit 400A, 400B, 400C, 500A-500B, 600, 700A, 700B, 800, 900, 1000, 1100, 1200, 1300, 1400 or 1500, and active regions 502b or 502c are source and drain regions of NFET transistors of at least one of memory cell 300A or 300B or memory circuit 400A, 400B, 400C, 500A-500B, 600, 700A, 700B, 800, 900, 1000, 1100, 1200, 1300, 1400 or 1500.

In some embodiments, the set of active regions 502 is located on a first level. In some embodiments, the first level corresponds to an active level or an OD level of at least one of memory cell 300A or 300B or memory circuit 400A, 400B, 400C, 500A-500B, 600, 700A, 700B, 800, 900, 1000, 1100, 1200, 1300, 1400 or 1500.

Other configurations, arrangements on other levels or quantities of regions in the set of active regions 502 are within the scope of the present disclosure.

Memory circuit 500A further includes one or more gates 504a, 504b, 504c or 504d (collectively referred to as a “set of gates 504”) extending in the first direction X.

The set of gates 504 is above the set of active regions 502.

Gates 504a and 504c are separated from one another in the first direction X.

Gates 504b and 504d are separated from one another in the first direction X.

Gates 504a and 504b are separated from one another in the second direction Y.

Gates 504c and 504d are separated from one another in the second direction Y.

In some embodiments, the set of gates 504 is manufactured by a corresponding set of gate patterns (not shown) of a corresponding layout design of memory circuit 500A-500B, 600, 800 or 900.

In some embodiments, gates 504a, 504b, 504c or 504d of the set of gates 504 are manufactured by corresponding gate patterns (not shown) of the set of gate patterns (not shown) of a corresponding layout design of memory circuit 500A-500B, 600, 800 or 900.

In some embodiments, at least one of the set of gates 504 are located on the front-side of memory circuit 400A, 400B, 400C, 500A-500B, 600, 700A, 700B, 800, 900, 1000, 1100, 1200, 1300, 1400 or 1500.

In some embodiments, each of the gates in the set of gates 504 is shown in FIGS. 5A-5F, 6, 8 and 9 with labels “N2-1, P2-1, N2-2, P2-2, N2-3, N2-4” that identify corresponding transistors of FIGS. 3A, 4A, 4B and 4C, and are omitted for brevity.

In some embodiments, one of the gates of the set of gates 504, 604, 804 or 904 is a gate of a dummy transistor. In some embodiments, a dummy transistor is a non-functional transistor.

In some embodiments, the set of gates 504 is above the set of active region 502.

In some embodiments, the set of gates 504 encapsulate the set of active region patterns 502 and 304.

The set of gates 504 is positioned on a second level. In some embodiments, the second level is different from the first level. In some embodiments, the second level corresponds to the POLY level of one or more of memory cell 300A or 300B or memory circuit 400A, 400B, 400C, 500A-500B, 600, 700A, 700B, 800, 900, 1000, 1100, 1200, 1300, 1400 or 1500. In some embodiments, the POLY level is above the OD level.

Other configurations, arrangements on other levels or quantities of gates in the set of gates 504 are within the scope of the present disclosure.

In some embodiments, at least one via of the set of vias 402 is electrically coupled to at least one gate of the set of gates 504. In some embodiments, at least one via of the set of vias 404 is electrically coupled to at least one gate of the set of gates 504.

In some embodiments, at least one via of the set of vias 402 is electrically coupled to at least one active region of the set of active regions 502. In some embodiments, at least one via of the set of vias 404 is electrically coupled to at least one active region of the set of active regions 502.

Other configurations of memory circuit 500A are within the scope of the present disclosure.

FIG. 5B is a corresponding schematic diagram of a corresponding memory circuit 500B, in accordance with some embodiments.

FIG. 5C is a cross-sectional view of integrated circuit 500B as intersected by plane A-A′, in accordance with some embodiments.

FIG. 5D is a cross-sectional view of integrated circuit 500B as intersected by plane B-B′, in accordance with some embodiments.

FIG. 5E is a cross-sectional view of integrated circuit 500B as intersected by plane C-C′, in accordance with some embodiments.

FIG. 5F is a cross-sectional view of integrated circuit 500B as intersected by plane D-D′, in accordance with some embodiments.

Memory circuit 500B relates to memory cell array 202 of FIG. 2A. Memory circuit 500B is an embodiment of memory cell 401d of memory cell array 401 of FIG. 4A, and similar detailed description is therefore omitted. In some embodiments, memory circuit 500B is an embodiment of memory cell 401a, 401b or 401c of memory cell array 401 of FIG. 4A, and similar detailed description is therefore omitted.

Memory circuit 500B is manufactured by a corresponding layout design similar to memory circuit 500B.

In some embodiments, memory circuit 500B combines features of memory circuit 500A of FIG. 5A applied to memory cell 401d of memory cell array 401 of FIG. 4A, and similar detailed description is therefore omitted. In some embodiments, the features of memory circuit 500B are applicable to at least one of memory circuit 400B, 400C, 600, 700A, 700B, 800 or 900, and similar detailed description is therefore omitted.

Memory circuit 500B is a variation of memory circuit 400A of FIG. 4A and memory circuit 500A of FIG. 5A, and similar detailed description is therefore omitted. In comparison with memory circuit 500A of FIG. 5A, memory circuit 500B of FIG. 5B further comprises memory circuit 500A of FIG. 5A, a set of contacts 506, a set of vias 512, a set of vias 514, a set of conductors 520 and a set of conductors 530.

In comparison with memory circuit 400A of FIG. 4A, memory circuit 500B of FIG. 5B further comprises memory circuit 500A of FIG. 5A, the set of contacts 506, the set of vias 512, the set of vias 514, the set of conductors 520 and the set of conductors 530.

Memory circuit 500B is an embodiment of memory cell 401d of memory cell array 401 of FIG. 4A, and similar detailed description is therefore omitted.

Memory circuit 500B comprises Bit line BL[2], bit line bar BLB[2], word line WL[2], vias 402e and 402f and vias 404d and 404f, the set of active regions 502, the set of gates 504, the set of contacts 506, the set of vias 512, the set of vias 514, the set of conductors 520 and the set of conductors 530.

In some embodiments, bit line BL[2], bit line bar BLB[2], word line WL[2], vias 402e and 402f and vias 404d and 404f are part of memory cell 401d of FIG. 4A.

The set of contacts 506 includes one or more of contacts 506a, 506b, 506c or 506d. The set of contacts 506 extends in the first direction X. The set of contacts 506 is over the set of active regions 502.

The set of contacts 506 is electrically coupled to the set of active regions 502. In some embodiments, the set of contacts 506 electrically couples the set of active regions 502 to upper levels (e.g., M0, M1 or M2).

Contact 506a is electrically coupled to active regions 502a and 502b. Contact 506a electrically couples active regions 502a and 502b together. In some embodiments, contact 506a electrically couples the drain of NFET transistor N2-2, the drain of PFET transistor P2-2 and the source of NFET transistor N2-4 together.

Contact 506b is electrically coupled to active region 502a. In some embodiments, contact 506b is electrically coupled to the drain of NFET transistor N2-4.

Contact 506c is electrically coupled to active regions 502c and 502d. Contact 506c electrically couples active regions 502c and 502d together. In some embodiments, contact 506c electrically couples the drain of NFET transistor N2-1, the drain of PFET transistor P2-1 and the source of NFET transistor N2-3 together.

Contact 506d is electrically coupled to active region 502d. In some embodiments, contact 506d is electrically coupled to the drain of NFET transistor N2-3.

The set of contacts 506 is located on a third level. In some embodiments, the third level is different from the first level. In some embodiments, the third level corresponds to the metal over diffusion (MD) level of one or more of memory cell 300A or 300B or memory circuit 400A, 400B, 400C, 500A-500B, 600, 700A, 700B, 800, 900, 1000, 1100, 1200, 1300, 1400 or 1500. In some embodiments, the MD level is above the OD level.

Other quantities, configurations, arrangements on other levels or quantities of contacts in the set of contacts 506 are within the scope of the present disclosure.

The set of vias 512 includes one or more of vias 512a, 512b or 512c.

In some embodiments, the set of vias 512 is manufactured by a corresponding set of via patterns (not shown) of a corresponding layout design of memory circuit 500B. In some embodiments, vias 512a, 512b or 512c of the set of vias 512 are manufactured by corresponding via patterns (not shown) of the set of via patterns (not shown) of a corresponding layout design of memory circuit 500B.

The set of vias 512 is between the set of gates 504 and the set of conductors 520.

In some embodiments, via 512a is between gate 504b and conductor 520a. In some embodiments, via 512a electrically couples gate 504b and conductor 520a together.

In some embodiments, via 512b is between gate 504d and conductor 520d. In some embodiments, via 512b electrically couples gate 504d and conductor 520d together.

In some embodiments, via 512c is between gate 504c and conductor 520d. In some embodiments, via 512c electrically couples gate 504c and conductor 520d together.

The set of vias 512 is positioned at the VG level of memory circuit 400A, 400B, 400C, 500A-500B, 600, 700A, 700B, 800 or 900. Other levels are within the scope of the present disclosure.

Other configurations, arrangements on other levels or quantities of vias in at least the set of vias 512 are within the scope of the present disclosure.

The set of vias 514 includes one or more of vias 514a or 514b.

In some embodiments, the set of vias 514 is manufactured by a corresponding set of via patterns (not shown) of a corresponding layout design of memory circuit 500B. In some embodiments, vias 514a or 514b of the set of vias 514 are manufactured by corresponding via patterns (not shown) of the set of via patterns (not shown) of a corresponding layout design of memory circuit 500B.

The set of vias 514 is between the set of contacts 506 and the set of conductors 520.

In some embodiments, via 514a is between contact 506d and conductor 520c. In some embodiments, via 514a electrically couples contact 506d and conductor 520c together.

In some embodiments, via 514b is between contact 506b and conductor 520b. In some embodiments, via 514b electrically couples contact 506b and conductor 520b together.

The set of vias 514 is positioned at the VD level of memory circuit 400A, 400B, 400C, 500A-500B, 600, 700A, 700B, 800 or 900. Other levels are within the scope of the present disclosure.

Other configurations, arrangements on other levels or quantities of vias in at least the set of vias 514 are within the scope of the present disclosure.

The set of conductors 520 includes one or more of conductors 520a, 520b, 520c or 520d.

Set of conductors 520 extends in the second direction Y.

The set of conductors 520 is over the set of contacts 506, the set of gates 504 and the set of active regions 502.

The set of conductors 520 is below the set of conductors 530, the set of bit lines BL, the set of bit line bars BLB and the set of word lines WL.

The set of conductors 520 electrically couples the set of contacts 506 or the set of gates 504 to upper levels (e.g., M1 or M2).

Conductor 520a is electrically coupled to gate 504b by via 512a.

Conductor 520b is electrically coupled to contact 506b by via 514b.

Conductor 520c is electrically coupled to contact 506d by via 514a.

Conductor 520d is electrically coupled to gate 504d and gate 504c by corresponding via 512b and 512c. Conductor 520d electrically couples gate 504d and gate 504c together by corresponding vias 512b and 512c.

The set of conductors 520 is located on a fourth level. The fourth level is above the first level, the second level and the third level. In some embodiments, the fourth level is referred to as the metal zero (M0) level. Other levels are within the scope of the present disclosure.

Other quantities or configurations of the set of conductors 520 are within the scope of the present disclosure.

The set of conductors 530 includes one or more of conductors 530a or 530b.

Set of conductors 530 extends in the first direction X.

The set of conductors 530 is over the set of conductors 530, the set of contacts 506, the set of gates 504 and the set of active regions 502.

The set of conductors 530 is below the set of bit lines BL and the set of bit line bars BLB.

The set of conductors 530 electrically couples the set of contacts 506 or the set of gates 504 to upper levels (e.g., M2).

Conductor 530a is electrically coupled to conductor 520c by via 522a.

Conductor 530b is electrically coupled to conductor 520b by via 522b.

The set of conductors 530 is located on a fifth level. The fifth level is above the first level, the second level, the third level and the fourth level. In some embodiments, the fifth level is referred to as the metal one (M1) level. Other levels are within the scope of the present disclosure.

In some embodiments, word line WL[2] is on the fifth level. Word line WL[2] is electrically coupled to conductor 520a by via 402e. Word line WL[2] is electrically coupled to conductor 520d by via 402f.

In some embodiments, vias 402e and 402f are in the V0 level. In some embodiments, the set of vias 402 are in the V0 level. Other levels are within the scope of the present disclosure.

Other quantities or configurations of the set of conductors 530 are within the scope of the present disclosure.

The set of vias 522 includes one or more of vias 522a or 522b.

In some embodiments, the set of vias 522 is manufactured by a corresponding set of via patterns (not shown) of a corresponding layout design of memory circuit 500B. In some embodiments, vias 522a or 522b of the set of vias 522 are manufactured by corresponding via patterns (not shown) of the set of via patterns (not shown) of a corresponding layout design of memory circuit 500B.

The set of vias 522 is between the set of conductors 520 and the set of conductors 530.

In some embodiments, via 522a is between conductor 520c and conductor 530a. In some embodiments, via 522a electrically couples conductor 520c and conductor 530a together.

In some embodiments, via 522b is between conductor 520b and conductor 530b. In some embodiments, via 522b electrically couples conductor 520b and conductor 530b together.

The set of vias 522 is positioned at the V1 level of memory circuit 400A, 400B, 400C, 500A-500B, 600, 700A, 700B, 800 or 900. Other levels are within the scope of the present disclosure.

Other configurations, arrangements on other levels or quantities of vias in at least the set of vias 522 are within the scope of the present disclosure.

In some embodiments, the set of bit lines BL and the set of bit line bars BLB are located on a sixth level. The sixth level is above the first level, the second level, the third level, the fourth level and the fifth level. In some embodiments, the sixth level is referred to as the metal two (M2) level.

Other levels are within the scope of the present disclosure.

Bit line BL[2] is electrically coupled to conductor 530a by via 404d.

Bit line bar BLB[2] is electrically coupled to conductor 530b by via 404f.

In some embodiments, vias 404d and 404f are in the V1 level. In some embodiments, the set of vias 404 are in the V1 level. Other levels are within the scope of the present disclosure.

Other quantities or configurations of the set of conductors 530 are within the scope of the present disclosure.

Other configurations of memory circuit 500B are within the scope of the present disclosure.

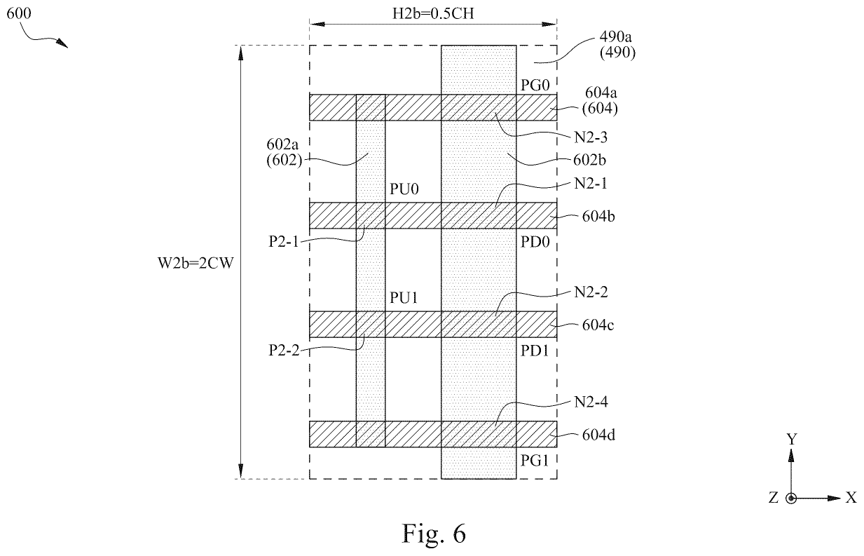

FIG. 6 is a corresponding schematic diagram of a corresponding memory circuit 600, in accordance with some embodiments.

Memory circuit 600 relates to memory cell array 202 of FIG. 2A. Memory circuit 600 is an embodiment of one memory cell (e.g., memory cell 411a, 411b, 411c or 411d) of memory cell array 411 of FIG. 4B, and similar detailed description is therefore omitted.

In some embodiments, memory circuit 600 is an embodiment of one memory cell (e.g., memory cell 421a, 421b, 421c or 421d) of memory cell array 421 of FIG. 4C, and similar detailed description is therefore omitted.

Memory circuit 600 is manufactured by a corresponding layout design similar to memory circuit 600.

Memory circuit 600 has a height H2b in the first direction X. In some embodiments, the height H2b is equal to 0.5CH, where CH is a scaled cell height in the first direction X of at least circuit 600.

Memory circuit 600 has a width W2b in the second direction Y. In some embodiments, the width W2b is equal to 2CW, where CW is a scaled cell width in the second direction Y of at least memory circuit 600.

In some embodiments, memory circuit 600 has a width in the second direction Y equal to 4 contacted polysilicon pitches (e.g., 4CPP).

In some embodiments, memory circuit 600 is usable as at least one memory cell 411a, 411b, 411c or 411d of memory cell array 411 of FIG. 4B, and similar detailed description is therefore omitted.

In some embodiments, memory circuit 600 is usable as at least one memory cell 421a, 421b, 421c or 421d of memory cell array 421 of FIG. 4C, and similar detailed description is therefore omitted.

Memory circuit 600 includes one or more active regions 602a or 602b (collectively referred to as a “set of active regions 602”) extending in the second direction Y.

In some embodiments, the set of active regions 602 is similar to the set of active regions 502 of FIG. 5A, and similar detailed description is therefore omitted. In some embodiments, one or more of active regions 602a or 602b is similar to one or more of active regions 502a, 502b, 502c or 502d of the set of active regions 502 of FIG. 5A, and similar detailed description is therefore omitted.

In some embodiments, the set of active regions 602 is manufactured by a corresponding set of active region patterns (not shown) of a corresponding layout design of memory circuit 500A-500B, 600, 800 or 900. In some embodiments, active regions 602a or 602b of the set of active regions 602 are manufactured by corresponding active region patterns (not shown) of the set of active region patterns (not shown) of a corresponding layout design of memory circuit 500A-500B, 600, 800 or 900.

In some embodiments, active region 602a is source and drain regions of PFET transistors of at least one of memory cell 300A or memory circuit 400A, 400B, 400C, 500A-500B, 600, 700A, 700B, 800, 900, 1000, 1100, 1200, 1300, 1400 or 1600, and active region 602b is source and drain regions of NFET transistors of at least one of memory cell 300A or memory circuit 400A, 400B, 400C, 500A-500B, 600, 700A, 700B, 800, 900, 1000, 1100, 1200, 1300, 1400 or 1500.

In some embodiments, active region 602a is source and drain regions of NFET transistors of at least one of memory cell 300A or memory circuit 400A, 400B, 400C, 500A-500B, 600, 700A, 700B, 800, 900, 1000, 1100, 1200, 1300, 1400 or 1600, and active region 602b is source and drain regions of PFET transistors of at least one of memory cell 300A or memory circuit 400A, 400B, 400C, 500A-500B, 600, 700A, 700B, 800, 900, 1000, 1100, 1200, 1300, 1400 or 1500.

Other configurations, arrangements on other levels or quantities of regions in the set of active regions 602 are within the scope of the present disclosure.

Memory circuit 600 further includes one or more gates 604a, 604b, 604c or 604d (collectively referred to as a “set of gates 604”) extending in the first direction X.

In some embodiments, the set of gates 604 is similar to the set of gates 504 of FIG. 5A, and similar detailed description is therefore omitted. In some embodiments, one or more of gates 604a, 604b, 604c or 604d is similar to one or more of gates 504a, 504b, 504c or 504d of the set of gates 504 of FIG. 5A, and similar detailed description is therefore omitted.

Each of the gates in the set of gates 604 is separated from another gate in the set of gates 604 in the second direction Y.

In some embodiments, the set of gates 604 is manufactured by a corresponding set of gate patterns (not shown) of a corresponding layout design of memory circuit 500A-500B, 600, 800 or 900.

In some embodiments, gates 604a, 604b, 604c or 604d of the set of gates 604 are manufactured by corresponding gate patterns (not shown) of the set of gate patterns (not shown) of a corresponding layout design of memory circuit 500A-500B, 600, 800 or 900.

In some embodiments, each of the gates in the set of gates 604 is shown in FIGS. 5A-5F, 6, 8 and 9 with labels “N2-1, P2-1, N2-2, P2-2, N2-3, N2-4” that identify corresponding transistors of FIGS. 3A, 4A, 4B and 4C, and are omitted for brevity.

Other configurations, arrangements on other levels or quantities of gates in the set of gates 604 are within the scope of the present disclosure.

In some embodiments, at least one via of the set of vias 402 is electrically coupled to at least one gate of the set of gates 604. In some embodiments, at least one via of the set of vias 404 is electrically coupled to at least one gate of the set of gates 604.

In some embodiments, at least one via of the set of vias 402 is electrically coupled to at least one active region of the set of active regions 602. In some embodiments, at least one via of the set of vias 404 is electrically coupled to at least one active region of the set of active regions 602.

Other configurations of memory circuit 600 are within the scope of the present disclosure.

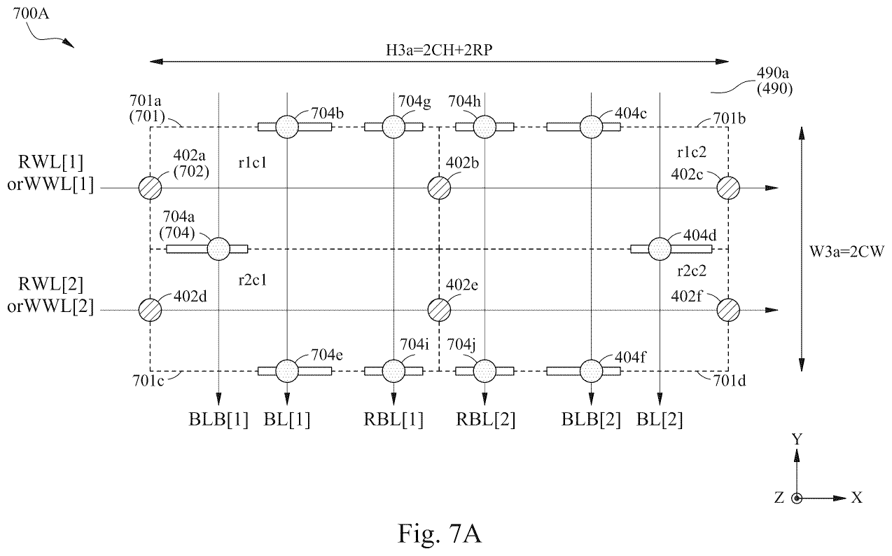

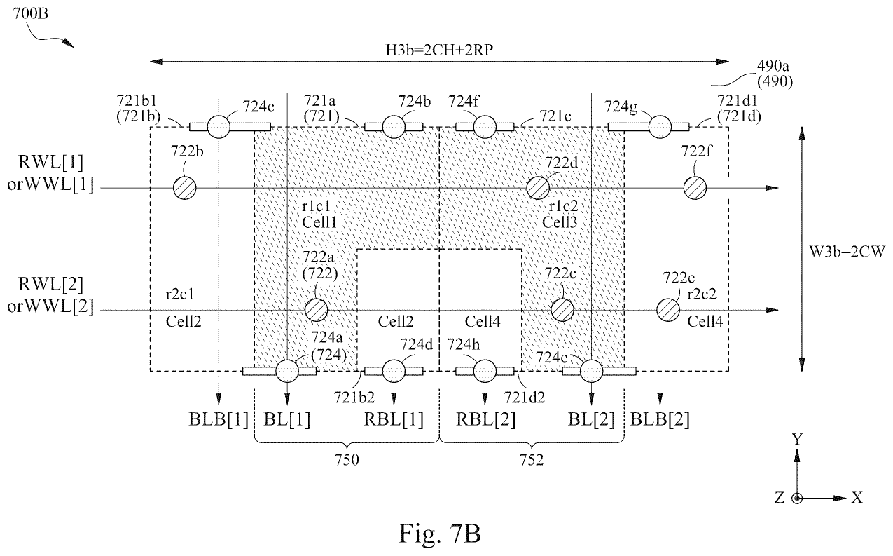

FIGS. 7A-7B are corresponding schematic diagrams of a corresponding memory circuit 700A-700B, in accordance with some embodiments.

FIG. 7A is a schematic diagram of a memory circuit 700A, in accordance with some embodiments.

Memory circuit 700A relates to memory cell array 202 of FIG. 2B. Memory circuit 700A is an embodiment of region 201b of memory circuit 200B of FIG. 2B, and similar detailed description is therefore omitted. In some embodiments, memory circuit 700A is an embodiment of regions of memory circuit 200B other than region 201b of memory circuit 200B of FIG. 2B.

Memory circuit 700A is a variation of memory circuit 400A of FIG. 4A, and similar detailed description is therefore omitted. In comparison with memory circuit 400A of FIG. 4A, a memory cell array 701 of FIG. 7A replaces memory cell array 401 of FIG. 4A, read word lines RWL of FIG. 7A or write word lines WWL of FIG. 7A replace word lines WL of FIG. 4A, and similar detailed description is therefore omitted. In comparison with memory circuit 400A of FIG. 4A, memory circuit 700A further includes read bit lines RBL, and similar detailed description is therefore omitted.

Memory circuit 700A comprises a memory cell array 701. Memory circuit 700A is a schematic representation of two adjacent columns and two adjacent rows of a memory cell array 701. In some embodiments, memory circuit 700 is a schematic representation of columns 1 and 2 of memory cell array 202 of FIG. 2B, and rows 1 and 2 of memory cell array 202 of FIG. 2B, and similar detailed description is therefore omitted. In some embodiments, memory circuit 700 is a schematic representation of other columns or other rows of memory cell array 202 of FIG. 2B rather than columns 1 and 2 or rows 1 and 2 of memory cell array 202 of FIG. 2B, and similar detailed description is therefore omitted.

Memory circuits 700A-700B is manufactured by a corresponding layout design similar to memory circuits 700A-700B.

Memory cell array 701 is similar to memory cell array 202 of FIG. 2B, and similar detailed description is therefore omitted.

Memory cell array 701 comprises memory cells 701a, 701b, 701c and 701d.

Memory cell 701a is in row 1 and column 1 of memory cell array 701, and is designated in FIG. 7A as “r1c1.” Memory cell 701b is in row 1 and column 2 of memory cell array 701, and is designated in FIG. 7A as “r1c2.” Memory cell 701c is in row 2 and column 1 of memory cell array 701, and is designated in FIG. 7A as “r2c1.” Memory cell 701d is in row 2 and column 2 of memory cell array 701, and is designated in FIG. 7A as “r2c2.”

Memory cell array 701 is shown as a 2×2 memory cell array in FIG. 7A. Other numbers of rows and columns are within the scope of the present disclosure.

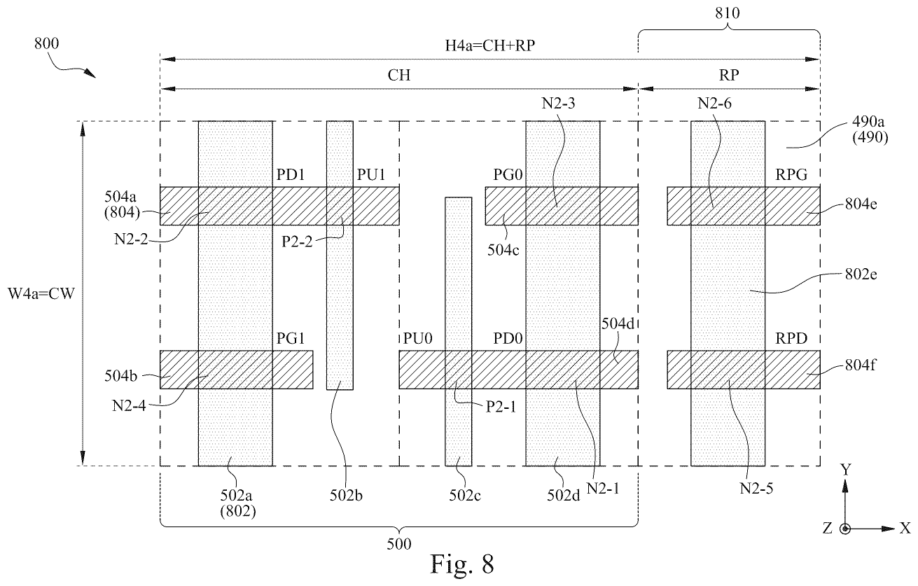

Memory cell array 701 has a height H3a in the first direction X. In some embodiments, the height H3a is equal to 2CH+2RP, where CH is a scaled cell height in the first direction X of at least one of memory cell 701a, 701b, 701c, or 701d in memory cell array 701, and where RP is a cell height in the first direction X of at least a region 810 in FIG. 8.

Memory cell array 701 has a width W3a in the second direction Y. In some embodiments, the width W3a is equal to 2CW, where CW is a scaled cell width in the second direction Y of at least one of memory cell 701a, 701b, 701c, or 701d in memory cell array 701.

In some embodiments, memory cell array 701 has a width in the second direction Y equal to 2 contacted polysilicon pitches (e.g., 2CPP).

In some embodiments, memory cell array 701 has an aspect ratio ARla that is equal to ((CH+RP)/CW). (e.g., W1a/H1a).

Memory circuit 700A further comprises the set of bit lines BL and the set of bit line bars BLB.

In some embodiments, memory cells 701a, 701b, 701c and 701d are similar to corresponding memory cells MCB in the same corresponding rows and same corresponding columns of region 201b of FIG. 2B, and similar detailed description is therefore omitted. In some embodiments, each of memory cells 701a, 701b, 701c and 701d is memory cell 300B of FIG. 3B, and similar detailed description is therefore omitted.

Bit line BL[1] and bit line bar BLB[1] overlap memory cells 701a and 701c. Bit line bar BLB[1] is electrically coupled to memory cells 701a and 701c by a via 704a. Bit line BL[1] is electrically coupled to memory cell 701a by a via 704b and to memory cell 701c by a via 704e.

Bit line BL[2] and bit line bar BLB[2] overlap memory cells 701b and 701d. Bit line BL[2] is electrically coupled to memory cells 701b and 701d by via 404d. Bit line bar BLB[2] is electrically coupled to memory cell 701b by via 404c and to memory cell 701d by via 404f.

Other configurations, arrangements on other metal layers or quantities of bit lines in the set of bit lines BL are within the scope of the present disclosure.

Other configurations, arrangements on other metal layers or quantities of bit line bars in the set of bit line bars BLB are within the scope of the present disclosure.

Memory circuit 700A further comprises read word lines RWL[1] and RWL[2] (collectively referred to as a “set of read word lines RWL”) or write word lines WWL[1] and WWL[2] (collectively referred to as a “set of write word lines WWL”).

The set of write word lines WWL[1] or the set of read word lines RWL[1] extend in the first direction X. In some embodiments, at least one of the set of write word lines WWL[1] or the set of read word lines RWL[1] is similar to the set of word lines WL, and similar detailed description is therefore omitted.

In some embodiments, write word lines WWL[1] and WWL[2] are similar to corresponding write word lines WWL[1] and WWL[2] of FIG. 2B, and similar detailed description is therefore omitted. In some embodiments, read word lines RWL[1] and RWL[2] are similar to corresponding read word lines RWL[1] and RWL[2] of FIG. 2B, and similar detailed description is therefore omitted.

Write word line WWL[1] or read word line RWL[1] overlaps memory cells 701a and 701b.

Write word line WWL[1] or read word line RWL[1] is electrically coupled to memory cell 701a by vias 402a and 402b. Write word line WWL[1] or read word line RWL[1] is electrically coupled to memory cell 701b by vias 402b and 402c.

Write word line WWL[2] or read word line RWL[2] overlaps memory cells 701c and 701d.

Write word line WWL[2] or read word line RWL[2] is electrically coupled to memory cell 701c by vias 402d and 402e. Write word line WWL[2] or read word line RWL[2] is electrically coupled to memory cell 701d by vias 402e and 402f.

In some embodiments, at least one of the set of write word lines WWL or the set of read word lines RWL is in the M1 layer of at least one of memory circuit 700A or 700B. In some embodiments, at least one of the set of write word lines WWL or the set of read word lines RWL is in an M0 layer of at least one of memory circuit 700A or 700B. Other metal layers for at least one of the set of write word lines WWL or the set of read word lines RWL are within the scope of the present disclosure.

In some embodiments, at least one of the set of write word lines WWL or the set of read word lines RWL is in the POLY layer of at least one of memory circuit 700A or 700B.

Other configurations, arrangements on other metal layers or quantities of read word lines or write word lines in at least one of the set of write word lines WWL or the set of read word lines RWL are within the scope of the present disclosure.

Memory circuit 700A further comprises read bit lines RBL[1] and RBL[2] (collectively referred to as a “set of read bit lines RBL”).

The set of read bit lines RBL extend in the second direction Y. In some embodiments, the set of read bit lines RBL is similar to the set of bit lines BL, and similar detailed description is therefore omitted.

In some embodiments, read bit lines RBL[1] and RBL[2] are similar to corresponding read bit lines RBL[1] and RBL[2] of FIG. 2B, and similar detailed description is therefore omitted.

Read bit line RBL[1] overlaps memory cells 701a and 701c. Read bit line RBL[1] is electrically coupled to memory cell 701a by via 704g. Read bit line RBL[1] is electrically coupled to memory cell 701c by via 704i.

Read bit line RBL[2] overlaps memory cells 701b and 701d. Read bit line RBL[2] is electrically coupled to memory cell 701b by via 704h. Read bit line RBL[2] is electrically coupled to memory cell 701d by via 704j.

In some embodiments, the set of read bit lines RBL is in the M2 layer of at least one of memory circuit 700A or 700B. In some embodiments, the set of read bit lines RBL is in an M1 layer of at least one of memory circuit 700A or 700B. Other metal layers for the set of read bit lines RBL are within the scope of the present disclosure.

Other configurations, arrangements on other metal layers or quantities of read bit lines in the set of read bit lines RBL are within the scope of the present disclosure.

Memory circuit 700A further comprises one or more of vias 402a, 402b, 402c, 402d, 402e or 402f (collectively referred to as a “set of vias 702”).

In some embodiments, the set of vias 702 is similar to the set of vias 402 of FIG. 4A, and similar detailed description is therefore omitted.

The set of vias 702 is between one of the set of write word lines WWL or the set of read word lines RWL and underlying layers (e.g., shown in FIG. 5A-5F, 6, 8 or 9) of memory cell array 701.

In some embodiments, the set of vias 702 is between one of the set of write word lines WWL or the set of read word lines RWL and at least one memory cell 701a, 701b, 701c or 701d of memory cell array 701.

In some embodiments, vias 402a and 402b are between write word line WWL[1] or read word line RWL[1] and memory cell 701a. In some embodiments, vias 402b and 402c are between write word line WWL[1] or read word line RWL[1] and memory cell 701b.

In some embodiments, vias 402d and 402e are between write word line WWL[2] or read word line RWL[2] and memory cell 701c. In some embodiments, vias 402e and 402f are between write word line WWL[2] or read word line RWL[2] and memory cell 701d.

Other configurations, arrangements on other levels or quantities of vias in at least the set of vias 702 are within the scope of the present disclosure.

Memory circuit 700A further comprises one or more of vias 704a, 704b, 404c, 404d, 704e, 404f, 704g, 704h, 704i or 704j (collectively referred to as a “set of vias 704”).

In some embodiments, the set of vias 704 is similar to the set of vias 404 of FIG. 4A, and similar detailed description is therefore omitted. In some embodiments, at least one of vias 704a, 704b, 704e, 704g, 704h, 704i or 704j is similar to at least one or more of vias 404a, 404b, 404c, 404d, 404e or 404f of the set of vias 404 of FIG. 4A, and similar detailed description is therefore omitted.

The set of vias 704 is between at least one of the set of bit lines BL, the set of bit line bars BLB or the set of read bit lines RBL and underlying layers (e.g., shown in FIG. 5A-5F, 6, 8 or 9) of memory cell array 701. In some embodiments, the set of vias 704 is between at least one of the set of bit lines BL, the set of bit line bars BLB or the set of read bit lines RBL and at least one memory cell 701a, 701b, 701c or 701d of memory cell array 701.

In some embodiments, via 704a is between bit line bar BLB[1] and memory cells 701a and 701c.

In some embodiments, via 704b is between bit line BL[1] and memory cell 701a, and via 704e is between bit line BL[1] and memory cell 701c.

In some embodiments, via 704g is between read bit line RBL[1] and memory cell 701a, and via 704i is between read bit line RBL[1] and memory cell 701c.

In some embodiments, via 704h is between read bit line RBL[2] and memory cell 701b, and via 704j is between read bit line RBL[2] and memory cell 701d.

In some embodiments, via 404d is between bit line BL[2] and memory cells 701b and 701d.

In some embodiments, via 404c is between bit line bar BLB[2] and memory cell 701b, and via 404f is between bit line bar BLB[2] and memory cell 701d.

Other configurations, arrangements on other levels or quantities of vias in at least the set of vias 704 are within the scope of the present disclosure.

Other configurations of memory circuit 700A are within the scope of the present disclosure.

FIG. 7B is a schematic diagram of a memory circuit 700B, in accordance with some embodiments.

Memory circuit 700B relates to memory cell array 202 of FIG. 2B. Memory circuit 700B is an embodiment of region 201b of memory circuit 200B of FIG. 2B, and similar detailed description is therefore omitted. In some embodiments, memory circuit 700B is an embodiment of regions of memory circuit 200B other than region 201b of memory circuit 200B of FIG. 2B.

Memory circuit 700B is a variation of memory circuit 400C of FIG. 4C or memory circuit 700A of FIG. 7A, and similar detailed description is therefore omitted. In comparison with memory circuit 400C of FIG. 4C, a memory cell array 721 of FIG. 7B replaces memory cell array 421 of FIG. 4C, and similar detailed description is therefore omitted.

Memory circuit 700B comprises a memory cell array 721. Memory cell array 721 is similar to memory cell array 202 of FIG. 2B, memory cell array 421 of FIG. 4C or memory cell array 701 of FIG. 7A, and similar detailed description is therefore omitted.

Memory cell array 721 comprises memory cells 721a, 721b, 721c and 721d. In some embodiments, at least one of memory cell 721a, 721b, 721c or 721d is similar to at least one of memory cell 401a, 401b, 401c or 401d of memory cell array 401 of FIG. 4A or at least one of memory cell 411a, 411b, 411c or 411d of memory cell array 411 of FIG. 4B, and similar detailed description is therefore omitted.

Memory cell 721a (also labelled as “Cell1” in FIG. 7B) is in row 1 and column 1 of memory cell array 721, and is designated in FIG. 7B as “r1c1.” Memory cell 721b (also labelled as “Cell2” in FIG. 7B) is in row 2 and column 1 of memory cell array 721, and is designated in FIG. 7B as “r2c1.” Memory cell 721c (also labelled as “Cell3” in FIG. 7B) is in row 1 and column 2 of memory cell array 721, and is designated in FIG. 7B as “r1c2.” Memory cell 721d (also labelled as “Cell4” in FIG. 7B) is in row 2 and column 2 of memory cell array 721, and is designated in FIG. 7B as “r2c2.” In some embodiments, a portion (e.g., memory cell portion 721b2) of memory cell 721b is located in r1c1. In some embodiments, a portion (e.g., memory cell portion 721d2) of memory cell 721d is located in r1c2.

Memory cell array 721 is shown as a 2×2 memory cell array in FIG. 7B. Other numbers of rows and columns are within the scope of the present disclosure.

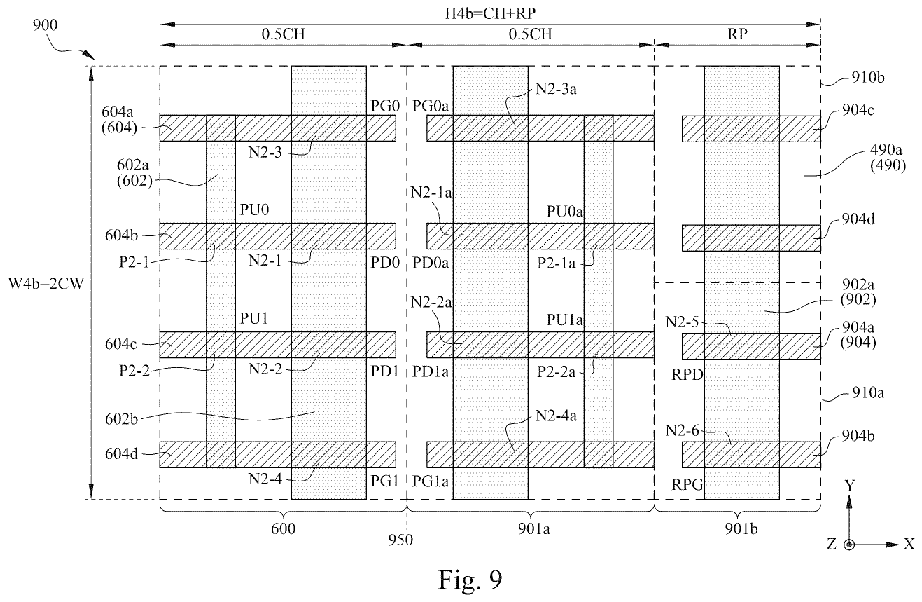

Memory cell array 721 has a height H3b in the first direction X. In some embodiments, the height H3b is equal to 2CH+2RP, where 0.5CH is the scaled cell height in the first direction X of at least one of memory cell 721b or 721d in memory cell array 721, and where RP is a cell height in the first direction X of at least a region 901b in FIG. 9.

Memory cell array 721 has a width W3b in the second direction Y. In some embodiments, the width W3b is equal to 2CW, where 2CW is the scaled cell width in the second direction Y of at least one of memory cell 721a, 721b, 721c, or 721d in memory cell array 721.

In some embodiments, memory cell array 721 has a width in the second direction Y equal to 4 contacted polysilicon pitches (e.g., 4CPP).

In some embodiments, memory cell array 721 has an aspect ratio AR1a that is equal to ((CH+RP)/CW). (e.g., W3b/H3b).

In some embodiments, memory cells 721a, 721b, 721c and 721d are similar to corresponding memory cells MCB in the same corresponding rows and same corresponding columns of region 201b of FIG. 2B, and similar detailed description is therefore omitted. In some embodiments, each of memory cells 721a, 721b, 721c and 721d is memory cell 300B of FIG. 3B, and similar detailed description is therefore omitted.

In some embodiments, memory cell 721b is divided into memory cell portion 721b1 and memory cell portion 721b2. In some embodiments, memory cell portion 721b2 is located in a corner of a region 750. In some embodiments, memory cell portion 721b1 corresponds to memory circuit 600 in FIG. 9 and region 901a in FIG. 9. In some embodiments, memory cell portion 721b2 corresponds to region 910a or 910b in FIG. 9.

In some embodiments, memory cell 721d is divided into memory cell 721dl and memory cell 721d2. In some embodiments, memory cell portion 721d2 is located in a corner of a region 752. In some embodiments, memory cell portion 721dl corresponds to memory circuit 600 in FIG. 9 and region 901a in FIG. 9. In some embodiments, memory cell portion 721d2 corresponds to region 910a or 910b in FIG. 9.

Memory circuit 700B further comprises the set of bit lines BL, the set of bit line bars BLB, the set of read bit lines RBL and at least one of the set of write word lines WWL or the set of read word lines RWL.

Bit line BL[1] overlaps memory cell 721a. Bit line BL[1] is electrically coupled to memory cell 721a by a via 724a. In some embodiments, bit line BL[1] is electrically coupled to memory cell 721a and memory cell 721b (not shown), and the bit line BL[1] is shared between memory cell 721a and memory cell 721b. Stated differently, neighboring memory cells (e.g., memory cells 721b and 721a) in memory circuit 700B are configured to share BLs with each other.

Bit line bar BLB[1] overlaps memory cell 721b.

Bit line bar BLB[1] is electrically coupled to memory cell 721b by a via 724c. In some embodiments, bit line bar BLB[1] is electrically coupled to memory cell 721b and memory cell 721a (not shown), and the bit line bar BLB[1] is shared between memory cell 721b and memory cell 721a.

Stated differently, neighboring memory cells (e.g., memory cells 721b and 721a) in memory circuit 700B are configured to share BLBs with each other.

Bit line bar BLB [2] overlaps memory cell 721d. Bit line bar BLB [2] is electrically coupled to memory cell 721d by a via 724g. In some embodiments, bit line bar BLB[2] is electrically coupled to memory cell 721d and memory cell 721c (not shown), and the bit line bar BLB[2] is shared between memory cell 721d and memory cell 721c. Stated differently, neighboring memory cells (e.g., memory cells 721d and 721c) in memory circuit 700B are configured to share BLBs with each other.

Bit line BL[2] overlaps memory cell 721c. Bit line BL[2] is electrically coupled to memory cell 721c by a via 724e. In some embodiments, bit line BL[2] is electrically coupled to memory cell 721c and memory cell 721d (not shown), and the bit line BL[2] is shared between memory cell 721c and memory cell 721d. Stated differently, neighboring memory cells (e.g., memory cells 721d and 721c) in memory circuit 700B are configured to share BLs with each other.

Other configurations, arrangements on other metal layers or quantities of bit lines in the set of bit lines BL are within the scope of the present disclosure.

Other configurations, arrangements on other metal layers or quantities of bit line bars in the set of bit line bars BLB are within the scope of the present disclosure.

Read bit line RBL[1] overlaps memory cell 721a and memory cell portion 721b2. Read bit line RBL[1] is electrically coupled to memory cell 721a by a via 724b. Read bit line RBL[1] is electrically coupled to memory cell portion 721b2 of memory cell 721b by a via 724d.

In some embodiments, read bit line RBL[1] is electrically coupled to memory cell 721a and memory cell 721b, and the read bit line RBL[1] is shared between memory cell 721a and memory cell 721b. Stated differently, neighboring memory cells (e.g., memory cells 721b and 721a) in memory circuit 700B are configured to share RBLs with each other.

Read bit line RBL[2] overlaps memory cell 721c and memory cell portion 721d2. Read bit line RBL[2] is electrically coupled to memory cell 721c by a via 724f. Read bit line RBL[2] is electrically coupled to memory cell portion 721d2 of memory cell 721d by a via 724h.

In some embodiments, read bit line RBL[2] is electrically coupled to memory cell 721c and memory cell 721d, and the read bit line RBL[2] is shared between memory cell 721c and memory cell 721d. Stated differently, neighboring memory cells (e.g., memory cells 721c and 721d) in memory circuit 700B are configured to share RBLs with each other.

Other configurations, arrangements on other metal layers or quantities of read bit lines in the set of read bit lines RBL are within the scope of the present disclosure.

Write word line WWL[1] or read word line RWL[1] overlaps memory cells 721a, 721b, 721c and 721d. Write word line WWL[1] or read word line RWL[1] is electrically coupled to memory cell 721b by a via 722b. Write word line WWL[1] or read word line RWL[1] is electrically coupled to memory cell 721c by a via 722d. Write word line WWL[1] or read word line RWL[1] is electrically coupled to memory cell 721d by a via 722f.

Write word line WWL[1] or read word line RWL[1] overlaps memory cells 721a, 721b, 721c and 721d. Write word line WWL[2] or read word line RWL[2] is electrically coupled to memory cell 721a by a via 722a. Write word line WWL[2] or read word line RWL[2] is electrically coupled to memory cell 721c by a via 722c. Write word line WWL[2] or read word line RWL[2] is electrically coupled to memory cell 721d by a via 722e.

In some embodiments, by interleaving the set of WWLs/RWLs and sharing BLs or BLBs between neighboring memory cells causes memory circuit 700B to have a same aspect ratio ((CH+RP)/CW) as memory circuit 700A, resulting in a more flexible cell compared to other approaches.

Other configurations, arrangements on other metal layers or quantities of word lines in the set of word lines WL are within the scope of the present disclosure.

Memory circuit 700B further comprises one or more of vias 722a, 722b, 722c, 722d, 722e or 722f (collectively referred to as a “set of vias 722”).

In some embodiments, the set of vias 722 is similar to the set of vias 702 of FIG. 7A, and similar detailed description is therefore omitted. In some embodiments, at least one of vias 722a, 722b, 722c, 722d, 722e or 722f is similar to at least one of vias 402a, 402b, 402c, 402d, 402e or 402f, and similar detailed description is therefore omitted.

In some embodiments, via 722b is between write word line WWL[1] or read word line RWL[1] and memory cell 721b. In some embodiments, via 722d is between write word line WWL[1] or read word line RWL[1] and memory cell 721c. In some embodiments, via 722f is between write word line WWL[1] or read word line RWL[1] and memory cell 721d.

In some embodiments, via 722a is between write word line WWL[2] or read word line RWL[2] and memory cell 721a. In some embodiments, via 722c is between write word line WWL[2] or read word line RWL[2] and memory cell 721c. In some embodiments, via 722e is between write word line WWL[2] or read word line RWL[2] and memory cell 721d.

Other configurations, arrangements on other levels or quantities of vias in at least the set of vias 722 are within the scope of the present disclosure.

Memory circuit 700B further comprises one or more of vias 724a, 724b, 724c, 724d, 724e, 724f, 724g or 724h (collectively referred to as a “set of vias 724”).

In some embodiments, the set of vias 724 is similar to the set of vias 404 of FIG. 4A or the set of vias 704 of FIG. 7A, and similar detailed description is therefore omitted. In some embodiments, at least one of vias 724a, 724b, 724c, 724d, 724e, 724f, 724g or 724h is similar to at least one or more of vias 404a, 404b, 404c, 404d, 404e or 404f of the set of vias 404 of FIG. 4A or at least one or more of vias 704a, 704b, 404c, 404d, 704e, 404f, 704g, 704h, 704i or 704j of the set of vias 704 of FIG. 7A, and similar detailed description is therefore omitted.

In some embodiments, via 724a is between bit line BL[1] and memory cell 721a.

In some embodiments, via 724c is between bit line bar BLB[1] and memory cell 721b.

In some embodiments, via 724b is between read bit line RBL[1] and memory cell 721a.

In some embodiments, via 724d is between read bit line RBL[1] and memory cell portion 721b2 of memory cell 721b.

In some embodiments, via 724f is between read bit line RBL[2] and memory cell 721c.

In some embodiments, via 724h is between read bit line RBL[2] and memory cell portion 721d2 of memory cell 721d.

In some embodiments, via 724e is between bit line BL[2] and memory cell 721c.

In some embodiments, via 724g is between bit line bar BLB[2] and memory cell 721d.

Other configurations, arrangements on other levels or quantities of vias in at least the set of vias 724 are within the scope of the present disclosure.

Other configurations of memory circuit 700B are within the scope of the present disclosure.

FIG. 8 is a corresponding schematic diagram of a corresponding memory circuit 800, in accordance with some embodiments.

Memory circuit 800 relates to memory cell array 202 of FIG. 2B. Memory circuit 800 is an embodiment of one memory cell (e.g., memory cell 701a, 701b, 701c or 701d) of memory cell array 701 of FIG. 7A, and similar detailed description is therefore omitted.

Memory circuit 800 is a variation of memory circuit 500A of FIG. 5A, and similar detailed description is therefore omitted. In comparison with memory circuit 500A of FIG. 5A, memory circuit 800 further includes a region 810, and similar detailed description is therefore omitted.

Memory circuit 800 is manufactured by a corresponding layout design similar to memory circuit 800.

Memory circuit 800 has a height H4a in the first direction X. In some embodiments, the height H4a is equal to CH+RP, where CH is a scaled cell height in the first direction X of at least circuit 800, and where RP is a cell height in the first direction X of at least region 810.

Memory circuit 800 has a width W4a in the second direction Y. In some embodiments, the width W4a is equal to CW, where CW is a scaled cell width in the second direction Y of at least memory circuit 800.

In some embodiments, memory circuit 800 has a width in the second direction Y equal to 2 contacted polysilicon pitches (e.g., 2CPP).

In some embodiments, memory circuit 800 is usable as at least one memory cell 701a, 701b, 701c or 701d of memory cell array 701 of FIG. 7A, and similar detailed description is therefore omitted.

Memory circuit 800 includes memory circuit 500A and region 810. Memory circuit 500A is adjacent or directly next to region 810.

Region 810 has a height RP in the first direction X.

Region 810 includes an active region 802e.

The set of active regions 802 includes one or more of active regions 502a, 502b, 502c, 502d or 802e.

In some embodiments, the set of active regions 802 is similar to the set of active regions 502 of FIG. 5A, and similar detailed description is therefore omitted. In some embodiments, active region 802e is similar to one or more of active regions 502a, 502b, 502c or 502d of the set of active regions 502 of FIG. 5A, and similar detailed description is therefore omitted.

In some embodiments, the set of active regions 802 is manufactured by a corresponding set of active region patterns (not shown) of a corresponding layout design of memory circuit 500A-500B, 600, 800 or 900. In some embodiments, active region 802e of the set of active regions 802 is manufactured by corresponding active region patterns (not shown) of the set of active region patterns (not shown) of a corresponding layout design of memory circuit 500A-500B, 600, 800 or 900.

In some embodiments, active region 802e is source and drain regions of NFET transistors of at least one of memory cell 300B or memory circuit 400A, 400B, 400C, 500A-500B, 600, 700A, 700B, 800, 900, 1000, 1100, 1200, 1300, 1400 or 1500.

In some embodiments, active region 802e is source and drain regions of PFET transistors of at least one of memory cell 300B or memory circuit 400A, 400B, 400C, 500A-500B, 600, 700A, 700B, 800, 900, 1000, 1100, 1200, 1300, 1400 or 1500.

Other configurations, arrangements on other levels or quantities of regions in the set of active regions 802 are within the scope of the present disclosure.

Region 810 further includes at least one of gates 804e or 804f.

The set of gates 804 includes one or more of gates 504a, 504b, 504c, 504d, 804e or 804f.

In some embodiments, the set of gates 804 is similar to the set of gates 504 of FIG. 5A, and similar detailed description is therefore omitted. In some embodiments, at least one or more of gates 804e or 804f is similar to one or more of gates 504a, 504b, 504c or 504d of the set of gates 504 of FIG. 5A, and similar detailed description is therefore omitted.

In some embodiments, the set of gates 804 is manufactured by a corresponding set of gate patterns (not shown) of a corresponding layout design of memory circuit 500A-500B, 600, 800 or 900.

In some embodiments, gates 804e or 804f of the set of gates 804 are manufactured by corresponding gate patterns (not shown) of the set of gate patterns (not shown) of a corresponding layout design of memory circuit 500A-500B, 600, 800 or 900.

In some embodiments, each of the gates in the set of gates 804 is shown in FIGS. 5,6, 8 and 9 with labels “N2-1, P2-1, N2-2, P2-2, N2-3, N2-4, N2-5, N2-6” that identify corresponding transistors of FIGS. 3B, 7A and 7B, and are omitted for brevity.

Other configurations, arrangements on other levels or quantities of gates in the set of gates 804 are within the scope of the present disclosure.

In some embodiments, at least one via of the set of vias 702 is electrically coupled to at least one gate of the set of gates 804. In some embodiments, at least one via of the set of vias 704 is electrically coupled to at least one gate of the set of gates 804.

In some embodiments, at least one via of the set of vias 702 is electrically coupled to at least one active region of the set of active regions 802. In some embodiments, at least one via of the set of vias 704 is electrically coupled to at least one active region of the set of active regions 802.

Other configurations of memory circuit 800 are within the scope of the present disclosure.

FIG. 9 is a corresponding schematic diagram of a corresponding memory circuit 900, in accordance with some embodiments.

Memory circuit 900 relates to memory cell array 202 of FIG. 2B. Memory circuit 900 is an embodiment of memory cells 721b and 721a of memory cell array 721 of FIG. 7B, and similar detailed description is therefore omitted.

Memory circuit 900 is a variation of memory circuit 600 of FIG. 6, and similar detailed description is therefore omitted. In comparison with memory circuit 600 of FIG. 6, memory circuit 900 further includes a region 901a and a region 901b, and similar detailed description is therefore omitted.

Memory circuit 900 is manufactured by a corresponding layout design similar to memory circuit 900.

Memory circuit 900 has a height H4b in the first direction X. In some embodiments, the height H4b is equal to CH+RP, where CH is a scaled cell height in the first direction X of at least circuit 900, and where RP is a cell height in the first direction X of at least region 901b.

Memory circuit 900 has a width W4b in the second direction Y. In some embodiments, the width W4b is equal to 2CW, where CW is a scaled cell width in the second direction Y of at least memory circuit 900.

In some embodiments, memory circuit 900 has a width in the second direction Y equal to 4 contacted polysilicon pitches (e.g., 4CPP).

In some embodiments, memory circuit 900 is usable as memory cell 721a and 721b of memory cell array 721 of FIG. 7B, and similar detailed description is therefore omitted. In some embodiments, memory circuit 900 is usable as memory cell 721c and 721d of memory cell array 721 of FIG. 7B, and similar detailed description is therefore omitted.

Memory circuit 900 includes memory circuit 600, region 901a and region 901b. Memory circuit 600 is adjacent or directly next to region 901a. Region 901a is adjacent to region 901b. Region 901a is between memory circuit 600 and region 901b.

In some embodiments, region 901a is a mirror image of memory circuit 600 with respect to a gridline 950 in the second direction Y, and similar detailed description is therefore omitted. Gridline 950 extends in the second direction Y.

Region 901b has a height RP in the first direction X.

Region 901b includes a region 910a and a region 910b.

Each of region 910a and region 910b have a width CW in the second direction Y.

Region 910a includes an active region 902a.

The set of active regions 902 includes active region 902a.

In some embodiments, the set of active regions 902 is similar to the set of active regions 602 of FIG. 6, and similar detailed description is therefore omitted. In some embodiments, active region 902a is similar to one or more of active regions 602a, 602b, 602c or 602d of the set of active regions 602 of FIG. 6, and similar detailed description is therefore omitted.

In some embodiments, the set of active regions 902 is manufactured by a corresponding set of active region patterns (not shown) of a corresponding layout design of memory circuit 500A-500B, 600, 800 or 900. In some embodiments, active region 902a of the set of active regions 902 is manufactured by corresponding active region patterns (not shown) of the set of active region patterns (not shown) of a corresponding layout design of memory circuit 500A-500B, 600, 800 or 900.

In some embodiments, active region 902a is source and drain regions of NFET transistors of at least one of memory cell 300B or memory circuit 400A, 400B, 400C, 500A-500B, 600, 700A, 700B, 800, 900, 1000, 1100, 1200, 1300, 1400 or 1500.

In some embodiments, active region 902a is source and drain regions of PFET transistors of at least one of memory cell 300B or memory circuit 400A, 400B, 400C, 500A-500B, 600, 700A, 700B, 800, 900, 1000, 1100, 1200, 1300, 1400 or 1500.

Other configurations, arrangements on other levels or quantities of regions in the set of active regions 902 are within the scope of the present disclosure.

Region 910a further includes at least one of gates 904a or 904b.

The set of gates 904 includes one or more of gates 904a, 904b, 904c or 904d.

In some embodiments, the set of gates 904 is similar to the set of gates 604 of FIG. 6, and similar detailed description is therefore omitted. In some embodiments, at least one or more of gates 904a, 904b, 904c or 904d is similar to one or more of gates 604a, 604b, 604c or 604d of the set of gates 604 of FIG. 6, and similar detailed description is therefore omitted.

In some embodiments, the set of gates 904 is manufactured by a corresponding set of gate patterns (not shown) of a corresponding layout design of memory circuit 500A-500B, 600, 800 or 900.

In some embodiments, gates 904a, 904b, 904c or 904d of the set of gates 904 are manufactured by corresponding gate patterns (not shown) of the set of gate patterns (not shown) of a corresponding layout design of memory circuit 500A-500B, 600, 800 or 900.

In some embodiments, each of the gates in the set of gates 904 is shown in FIGS. 5,6, 8 and 9 with labels “N2-1, P2-1, N2-2, P2-2, N2-3, N2-4, N2-5, N2-6” that identify corresponding transistors of FIGS. 3B, 7A and 7B, and are omitted for brevity.

Other configurations, arrangements on other levels or quantities of gates in the set of gates 904 are within the scope of the present disclosure.

Region 910b includes a portion of active region 902a and at least one of gates 904c or 904d.

In some embodiments, at least one of gates 904c or 904d is a gate of a dummy transistor. In some embodiments, a portion of active region 902a that is located in region 910b is part of the dummy transistor.

In some embodiments, at least one via of the set of vias 722 is electrically coupled to at least one gate of the set of gates 904. In some embodiments, at least one via of the set of vias 724 is electrically coupled to at least one gate of the set of gates 904.

In some embodiments, at least one via of the set of vias 722 is electrically coupled to at least one active region of the set of active regions 902. In some embodiments, at least one via of the set of vias 724 is electrically coupled to at least one active region of the set of active regions 902.

Other configurations of memory circuit 900 are within the scope of the present disclosure.

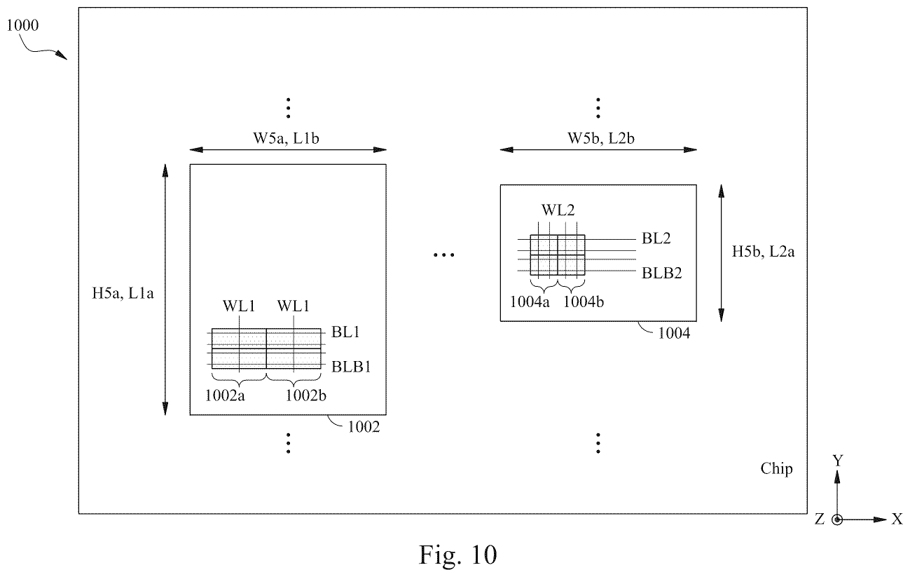

FIG. 10 is a schematic diagram of a memory circuit 1000, in accordance with some embodiments.

In some embodiments, memory circuit 1000 is an integrated circuit chip. In some embodiments, memory circuit 1000 is an embodiment of memory circuit 100 of FIG. 1, and similar detailed description is therefore omitted.

Memory circuit 1000 includes a memory circuit 1002 and a memory circuit 1004.

In some embodiments, memory circuit 1000 includes memory circuits of different types, and therefore memory circuit 1000 is referred to as a “mixed cell.”

In some embodiments, memory circuit 1002 is memory circuit 400B of FIG. 4B, and similar detailed description is therefore omitted. In these embodiments, memory circuit 1002 is memory circuit 400B of FIG. 4B, includes one or more copies of memory circuit 600 of FIG. 6, and similar detailed description is therefore omitted. In some embodiments, memory circuit 1002 is memory circuit 200A of FIG. 2A, and similar detailed description is therefore omitted. In some embodiments, memory circuit 1002 includes one or more regions of memory circuit 200A of FIG. 2A similar to region 201a, and similar detailed description is therefore omitted.

In some embodiments, memory circuit 1004 is memory circuit 400C of FIG. 4C, and similar detailed description is therefore omitted. In these embodiments, memory circuit 1004 includes one or more copies of memory circuit 600 of FIG. 6, and similar detailed description is therefore omitted. In some embodiments, memory circuit 1004 is memory circuit 200A of FIG. 2A, and similar detailed description is therefore omitted. In some embodiments, memory circuit 1004 includes one or more regions of memory circuit 200A of FIG. 2A similar to region 201a, and similar detailed description is therefore omitted.

Memory circuit 1000 is shown as including one memory circuit 1002 and one memory circuit 1004. In some embodiments, memory circuit 1000 includes at least two or more of memory circuit 1002. In some embodiments, memory circuit 1000 includes at least two or more of memory circuit 1004. Other positions in memory circuit 1000 for at least one of memory circuit 1002 or memory circuit 1004 are within the scope of the present disclosure.

In some embodiments, memory circuit 1002 is generated by a first memory compiler. In some embodiments, memory circuit 1002 is generated by an SRAM memory compiler. Other types of memory compilers are within the scope of the present disclosure.

In some embodiments, memory circuit 1004 is generated by a second memory compiler. In some embodiments, memory circuit 1004 is generated by an SRAM memory compiler. Other types of memory compilers are within the scope of the present disclosure.

Memory circuit 1002 has a height H5a in the second direction Y. In some embodiments, the height H5a is equal to the height H1b of memory circuit 400B of FIG. 4B.

Memory circuit 1002 has a width W5a in the first direction X. In some embodiments, the width W5a is equal to the width W1b of memory circuit 400B of FIG. 4B.

Memory circuit 1004 has a height H5b in the second direction Y. In some embodiments, the height H5b is equal to the height H1c of memory circuit 400C of FIG. 4C.

Memory circuit 1004 has a width W5b in the first direction X. In some embodiments, the width W5b is equal to the width W1c of memory circuit 400C of FIG. 4C.

In some embodiments, the height H5a is different from the height H5b. In some embodiments, the height H5a is the same as the height H5b.

In some embodiments, the width W5a is different from the width W5b. In some embodiments, the width W5a is the same as the width W5b.

Memory circuit 1002 includes a memory cell 1002a, a memory cell 1002b, a set of bit lines BL1, a set of bit line bars BLB1 and a set of word lines WL1.

In some embodiments, memory cell 1002a is at least one of memory cell 411a, 411b, 411c or 411d in one of column 1 or 2, and memory cell 1002b is at least another of memory cell 411a, 411b, 411c or 411d in the other of column 1 or 2. For ease of illustration, memory circuit 1002 is shown as including 2 memory cells (memory cell 1002a and 1002b). However, other numbers of memory cells in memory circuit 1002 are within the scope of the present disclosure.

For ease of illustration, memory circuit 1002 is shown as including 2 columns of memory cells and 2 rows of memory cells. However, other numbers of rows or columns of memory cells in memory circuit 1002 are within the scope of the present disclosure.

Memory circuit 1004 includes a memory cell 1004a, a memory cell 1004b, a set of bit lines BL2, a set of bit line bars BLB2 and a set of word lines WL2.

In some embodiments, memory cell 1004a is at least one of memory cell 421a, 421b, 421c or 421d in one of column 1 or 2, and memory cell 1004b is at least another of memory cell 421a, 421b, 421c or 421d in the other of column 1 or 2. For ease of illustration, memory circuit 1004 is shown as including 2 memory cells (memory cell 1004a and 1004b). However, other numbers of memory cells in memory circuit 1004 are within the scope of the present disclosure.

For ease of illustration, memory circuit 1004 is shown as including 2 columns of memory cells and 2 rows of memory cells. However, other numbers of rows or columns of memory cells in memory circuit 1004 are within the scope of the present disclosure.

In some embodiments, the set of bit lines BL1 or BL2 of one or more of FIG. 10, 11 or 12 are similar to the set of bit lines BL of FIGS. 4A-4C, 6, 7A-7B, 8 and 9, and similar detailed description is therefore omitted.

In some embodiments, the set of bit line bars BLB1 or BLB2 of one or more of FIG. 10, 11 or 12 are similar to the set of bit line bars BLB of FIGS. 4A-4C, 6, 7A-7B, 8 and 9, and similar detailed description is therefore omitted.

In some embodiments, the set of word lines WL1 or WL2 of one or more of FIG. 10, 11 or 12 are similar to the set of word lines WL of FIGS. 4A-4C, 6, 7A-7B, 8 and 9, and similar detailed description is therefore omitted.

The set of word lines WL1 has a length L1a in the second direction Y.

The set of bit lines BL1 and the set of bit line bars BLB1 have a length L1b in the first direction X.

In some embodiments, the length L1a of the set of word lines WL1 is greater than the length L1b of the set of bit lines BL1 and the length L1b of the set of bit line bars BLB1. In some embodiments, memory circuits such as memory circuit 1002 are referred to as “a tall cell” (and also has a “tall footprint”) since the length L1a of the set of word lines WL1 is greater than the length L1b of the set of bit lines BL1 and the length L1b of the set of bit line bars BLB1. In some embodiments, since the length L1a of the set of word lines WL1 is greater than the length L1b of the set of bit lines BL1 and the length L1b of the set of bit line bars BLB1, the set of word lines WL1 are referred to as “long.”

The set of word lines WL2 has a length L2a in the second direction Y.

The set of bit lines BL2 and the set of bit line bars BLB2 have a length L2b in the first direction X.

In some embodiments, the length L2a of the set of word lines WL2 is less than the length L2b of the set of bit lines BL2 and the length L2b of the set of bit line bars BLB2. In some embodiments, memory circuits such as memory circuit 1004 are referred to as “a long cell” (and also has a “long footprint”) since the length L2a of the set of word lines WL2 is less than the length L2b of the set of bit lines BL2 and the length L2b of the set of bit line bars BLB2. In some embodiments, since the length L2a of the set of word lines WL2 is less than the length L2b of the set of bit lines BL2 and the length L2b of the set of bit line bars BLB2, the set of bit lines BL2 or the set of bit line bars BLB2 are referred to as “long.”

In some embodiments, the length L1a of the set of word lines WL1 is greater than the length L2a of the set of word lines WL2.

In some embodiments, at least one of the length L1b of the set of bit lines BL1 or the length L1b of the set of bit line bars BLB1 is less than at least one of the length L2b of the set of bit lines BL2 or the length L2b of the set of bit line bars BLB2.

In some embodiments, memory circuit 1000 includes different memory circuits (e.g., memory circuit 1002 and memory circuit 1004) with different corresponding dimensions (e.g., tall cells and long cells) in the same direction, and therefore memory circuit 1000 is referred to as a “mixed cell arrangement.” In some embodiments, memory circuits (e.g., memory circuit 1002 and memory circuit 1004) with different corresponding dimensions in the same direction have different corresponding resistance and capacitance characteristics (e.g., as shown below in Table 1). In some embodiments, the different characteristics of memory circuit 1000 includes one or more of a resistance of the bit line or bit line bar, a resistance of the word line, a capacitance of the bit line or bit line bar or a capacitance of the word line.

In some embodiments, by using memory circuit 1002 and memory circuit 1004 with different corresponding characteristics (e.g., the resistance of the bit line or bit line bar, resistance of the word line, the capacitance of the bit line or bit line bar, capacitance of the word line), a design of memory circuit 1000 is more flexible than other approaches with the same type of cell with the same type of characteristics, and the performance of memory circuit 1000 is greater than other approaches. In some embodiments, memory circuits (e.g., memory circuit 1002 and memory circuit 1004) with different corresponding dimensions in the same direction have optimized corresponding resistance and capacitance characteristics compared with other approaches with the same type of cell with the same type of characteristic, and results in better performance than other approaches.

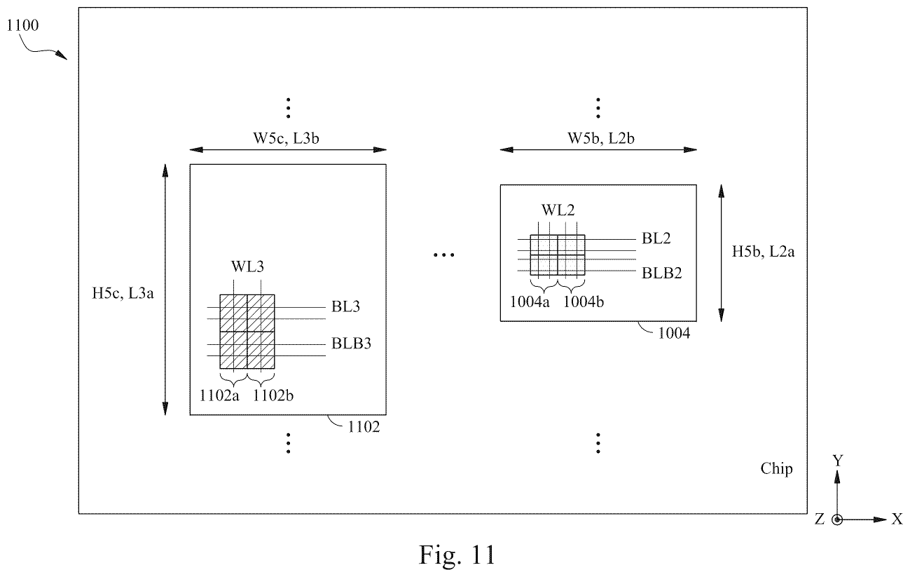

In some embodiments, a word line resistance (WL-R), a word line capacitance (WL-C), a bit line or bit line bar resistance (BL-R), a bit line or bit line bar capacitance (BL-C) of each of memory circuit 1002 (e.g., labelled as “4CPP”), memory circuit 1004 (e.g., labelled as “Pseudo-4CPP”) and memory circuit 1102 (e.g., labelled as “2CPP” and is shown in FIG. 11) are shown in Table 1.

Table 1 is a table of different cells and parameters of memory circuit 1002 (e.g., labelled as “4CPP”), memory circuit 1004 (e.g., labelled as “Pseudo-4CPP”) and memory circuit 1102 (e.g., labelled as “2CPP” and is shown in FIG. 11).

TABLE 1

| Cell | 2CPP | 4CPP | Pseudo-4CPP |
|---|---|---|---|
| Cell Height (equivalent) | Reference | 0.5x | 1x |
| Cell Width (equivalent) | Reference | 2x | 1x |
| BL-R | Reference | 1x | 0.5x |
| BL-C | Reference | 2x | 1x |
| WL-R | Reference | 0.5x | 1.2x |
| WL-C | Reference | 0.5x | 1.2x |

Table 1 comprises 7 rows and 4 columns. Row 1 comprises different cell types. Row 2 comprises an equivalent cell height for the corresponding cells. Row 3 comprises an equivalent cell width for the corresponding cells. Row 4 comprises a bit line or bit line bar resistance (BL-R) for the corresponding cells relative to the 2CPP cell. Row 5 comprises a bit line or bit line bar capacitance (BL-C) for the corresponding cells relative to the 2CPP cell. Row 6 comprises a word line resistance (WL-R) for the corresponding cells relative to the 2CPP cell. Row 7 comprises a word line capacitance (WL-C) for the corresponding cells relative to the 2CPP cell. Other numbers of columns or rows in table 1 are within the scope of the present disclosure.

In some embodiments, the cell entry labelled as “2CPP” in Table 1 includes one or more memory circuits of memory circuit 400A of FIG. 4A, memory circuit 500A of FIG. 5A, memory circuit 700A of FIG. 7A or memory circuit 800 of FIG. 8, and similar detailed description is therefore omitted.

In some embodiments, the cell entry labelled as “4CPP” in Table 1 includes one or more memory circuits of memory circuit 400B of FIG. 4B or memory circuit 600 of FIG. 6, and similar detailed description is therefore omitted.

In some embodiments, the cell entry labelled as “Pseudo-4CPP” in Table 1 includes one or more memory circuits of memory circuit 400C of FIG. 4C, memory circuit 600 of FIG. 6, memory circuit 700B of FIG. 7B or memory circuit 900 of FIG. 9, and similar detailed description is therefore omitted.

As shown in Table 1, memory circuit 1002 (e.g., labelled as “4CPP”) has reduced WL-R or WL-C characteristics compared with memory circuit 1004 (e.g., labelled as “Pseudo-4CPP”).

As shown in Table 1, memory circuit 1004 (e.g., labelled as “Pseudo-4CPP”) has reduced BL-R or BL-C characteristics compared with memory circuit 1002 (e.g., labelled as “4CPP”).

In some embodiments, memory circuit 1002 is useable for an SRAM compiler with tall cells or a tall footprint, and the set of word lines WL1 of memory circuit 1002 are also referred to as “long” as discussed above. For example, in some embodiments, since memory circuit 1002 is useable for an SRAM compiler with tall cells or a tall footprint (e.g., long word lines WL1), a memory circuit design with reduced WL-R or WL-C characteristics (e.g., 4CPP cell in Table 1) is used over a memory circuit design with reduced BL-R characteristics (e.g., Pseudo-4CPP cell in Table 1). Thus, even though memory circuit 1002 has a tall footprint (e.g., long word lines WL1), the reduced WL-R or WL-C characteristics of memory circuit 1002 compensate for the longer word lines WL1.

In some embodiments, memory circuit 1004 is useable for an SRAM compiler with long cells or a long footprint, and the set of bit lines BL2 or the set of bit lines BLB2 of memory circuit 1002 are also referred to as “long” as discussed above. For example, in some embodiments, since memory circuit 1004 is useable for an SRAM compiler with long cells or a long footprint (e.g., long bit lines BL2 or long bit line bars BLB2), a memory circuit design (e.g., Pseudo-4CPP cell in Table 1) with reduced BL-R characteristics is used over a memory circuit design with reduced WL-R or WL-C characteristics (e.g., 4CPP cell in Table 1). Thus, even though memory circuit 1004 has a long footprint (e.g., long bit lines BL2 or long bit line bars BLB2), the reduced BL-R characteristics of memory circuit 1004 compensate for the longer bit lines BL2 or bit line bars BLB2.

In some embodiments, engineering tradeoffs are made to balance WL-R, WL-C, BL-R and BL-C characteristics with each other for the selection of the cell type in memory circuit 1000. In some embodiments, combining cells of memory circuits with different corresponding characteristics allows memory circuit 1000 to have better overall performance than a memory circuit that has just a single type of memory cell with the same corresponding characteristics. For example, memory circuit 1002 is combined with memory circuit 1004 such that memory circuit 1000 includes the reduced WL-R or WL-C characteristics of memory circuit 1002 from Table 1 and the reduced BL-R characteristics of memory circuit 1004 from Table 1, in accordance with some embodiments. In some embodiments, combining different cells of memory circuits (e.g., memory circuits 1002 and 1004) with different corresponding characteristics into a same memory circuit such as memory circuit 1000 results in more fabrication steps during manufacturing of the memory circuit.

In some embodiments, by combining memory circuit 1002 with memory circuit 1004 in a same memory circuit 1000, the design of memory circuit 1000 is more flexible than other approaches with a same type of cell with the same type of characteristics, and the performance of memory circuit 1000 is greater than other approaches. In some embodiments, by combining memory circuit 1002 with memory circuit 1004 in a same memory circuit 1000, the resistance and capacitance characteristics of memory circuit 1000 are optimized compared with other approaches with the same type of cell with the same type of characteristics, and results in better performance than other approaches.

Other configurations of memory circuit 1000 are within the scope of the present disclosure.

FIG. 11 is a schematic diagram of a memory circuit 1100, in accordance with some embodiments.

Memory circuit 1100 is a variation of memory circuit 1000 of FIG. 10, and similar detailed description is therefore omitted. In comparison with memory circuit 1000 of FIG. 10, memory circuit 1002 of FIG. 10 is replaced by a memory circuit 1102 of FIG. 11, and similar detailed description is therefore omitted.

In some embodiments, memory circuit 1100 is an integrated circuit chip.

Memory circuit 1100 includes memory circuit 1102 and a memory circuit 1004.

In some embodiments, memory circuit 1100 includes memory circuits of different types, and therefore memory circuit 1100 is referred to as a “mixed cell.”

In some embodiments, memory circuit 1102 is memory circuit 400A of FIG. 4A, and similar detailed description is therefore omitted. In these embodiments, memory circuit 1102 is memory circuit 400A of FIG. 4A, includes one or more copies of memory circuit 500A of FIG. 5A, and similar detailed description is therefore omitted. In some embodiments, memory circuit 1102 is memory circuit 200A of FIG. 2A, and similar detailed description is therefore omitted. In some embodiments, memory circuit 1102 includes one or more regions of memory circuit 200A of FIG. 2A similar to region 201a, and similar detailed description is therefore omitted.

Memory circuit 1100 is shown as including one memory circuit 1102 and one memory circuit 1004. In some embodiments, memory circuit 1100 includes at least two or more of memory circuit 1102. In some embodiments, memory circuit 1100 includes at least two or more of memory circuit 1004. Other positions in memory circuit 1100 for at least one of memory circuit 1004 or memory circuit 1102 are within the scope of the present disclosure.

In some embodiments, memory circuit 1102 is generated by a third memory compiler. In some embodiments, memory circuit 1102 is generated by an SRAM memory compiler. Other types of memory compilers are within the scope of the present disclosure.

Memory circuit 1102 has a height H5c in the second direction Y. In some embodiments, the height H5c is equal to the height H1a of memory circuit 400A of FIG. 4A.

Memory circuit 1102 has a width W5c in the first direction X. In some embodiments, the width W5c is equal to the width W1a of memory circuit 400A of FIG. 4A.

In some embodiments, the height H5c is different from the height H5b. In some embodiments, the height H5c is the same as the height H5b.

In some embodiments, the width W5c is different from the width W5b. In some embodiments, the width W5c is the same as the width W5b.

Memory circuit 1102 includes a memory cell 1102a, a memory cell 1102b, a set of bit lines BL3, a set of bit line bars BLB3 and a set of word lines WL3.

In some embodiments, memory cell 1102a is at least one of memory cell 401a, 401b, 401c or 401d in one of column 1 or 2, and memory cell 1102b is at least another of memory cell 401a, 401b, 401c or 401d in the other of column 1 or 2. For ease of illustration, memory circuit 1102 is shown as including 2 memory cells (memory cell 1102a and 1102b). However, other numbers of memory cells in memory circuit 1102 are within the scope of the present disclosure.

For ease of illustration, memory circuit 1102 is shown as including 2 columns of memory cells and 2 rows of memory cells. However, other numbers of rows or columns of memory cells in memory circuit 1102 are within the scope of the present disclosure.

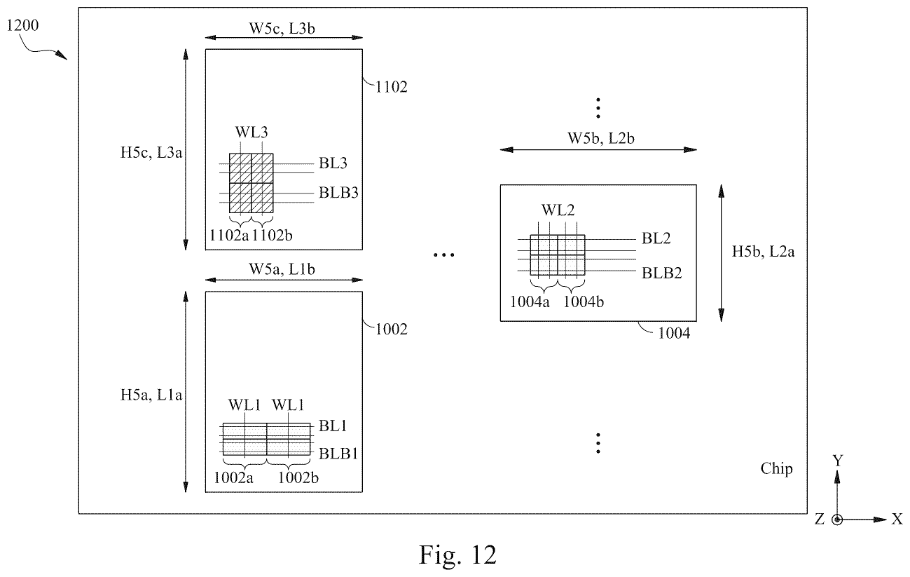

In some embodiments, the set of bit lines BL3 of one or more of FIG. 11 or 12 are similar to the set of bit lines BL of FIGS. 4A-4C, 6, 7A-7B, 8 and 9, and similar detailed description is therefore omitted.

In some embodiments, the set of bit line bars BLB3 of one or more of FIG. 11 or 12 are similar to the set of bit line bars BLB of FIGS. 4A-4C, 6, 7A-7B, 8 and 9, and similar detailed description is therefore omitted.

In some embodiments, the set of word lines WL3 of one or more of FIG. 11 or 12 are similar to the set of word lines WL of FIGS. 4A-4C, 6, 7A-7B, 8 and 9, and similar detailed description is therefore omitted.

The set of word lines WL3 has a length L3a in the second direction Y.

The set of bit lines BL3 and the set of bit line bars BLB3 have a length L3b in the first direction X.

In some embodiments, the length L3a of the set of word lines WL3 is greater than the length L3b of the set of bit lines BL3 and the length L3b of the set of bit line bars BLB3. In some embodiments, memory circuits such as memory circuit 1102 are referred to as “a tall cell” (and also has a “tall footprint”) since the length L3a of the set of word lines WL3 is greater than the length L3b of the set of bit lines BL3 and the length L3b of the set of bit line bars BLB3. In some embodiments, since the length L3a of the set of word lines WL3 is greater than the length L3b of the set of bit lines BL3 and the length L3b of the set of bit line bars BLB3, the set of word lines WL3 are referred to as “long.”

In some embodiments, the length L3a of the set of word lines WL3 is greater than the length L2a of the set of word lines WL2.

In some embodiments, at least one of the length L3b of the set of bit lines BL3 or the length L3b of the set of bit line bars BLB2 is less than at least one of the length L2b of the set of bit lines BL2 or the length L2b of the set of bit line bars BLB2.

In some embodiments, memory circuit 1100 includes different memory circuits (e.g., memory circuit 1102 and memory circuit 1004) with different corresponding dimensions (e.g., tall cells and long cells) in the same direction, and therefore memory circuit 1100 is referred to as a “mixed cell arrangement.” In some embodiments, memory circuits (e.g., memory circuit 1102 and memory circuit 1004) with different corresponding dimensions in the same direction have different corresponding resistance and capacitance characteristics (e.g., as shown above in Table 1).

In some embodiments, by using memory circuit 1102 and memory circuit 1004 with different corresponding characteristics (e.g., the resistance of the bit line or bit line bar, resistance of the word line, the capacitance of the bit line or bit line bar, capacitance of the word line), a design of memory circuit 1100 is more flexible than other approaches with the same type of cell with the same type of characteristics, and the performance of memory circuit 1100 is greater than other approaches. In some embodiments, memory circuits (e.g., memory circuit 1102 and memory circuit 1004) with different corresponding dimensions in the same direction have optimized corresponding resistance and capacitance characteristics compared with other approaches with the same type of cell with the same type of characteristic, and results in better performance than other approaches.

As shown above in Table 1, memory circuit 1102 (e.g., labelled as “2CPP”) has reduced WL-R or WL-C characteristics compared with memory circuit 1004 (e.g., labelled as “Pseudo-4CPP”).

As shown in Table 1, memory circuit 1004 (e.g., labelled as “Pseudo-4CPP”) has reduced BL-R characteristics compared with memory circuit 1102 (e.g., labelled as “2CPP”).

As shown in Table 1, memory circuit 1004 (e.g., labelled as “Pseudo-4CPP”) has similar BL-C characteristics compared with memory circuit 1102 (e.g., labelled as “2CPP”).

In some embodiments, memory circuit 1102 is useable for an SRAM compiler with tall cells or a tall footprint, and the set of word lines WL3 of memory circuit 1102 are also referred to as “long” as discussed above. For example, in some embodiments, since memory circuit 1102 is useable for an SRAM compiler with tall cells or a tall footprint (e.g., long word lines WL3), a memory circuit design with reduced WL-R or WL-C characteristics (e.g., 4CPP cell in Table 1) is used over a memory circuit design with reduced BL-R characteristics (e.g., Pseudo-4CPP cell in Table 1). Thus, even though memory circuit 1102 has a tall footprint (e.g., long word lines WL3), the reduced WL-R or WL-C characteristics of memory circuit 1102 compensate for the longer word lines WL3.

In some embodiments, combining cells of memory circuits with different corresponding characteristics allows memory circuit 1100 to have better overall performance than a memory circuit that has just a single type of memory cell with the same corresponding characteristics. For example, memory circuit 1102 is combined with memory circuit 1004 such that memory circuit 1100 includes the reduced WL-R or WL-C characteristics of memory circuit 1102 from Table 1 and the reduced BL-R characteristics of memory circuit 1004 from Table 1, in accordance with some embodiments. In some embodiments, combining different cells of memory circuits (e.g., memory circuits 1102 and 1004) with different corresponding characteristics into a same memory circuit such as memory circuit 1100 results in more fabrication steps during manufacturing of the memory circuit.

In some embodiments, by combining memory circuit 1102 with memory circuit 1004 in a same memory circuit 1100, the design of memory circuit 1100 is more flexible than other approaches with a same type of cell with the same type of characteristics, and the performance of memory circuit 1100 is greater than other approaches. In some embodiments, by combining memory circuit 1102 with memory circuit 1004 in a same memory circuit 1100, the resistance and capacitance characteristics of memory circuit 1100 are optimized compared with other approaches with the same type of cell with the same type of characteristics, and results in better performance than other approaches.

Other configurations of memory circuit 1100 are within the scope of the present disclosure.

FIG. 12 is a schematic diagram of a memory circuit 1200, in accordance with some embodiments.

Memory circuit 1200 is a variation of memory circuit 1000 of FIG. 10 and memory circuit 1100 of FIG. 11, and similar detailed description is therefore omitted. In comparison with memory circuit 1000 of FIG. 10, memory circuit 1200 of FIG. 12 further comprises memory circuit 1102 of FIG. 11, and similar detailed description is therefore omitted. In comparison with memory circuit 1100 of FIG. 11, memory circuit 1200 of FIG. 12 further comprises memory circuit 1002 of FIG. 10, and similar detailed description is therefore omitted.

In some embodiments, memory circuit 1200 is an integrated circuit chip.

Memory circuit 1200 includes memory circuit 1002, memory circuit 1004 and memory circuit 1102.

Memory circuit 1200 is shown as including one memory circuit 1002, one memory circuit 1004 and one memory circuit 1102. In some embodiments, memory circuit 1200 includes at least two or more of memory circuit 1002. In some embodiments, memory circuit 1200 includes at least two or more of memory circuit 1004. In some embodiments, memory circuit 1200 includes at least two or more of memory circuit 1102. Other positions in memory circuit 1200 for at least one of memory circuit 1002, memory circuit 1004 or memory circuit 1102 are within the scope of the present disclosure.

In some embodiments, at least one of height H5a, H5b or H5c is different from at least another of height H5a, H5b or H5c. In some embodiments, at least one of height H5a, H5b or H5c is the same as at least another of height H5a, H5b or H5c.

In some embodiments, at least one of width W5a, W5b or W5c is different from at least another of width W5a, W5b or W5c. In some embodiments, at least one of width W5a, W5b or W5c is the same as at least another of width W5a, W5b or W5c.

In some embodiments, at least one of length L1a, L2a or L3a is different from at least another of length L1a, L2a or L3a. In some embodiments, at least one of length L1a, L2a or L3a is the same as at least another of length L1a, L2a or L3a.

In some embodiments, at least one of length L1b, L2b or L3b is different from at least another of length L1b, L2b or L3b. In some embodiments, at least one of length L1b, L2b or L3b is the same as at least another of length L1b, L2b or L3b.

Memory circuit 1200 achieves one or more of the benefits discussed herein.

Other configurations of memory circuit 1200 are within the scope of the present disclosure.

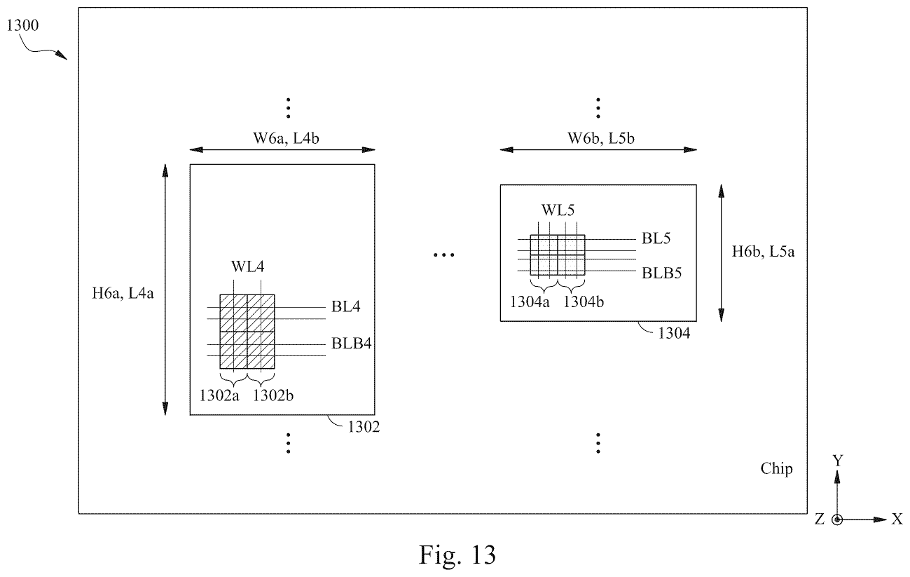

FIG. 13 is a schematic diagram of a memory circuit 1300, in accordance with some embodiments.

Memory circuit 1300 is a variation of memory circuit 1100 of FIG. 11, and similar detailed description is therefore omitted. In comparison with memory circuit 1100 of FIG. 11, memory circuit 1102 of FIG. 11 is replaced by a memory circuit 1302 of FIG. 13, memory circuit 1004 of FIG. 11 is replaced by a memory circuit 1304 of FIG. 13, and similar detailed description is therefore omitted.

In some embodiments, memory circuit 1300 is an integrated circuit chip.

Memory circuit 1300 includes memory circuit 1302 and memory circuit 1304.

In some embodiments, memory circuit 1300 includes memory circuits of different types, and therefore memory circuit 1300 is referred to as a “mixed cell.”

In some embodiments, memory circuit 1302 is memory circuit 700A of FIG. 7A, and similar detailed description is therefore omitted. In these embodiments, memory circuit 1302 is memory circuit 700A of FIG. 7A, includes one or more copies of memory circuit 800 of FIG. 8, and similar detailed description is therefore omitted. In some embodiments, memory circuit 1302 is memory circuit 200B of FIG. 2B, and similar detailed description is therefore omitted. In some embodiments, memory circuit 1302 includes one or more regions of memory circuit 200B of FIG. 2B similar to region 201b, and similar detailed description is therefore omitted.

In some embodiments, memory circuit 1304 is memory circuit 700B of FIG. 7B, and similar detailed description is therefore omitted. In these embodiments, memory circuit 1304 includes one or more copies of memory circuit 900 of FIG. 9, and similar detailed description is therefore omitted. In some embodiments, memory circuit 1304 is memory circuit 200B of FIG. 2B, and similar detailed description is therefore omitted. In some embodiments, memory circuit 1304 includes one or more regions of memory circuit 200B of FIG. 2B similar to region 201b, and similar detailed description is therefore omitted.

Memory circuit 1300 is shown as including one memory circuit 1302 and one memory circuit 1304. In some embodiments, memory circuit 1300 includes at least two or more of memory circuit 1302. In some embodiments, memory circuit 1300 includes at least two or more of memory circuit 1304. Other positions in memory circuit 1300 for at least one of memory circuit 1302 or memory circuit 1304 are within the scope of the present disclosure.

In some embodiments, memory circuit 1302 is generated by a fourth memory compiler. In some embodiments, memory circuit 1302 is generated by an SRAM memory compiler. Other types of memory compilers are within the scope of the present disclosure.

In some embodiments, memory circuit 1304 is generated by a fifth memory compiler. In some embodiments, memory circuit 1304 is generated by an SRAM memory compiler. Other types of memory compilers are within the scope of the present disclosure.

Memory circuit 1302 has a height H6a in the second direction Y. In some embodiments, the height H6a is equal to the height H3a of memory circuit 700A of FIG. 7A.

Memory circuit 1302 has a width W6a in the first direction X. In some embodiments, the width W6a is equal to the width W3a of memory circuit 700A of FIG. 7A.

Memory circuit 1304 has a height H6b in the second direction Y. In some embodiments, the height H6b is equal to the height H3b of memory circuit 700B of FIG. 7B.

Memory circuit 1304 has a width W6b in the first direction X. In some embodiments, the width W6b is equal to the width W3b of memory circuit 700B of FIG. 7B.

In some embodiments, the height H6a is different from the height H6b. In some embodiments, the height H6a is the same as the height H6b.

In some embodiments, the width W6a is different from the width W6b. In some embodiments, the width W6a is the same as the width W6b.

Memory circuit 1302 includes a memory cell 1302a, a memory cell 1302b, a set of bit lines BL4, a set of bit line bars BLB4 and a set of word lines WL4.

In some embodiments, memory cell 1302a is at least one of memory cell 701a, 701b, 701c or 701d in one of column 1 or 2, and memory cell 1302b is at least another of memory cell 701a, 701b, 701c or 701d in the other of column 1 or 2. For ease of illustration, memory circuit 1302 is shown as including 2 memory cells (memory cell 1302a and 1302b). However, other numbers of memory cells in memory circuit 1302 are within the scope of the present disclosure.

For ease of illustration, memory circuit 1302 is shown as including 2 columns of memory cells and 2 rows of memory cells. However, other numbers of rows or columns of memory cells in memory circuit 1302 are within the scope of the present disclosure.

Memory circuit 1304 includes a memory cell 1304a, a memory cell 1304b, a set of bit lines BL5, a set of bit line bars BLB5 and a set of word lines WL5.

In some embodiments, memory cell 1304a is at least one of memory cell 721a, 721b, 721c or 721d in one of column 1 or 2, and memory cell 1304b is at least another of memory cell 721a, 721b, 721c or 721d in the other of column 1 or 2. For ease of illustration, memory circuit 1304 is shown as including 2 memory cells (memory cell 1304a and 1304b). However, other numbers of memory cells in memory circuit 1304 are within the scope of the present disclosure.

For ease of illustration, memory circuit 1304 is shown as including 2 columns of memory cells and 2 rows of memory cells. However, other numbers of rows or columns of memory cells in memory circuit 1304 are within the scope of the present disclosure.

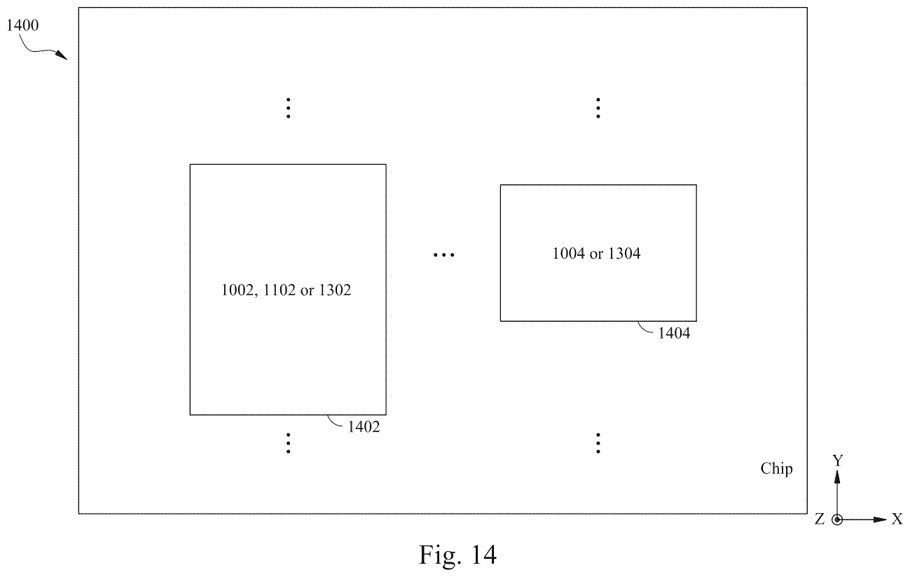

In some embodiments, the set of bit lines BL4 or BL5 of one or more of FIG. 13 or 14 are similar to the set of bit lines BL of FIGS. 7A-7B, 8 and 9, and similar detailed description is therefore omitted.

In some embodiments, the set of bit line bars BLB4 or BLB5 of one or more of FIG. 13 or 14 are similar to the set of bit line bars BLB of FIGS. 7A-7B, 8 and 9, and similar detailed description is therefore omitted.

In some embodiments, the set of word lines WL4 or WL5 of one or more of FIG. 13 or 14 are similar to the set of word lines WL of FIGS. 7A-7B, 8 and 9, and similar detailed description is therefore omitted.

The set of word lines WL4 has a length L4a in the second direction Y.

The set of bit lines BL4 and the set of bit line bars BLB4 have a length L4b in the first direction X.

In some embodiments, the length L4a of the set of word lines WL4 is greater than the length L4b of the set of bit lines BL4 and the length L4b of the set of bit line bars BLB4. In some embodiments, memory circuits such as memory circuit 1302 are referred to as “a tall cell” (and also has a “tall footprint”) since the length L4a of the set of word lines WL4 is greater than the length L4b of the set of bit lines BL4 and the length L4b of the set of bit line bars BLB4. In some embodiments, since the length L4a of the set of word lines WL4 is greater than the length L4b of the set of bit lines BL4 and the length L4b of the set of bit line bars BLB4, the set of word lines WL4 are referred to as “long.”

The set of word lines WL5 has a length L5a in the second direction Y.

The set of bit lines BL5 and the set of bit line bars BLB5 have a length L5b in the first direction X.

In some embodiments, the length L5a of the set of word lines WL5 is less than the length L5b of the set of bit lines BL5 and the length L5b of the set of bit line bars BLB5. In some embodiments, memory circuits such as memory circuit 1304 are referred to as “a long cell” (and also has a “long footprint”) since the length L5a of the set of word lines WL5 is less than the length L5b of the set of bit lines BL5 and the length L5b of the set of bit line bars BLB5. In some embodiments, since the length L5a of the set of word lines WL5 is less than the length L5b of the set of bit lines BL5 and the length L5b of the set of bit line bars BLB5, the set of bit lines BL5 or the set of bit line bars BLB5 are referred to as “long.”

In some embodiments, the length L4a of the set of word lines WL4 is greater than the length L5a of the set of word lines WL5.

In some embodiments, at least one of the length L4b of the set of bit lines BL4 or the length L4b of the set of bit line bars BLB4 is less than at least one of the length L5b of the set of bit lines BL5 or the length L5b of the set of bit line bars BLB5.

In some embodiments, memory circuit 1300 includes different memory circuits (e.g., memory circuit 1302 and memory circuit 1304) with different corresponding dimensions (e.g., tall cells and long cells) in the same direction, and therefore memory circuit 1300 is referred to as a “mixed cell arrangement.” In some embodiments, memory circuits (e.g., memory circuit 1302 and memory circuit 1304) with different corresponding dimensions in the same direction have different corresponding resistance and capacitance characteristics (e.g., as discussed above in Table 1). In some embodiments, the different characteristics of memory circuit 1300 includes one or more of a resistance of the bit line or bit line bar, a resistance of the word line, a capacitance of the bit line or bit line bar or a capacitance of the word line.

Memory circuit 1300 achieves one or more of the benefits discussed herein.

In some embodiments, a word line resistance (WL-R), a word line capacitance (WL-C), a bit line or bit line bar resistance (BL-R), a bit line or bit line bar capacitance (BL-C) of each of memory circuit 1302 (e.g., labelled as “2CPP”) and memory circuit 1304 (e.g., labelled as “Pseudo-4CPP”) are shown above in Table 1. In some embodiments, Table 1 is also a table of different cells and parameters of memory circuit 1302 (e.g., labelled as “2CPP”) and memory circuit 1304 (e.g., labelled as “Pseudo-4CPP”).

As shown in Table 1, memory circuit 1302 has similar characteristics as memory circuit 1102, and similar detailed description is therefore omitted.

As shown in Table 1, memory circuit 1304 has similar characteristics as memory circuit 1004, and similar detailed description is therefore omitted.

Other configurations of memory circuit 1300 are within the scope of the present disclosure.

FIG. 14 is a schematic diagram of a memory circuit 1400, in accordance with some embodiments.

Memory circuit 1400 is a variation of memory circuit 1000 of FIG. 10, memory circuit 1100 of FIG. 11, memory circuit 1200 of FIG. 12 and memory circuit 1300 of FIG. 13, and similar detailed description is therefore omitted. In comparison with memory circuit 1300 of FIG. 13, memory circuit 1302 of FIG. 13 is replaced by a memory circuit 1402 of FIG. 14, and memory circuit 1304 of FIG. 13 is replaced by a memory circuit 1404 of FIG. 14, and similar detailed description is therefore omitted.

Memory circuit 1400 includes memory circuit 1402 and memory circuit 1404.

Memory circuit 1400 is shown as including one memory circuit 1402 and one memory circuit 1404. In some embodiments, memory circuit 1400 includes at least two or more of memory circuit 1402. In some embodiments, memory circuit 1400 includes at least two or more of memory circuit 1404. Other positions in memory circuit 1400 for at least one of memory circuit 1402 or memory circuit 1404 are within the scope of the present disclosure.

In some embodiments, memory circuit 1402 is one of memory circuit 1002 of FIG. 10, memory circuit 1102 of FIG. 11 or memory circuit 1302 of FIG. 13, and memory circuit 1404 is one of memory circuit 1004 of FIG. 10 or memory circuit 1304 of FIG. 13, and similar detailed description is therefore omitted.

In some embodiments, at least one of height H5a, H5b, H5c, H6a or H6b is different from at least another of height H5a, H5b, H5c, H6a or H6b. In some embodiments, at least one of height H5a, H5b, H5c, H6a or H6b is the same as at least another of height H5a, H5b, H5c, H6a or H6b.

In some embodiments, at least one of width W5a, W5b, W5c, W6a or W6b is different from at least another of width W5a, W5b, W5c, W6a or W6b. In some embodiments, at least one of width W5a, W5b, W5c, W6a or W6b is the same as at least another of width W5a, W5b, W5c, W6a or W6b.

In some embodiments, at least one of length L1a, L2a, L3a, L4a or L5a is different from at least another of length L1a, L2a, L3a, L4a or L5a. In some embodiments, at least one of length L1a, L2a, L3a, L4a or L5a is the same as at least another of length L1a, L2a, L3a, L4a or L5a.

In some embodiments, at least one of length L1b, L2b, L3b, L4b or L5b is different from at least another of length L1b, L2b, L3b, L4b or L5b. In some embodiments, at least one of length L1b, L2b, L3b, L4b or L5b is the same as at least another of length L1b, L2b, L3b, L4b or L5b.

Memory circuit 1400 achieves one or more of the benefits discussed herein.

Other configurations of memory circuit 1400 are within the scope of the present disclosure.

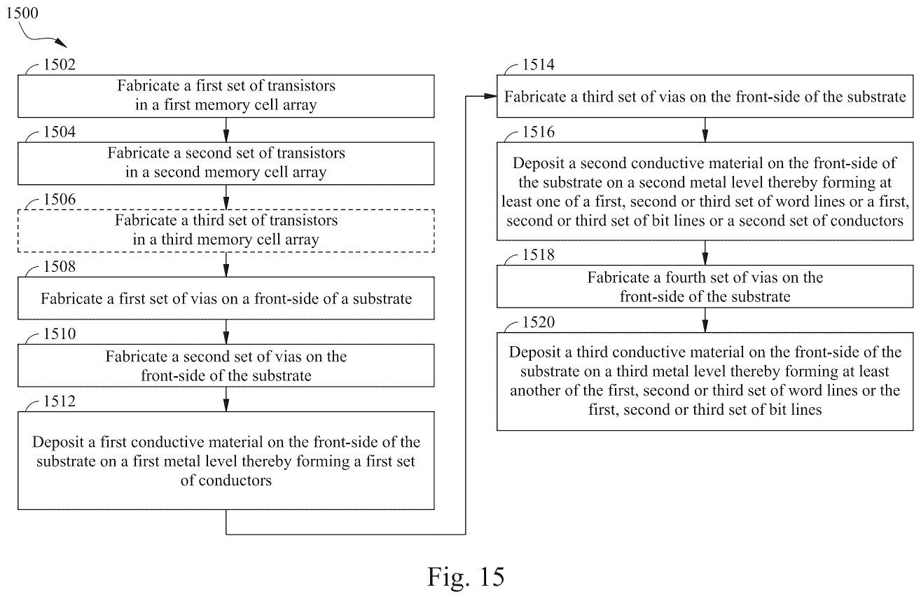

FIG. 15 is a functional flow chart of a method 1500 of manufacturing an IC device, in accordance with some embodiments. It is understood that additional operations may be performed before, during, and/or after the method 1500 depicted in FIG. 15, and that some other processes may only be briefly described herein.

In some embodiments, other order of operations of method 1500-1700 is within the scope of the present disclosure. Method 1500-1700 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 1500, 1600 or 1700 is not performed.

In some embodiments, method 1500 is an embodiment of operation 1604 of method 1600. In some embodiments, the methods 1500-1700 are usable to manufacture or fabricate at least memory circuit 100, 200A-200B, 400A-400C, 500A-500B, 600, 700A-700B, 800, 900, 1000, 1100, 1200, 1300 or 1400 or memory cells 300A-300B.

In operation 1502 of method 1500, a first set of transistors in a first memory cell array is fabricated. In some embodiments, the first memory cell array of method 1500 includes at least one of memory cell array 1002, 1102, 1302 or 1402. In some embodiments, the first memory cell array has a first width in the first direction X, and a first height in the second direction.

In some embodiments, the first width of method 1500 is at least one of width W5a, W5c or W6a. In some embodiments, the first height of method 1500 is at least one of height H5a, H5c or H6a.

In some embodiments, each memory cell in the first memory cell array includes a first set of transistors in the front-side 490a of the substrate 490. In some embodiments, the first set of transistors of method 1500 includes the transistors of at least one of memory cell array 1002, 1102, 1302 or 1402.

In some embodiments, the first set of transistors of method 1500 includes one or more transistors in at least the set of active regions 502, 602, 802 or 902.

In some embodiments, the first set of transistors includes a first number of transistors. In some embodiments, the first number of transistors of method 1500 is 6 or 8.

In operation 1504 of method 1500, a second set of transistors in a second memory cell array is fabricated. In some embodiments, the second memory cell array of method 1500 includes at least one of memory cell array 1004, 1304 or 1404. In some embodiments, the second memory cell array has a second width in the first direction X, and a second height in the second direction Y.

In some embodiments, the second width of method 1500 is at least one of width W5b or W6b.

In some embodiments, the second height of method 1500 is at least one of height H5b or H6b.

In some embodiments, each memory cell in the second memory cell array includes a second set of transistors in the front-side 490a of the substrate 490. In some embodiments, the second set of transistors of method 1500 includes the transistors of at least one of memory cell array 1002, 1102, 1302 or 1402.

In some embodiments, the second set of transistors of method 1500 includes one or more transistors in at least the set of active regions 502, 602, 802 or 902.

In some embodiments, the second set of transistors includes a second number of transistors.

In some embodiments, the second number of transistors of method 1500 is 6 or 8.

In some embodiments, the second set of transistors includes a second number of transistors.

In some embodiments, the second number of transistors of method 1500 is equal to the first number of transistors of method 1500. In some embodiments, the second number of transistors of method 1500 is different from the first number of transistors of method 1500.

In operation 1506 of method 1500, a third set of transistors in a third memory cell array is fabricated. In some embodiments, the third memory cell array of method 1500 includes at least one of memory cell array 1002, 1004, 1102, 1302, 1304, 1402 or 1404.

In some embodiments, the third memory cell array has a third width in the third direction X, and a third height in the third direction.

In some embodiments, the third width of method 1500 is at least one of width W5a, W5b, W5c, W6a or W6b. In some embodiments, the third height of method 1500 is at least one of height H5a, H5b, H5c, H6a or H6b.

In some embodiments, at least one of the first width, the second width or the third width is different from at least another of the first width, the second width or the third width.

In some embodiments, at least one of the first width, the second width or the third width is the same as at least another of the first width, the second width or the third width.

In some embodiments, at least one of the first height, the second height or the third height is different from at least another of the first height, the second height or the third height.

In some embodiments, at least one of the first height, the second height or the third height is the same as at least another of the first height, the second height or the third height.

In some embodiments, each memory cell in the third memory cell array includes a third set of transistors in the front-side 490a of the substrate 490. In some embodiments, the third set of transistors of method 1500 includes the transistors of at least one of memory cell array 1002, 1102, 1302 or 1402.

In some embodiments, the third set of transistors of method 1500 includes one or more transistors in at least the set of active regions 502, 602, 802 or 902.

In some embodiments, the third set of transistors includes a third number of transistors. In some embodiments, the third number of transistors of method 1500 is 6 or 8.

In some embodiments, the third number of transistors of method 1500 is equal to at least one of the first number of transistors of method 1500 or the second number of transistors of method 1500.

In some embodiments, the third number of transistors of method 1500 is different from at least one of the first number of transistors of method 1500 or the second number of transistors of method 1500.

In some embodiments, one or more of operations 1502, 1504 or 1506 are performed at the same time. In some embodiments, one or more portions of operations 1502, 1504 or 1506 are performed at the same time.

In some embodiments, at least one of operations 1502, 1504 or 1506 includes fabricating source and drain regions of the set of transistors in a first well. In some embodiments, the first well includes at least one of well 501a, 501b, 501c or 501d. In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (epi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material.

Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interacts with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, at least one of operations 1502, 1504 or 1506 further includes operation 1502a (not shown). In some embodiments, operation 1502a includes forming contacts of the first set of transistors, the second set of transistors or the third set of transistors. In some embodiments, the contacts includes at least one or more of contacts 506a, 506b, 506c or 506d.

In some embodiments, at least one of operations 1502, 1504 or 1506 further includes forming a gate region of the first set of transistors, the second set of transistors, the third set of transistors or the fourth set of transistors. In some embodiments, the gate regions of method 1500 include the set of gates 504, 604, 804 or 904.

In some embodiments, the gate region is between the drain region and the source region. In some embodiments, the gate region is over the first well and the substrate. In some embodiments, fabricating the gate regions of at least one of operations 1502, 1504 or 1506 includes performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers.

In some embodiments, fabricating the gate regions includes performing one or more deposition processes to form one or more conductive material layers. In some embodiments, fabricating the gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the gate regions include a metal, such as Al, Cu, W, Ti, Ta, TiN, TaN, NiSi, CoSi, other suitable conductive materials, or combinations thereof.

In operation 1508 of method 1500, a first set of vias are formed on the front-side 490a of the substrate 490. In some embodiments, the first set of vias of method 1500 includes at least one or more portions of at least the set of vias 514. In some embodiments, the first set of vias includes at least one or more vias in the VD level.

In some embodiments, operation 1508 and 1510 are performed in a same operation.

In some embodiments, the first set of vias is electrically coupled to at least one of the first set of transistors or the second set of transistors.

In some embodiments, the first set of vias is electrically coupled to at least one of the first set of transistors, the second set of transistors or the third set of transistors.

In some embodiments, operation 1508 includes forming a first set of self-aligned contacts (SACs) in the insulating layer over the front-side 490a of the substrate or wafer.

In operation 1510 of method 1500, a second set of vias are formed on the front-side 490a of the substrate 490. In some embodiments, the second set of vias of method 1500 includes at least one or more portions of at least the set of vias 512. In some embodiments, the second set of vias includes at least one or more vias in the VG level.

In some embodiments, the second set of vias is electrically coupled to at least one of the first set of transistors or the second set of transistors.

In some embodiments, the second set of vias is electrically coupled to at least one of the first set of transistors, the second set of transistors or the third set of transistors.

In some embodiments, operation 1510 includes forming a second set of SACs in the insulating layer over the front-side 490a of the substrate or wafer.

In operation 1512 of method 1500, a first conductive material is deposited on the front-side 490a of the substrate on a first metal level thereby forming a first set of conductors.

In some embodiments, the first set of conductors of method 1500 includes at least one conductor of the set of conductors 520.

In some embodiments, the first metal level of method 1500 includes at least one conductor of the M0 level. In some embodiments, the first metal level of method 1500 includes at least one conductor of the M1 level or the M2 level.

In some embodiments, the first set of conductors overlaps the first memory cell array, and extends in the first direction X.

In some embodiments, the first set of conductors is electrically coupled to the first set of transistors by the first set of vias or the second set of vias.

In some embodiments, the first set of conductors is electrically coupled to the second set of transistors by the first set of vias or the second set of vias.

In some embodiments, the first set of conductors is electrically coupled to the third set of transistors by the first set of vias or the second set of vias.

In operation 1514 of method 1500, a third set of vias are formed on the front-side 490a of the substrate 490. In some embodiments, the third set of vias of method 1500 includes at least one or more portions of at least the set of vias 402, 412, 422, 702, 722 or 522. In some embodiments, the third set of vias includes at least one or more vias in the V0 level.

In some embodiments, the third set of vias is electrically coupled to at least one of the first set of transistors, the second set of transistors or the third set of transistors by at least the first set of conductors.

In some embodiments, operation 1514 includes forming a third set of SACs in the insulating layer over the front-side 490a of the substrate or wafer.

In operation 1516 of method 1500, a second conductive material is deposited on the front-side 490a of the substrate on a second level thereby forming at least one of a first set of word lines, a second set of word lines or a third set of word lines or a second set of conductors.

In some embodiments, the first set of word lines of method 1500 includes at least one of the set of word lines WL1, WL3, WL4, WL, WWL or RWL.

In some embodiments, the second set of word lines of method 1500 includes at least one of the set of word lines WL2, WL5, WL, WWL or RWL.

In some embodiments, the third set of word lines of method 1500 includes at least one of the set of word lines WL1, WL2, WL3, WL4, WL5, WL, WWL or RWL.

In some embodiments, the second set of conductors of method 1500 includes the set of conductors 530.

In some embodiments, the second metal level of method 1500 includes the M1 level. In some embodiments, the second metal level of method 1500 includes at least one of the M0 level or the M2 level.

In some embodiments, the first set of word lines is electrically coupled to the first set of transistors by the second set of vias. In some embodiments, the first set of word lines overlaps the first memory cell array, and extends in the second direction Y.

In some embodiments, the second set of word lines is electrically coupled to the second set of transistors by the second set of vias. In some embodiments, the second set of word lines overlaps the second memory cell array, and extends in the second direction Y.

In some embodiments, the third set of word lines is electrically coupled to the third set of transistors by the second set of vias. In some embodiments, the third set of word lines overlaps the third memory cell array, and extends in the second direction Y.

In operation 1518 of method 1500, a fourth set of vias are formed on the front-side 490a of the substrate 490. In some embodiments, the fourth set of vias of method 1500 includes at least one or more portions of at least the set of vias 404, 414, 424, 704 or 724. In some embodiments, the fourth set of vias includes at least one or more vias in the V1 level.

In some embodiments, the fourth set of vias is electrically coupled to at least one of the first set of transistors, the second set of transistors or the third set of transistors by at least the first set of conductors or the second set of conductors.

In some embodiments, operation 1518 includes forming a fourth set of SACs in the insulating layer over the front-side 490a of the substrate or wafer.

In operation 1520 of method 1500, a third conductive material is deposited on the front-side 490a of the substrate on a third metal level thereby forming at least one of a first set of bit lines, a second set of bit lines or a third set of bit lines.

In some embodiments, the first set of bit lines of method 1500 includes at least one of the set of bit lines BL1, BLB1, BL3, BLB3, BL4, BLB4, BL, BLB or RBL.

In some embodiments, the second set of bit lines of method 1500 includes at least one of the set of bit lines BL2, BLB2, BL5, BLB5, BL, BLB or RBL.

In some embodiments, the third set of bit lines of method 1500 includes at least one of the set of bit lines BL1, BLB1, BL2, BLB2, BL3, BLB3, BL4, BLB4, BL5, BLB5, BL, BLB or RBL.

In some embodiments, the third metal level of method 1500 is different from the first metal level and the second metal level. In some embodiments, the third metal level of method 1500 includes the M2 level. In some embodiments, the third metal level of method 1500 includes at least one of the M0 level, the M1 level, the M3 level or M4 level.

In some embodiments, the first set of bit lines is electrically coupled to the first set of transistors by the first set of vias. In some embodiments, the first set of bit lines overlaps the first memory cell array, and extends in the first direction X.

In some embodiments, the second set of bit lines is electrically coupled to the second set of transistors by the first set of vias. In some embodiments, the second set of bit lines overlaps the second memory cell array, and extends in the first direction X.

In some embodiments, the third set of bit lines is electrically coupled to the third set of transistors by the first set of vias. In some embodiments, the third set of bit lines overlaps the third memory cell array, and extends in the first direction X.

In some embodiments, one or more of operations 1502, 1504, 1506, 1508, 1510, 1512, 1514, 1516, 1518 or 1520 of method 1500 include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

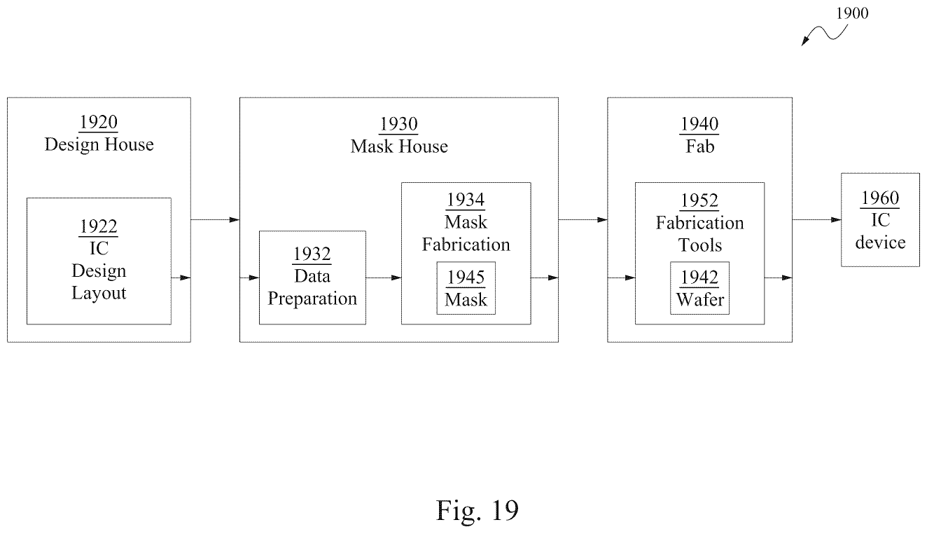

In some embodiments, at least one or more operations of method 1500 is performed by system 1900 of FIG. 19. In some embodiments, at least one method(s), such as method 1500 discussed above, is performed in whole or in part by at least one manufacturing system, including system 1900. One or more of the operations of method 1500 is performed by IC fab 1940 (FIG. 19) to fabricate IC device 1960. In some embodiments, one or more of the operations of method 1500 is performed by fabrication tools 1952 to fabricate wafer 1942.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 1508, 1510, 1512, 1514, 1516, 1518 or 1520, the conductive material is planarized to provide a level surface for subsequent steps.

In some embodiments, one or more of the operations of method 1500, 1600 or 1700 is not performed.

One or more of the operations of methods 1600-1700 is performed by a processing device configured to execute instructions for manufacturing an integrated circuit, such as at least memory circuit 100, 200A-200B, 400A-400C, 500A-500B, 600, 700A-700B, 800, 900, 1000, 1100, 1200, 1300 or 1400 or memory cells 300A-300B. In some embodiments, one or more operations of methods 1600-1700 is performed using a same processing device as that used in a different one or more operations of methods 1600-1700. In some embodiments, a different processing device is used to perform one or more operations of methods 1600-1700 from that used to perform a different one or more operations of methods 1600-1700. In some embodiments, other order of operations of method 1500, 1600 or 1700 is within the scope of the present disclosure. At least one of method 1500, 1600 or 1700 includes exemplary operations, but the operations are not necessarily performed in the order shown. Operations in method 1500, 1600 or 1700 may be added, replaced, changed order, and/or eliminated as appropriate, in accordance with the spirit and scope of disclosed embodiments.

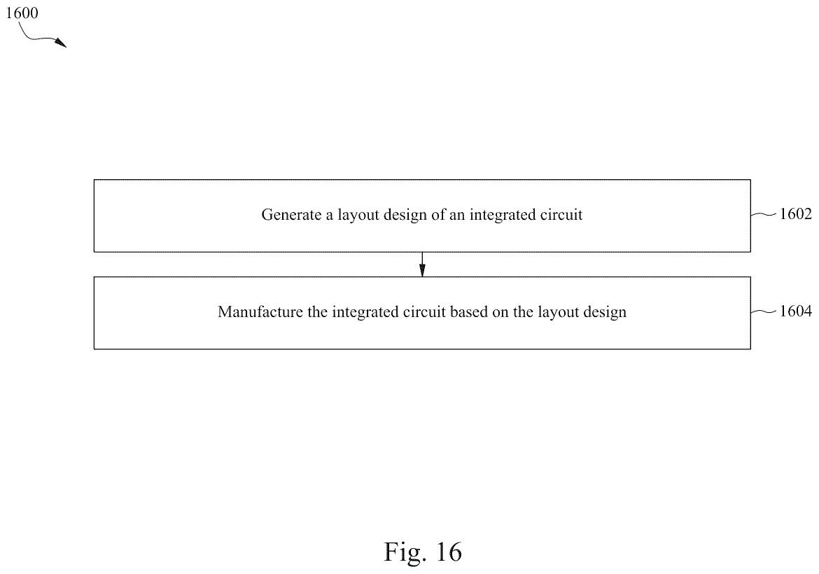

FIG. 16 is a flowchart of a method 1600 of forming or manufacturing an integrated circuit in accordance with some embodiments. It is understood that additional operations may be performed before, during, and/or after the method 1600 depicted in FIG. 16, and that some other operations may only be briefly described herein. In some embodiments, the method 1600 is usable to form integrated circuits, such as at least memory circuit 100, 200A-200B, 400A-400C, 500A-500B, 600, 700A-700B, 800, 900, 1000, 1100, 1200, 1300 or 1400 or memory cells 300A-300B.

In operation 1602 of method 1600, a layout design of an integrated circuit is generated.

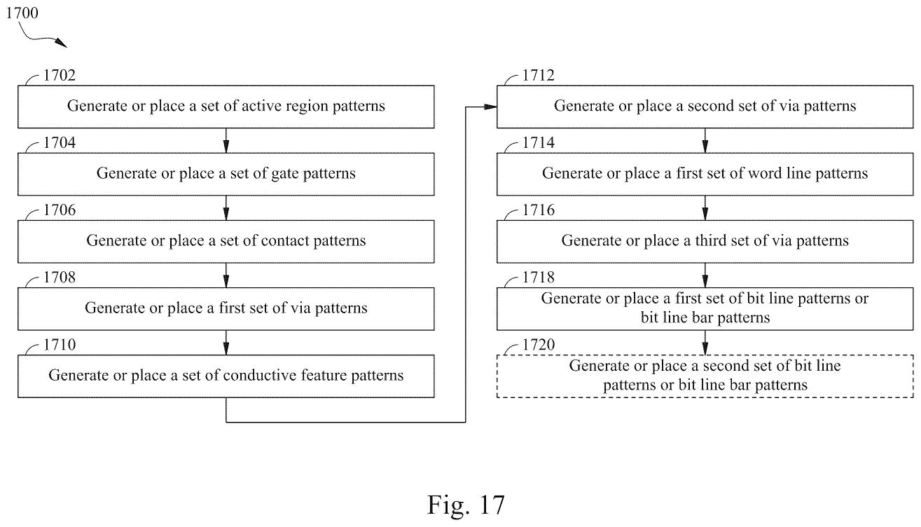

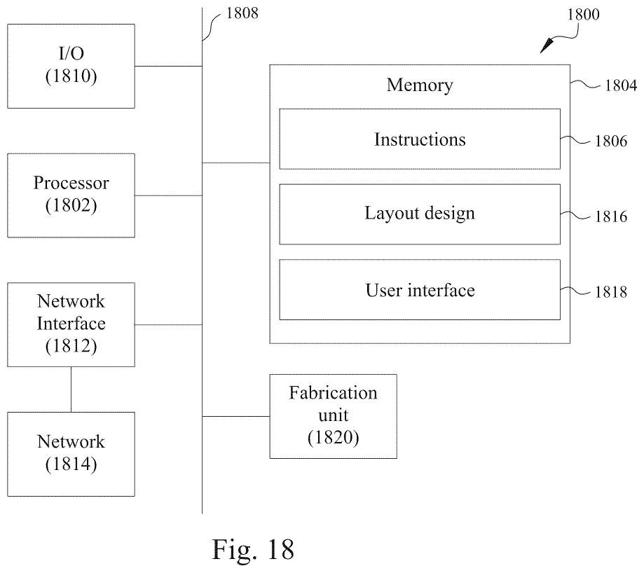

Operation 1602 is performed by a processing device (e.g., processor 1802 (FIG. 18)) configured to execute instructions for generating a layout design. In some embodiments, the layout design of method 1600 includes one or more layout patterns similar to one or more features of at least memory circuit 100, 200A-200B, 400A-400C, 500A-500B, 600, 700A-700B, 800, 900, 1000, 1100, 1200, 1300 or 1400 or memory cells 300A-300B. In some embodiments, the layout design of the present application is in a graphic database system (GDSII) file format. In some embodiments, operation 1602 corresponds to method 1700 of FIG. 17.

In operation 1604 of method 1600, the integrated circuit is manufactured based on the layout design. In some embodiments, operation 1604 of method 1600 comprises manufacturing at least one mask based on the layout design, and manufacturing the integrated circuit based on the at least one mask. In some embodiments, operation 1604 corresponds to method 1500 of FIG. 15.

FIG. 17 is a flowchart of a method 1700 of generating a layout design of an integrated circuit, in accordance with some embodiments. It is understood that additional operations may be performed before, during, and/or after the method 1700 depicted in FIG. 17, and that some other processes may only be briefly described herein. In some embodiments, method 1700 is an embodiment of operation 1602 of method 1600. In some embodiments, method 1700 is usable to generate one or more layout patterns similar to one or more features of at least memory circuit 100, 200A-200B, 400A-400C, 500A-500B, 600, 700A-700B, 800, 900, 1000, 1100, 1200, 1300 or 1400 or memory cells 300A-300B.

In some embodiments, method 1700 is usable to generate one or more layout patterns having structural relationships including alignment, lengths and widths, as well as configurations and layers similar to at least integrated circuit memory circuit 100, 200A-200B, 400A-400C, 500A-500B, 600, 700A-700B, 800, 900, 1000, 1100, 1200, 1300 or 1400 or memory cells 300A-300B, and similar detailed description will not be described in FIG. 17, for brevity.

In operation 1702 of method 1700, a set of active region patterns is generated or placed on the layout design. In some embodiments, the set of active region patterns of method 1700 includes one or more regions similar to the set of active regions 502, 602, 802 or 902. In some embodiments, the set of active region patterns of method 1700 includes one or more patterns similar to elements in the OD layer.

In operation 1704 of method 1700, a set of gate patterns is generated or placed on the layout design. In some embodiments, the set of gate patterns of method 1700 includes one or more regions similar to the set of gates 504, 604, 804 or 904. In some embodiments, the set of gate patterns of method 1700 includes at least portions of one or more patterns of the set of insulating patterns 394. In some embodiments, the set of gate patterns of method 1700 includes one or more patterns similar to elements in the POLY layer.

In operation 1706 of method 1700, a set of contact patterns is generated or placed on the layout design. In some embodiments, the set of contact patterns of method 1700 includes one or more regions similar to the set of contacts 506. In some embodiments, the set of contact patterns of method 1700 includes one or more patterns similar to elements in the MD layer.

In operation 1708 of method 1700, a first set of via patterns is generated or placed on the layout design. In some embodiments, the first set of via patterns of method 1700 includes one or more via patterns similar to at least the set of vias 512 or 514. In some embodiments, the first set of via patterns of method 1700 includes one or more patterns or vias similar to elements in the VD layer or the VG layer.

In operation 1710 of method 1700, a first set of conductive feature patterns is generated or placed on the layout design. In some embodiments, the first set of conductive feature patterns of method 1700 includes one or more regions similar to the set of conductors 520. In some embodiments, the first set of conductive feature patterns of method 1700 includes one or more patterns similar to elements in the M0 layer.

In operation 1712 of method 1700, a second set of via patterns is generated or placed on the layout design. In some embodiments, the second set of via patterns of method 1700 includes one or more via patterns similar to at least the set of vias 402, 412, 422, 702, 722 or 522. In some embodiments, the second set of via patterns of method 1700 includes one or more patterns or vias similar to elements in the V0 layer.

In operation 1714 of method 1700, a first set of word line patterns is generated or placed on the layout design. In some embodiments, the first set of word line patterns of method 1700 includes one or more patterns similar to the set of word lines WL, WL1, WL2, WL3, WL4, WL5, WWL or RWL. In some embodiments, the first set of word line patterns of method 1700 includes one or more patterns similar to elements in the POLY, M0 layer, M1 layer or the M2 layer. In some embodiments, operation 1714 further includes generating or placing a second set of conductive feature patterns on the layout design. In some embodiments, the second set of conductive feature patterns of method 1700 includes one or more regions similar to the set of conductors 530. In some embodiments, the second set of conductive feature patterns of method 1700 includes one or more patterns similar to elements in the M1 layer.

In operation 1716 of method 1700, a third set of via patterns is generated or placed on the layout design. In some embodiments, the third set of via patterns of method 1700 includes one or more via patterns similar to at least the set of vias 404, 414, 424, 704 or 724. In some embodiments, the third set of via patterns of method 1700 includes one or more patterns or vias similar to elements in the V1 layer.

In operation 1718 of method 1700, a first set of bit line patterns or a first set of bit line bar patterns is generated or placed on the layout design. In some embodiments, the first set of bit line patterns or the first set of bit line bar patterns of method 1700 includes one or more patterns similar to the set of bit lines or the set of bit line bars BL, BLB, BL1, BLB1, BL2, BLB2, BL3, BLB3, BL4, BLB4, BL5 or BLB5. In some embodiments, the second set of word line patterns of method 1700 includes one or more patterns similar to elements in the M0 layer, M1 layer or the M2 layer.

In operation 1720 of method 1700, a second set of bit line patterns or a second set of bit line bar patterns is generated or placed on the layout design. In some embodiments, the second set of bit line patterns or the second set of bit line bar patterns of method 1700 includes one or more patterns similar to the set of read bit lines RBL. In some embodiments, the second set of bit line patterns of method 1700 includes one or more patterns similar to elements in the M0 layer, M1 layer or the M2 layer.

FIG. 18 is a schematic view of a system 1800 for designing an IC layout design and manufacturing an IC circuit in accordance with some embodiments.

In some embodiments, system 1800 generates or places one or more IC layout designs described herein. System 1800 includes a hardware processor 1802 and a non-transitory, computer readable storage medium 1804 (e.g., memory 1804) encoded with, i.e., storing, the computer program code 1806, i.e., a set of executable instructions 1806. Computer readable storage medium 1804 is configured for interfacing with manufacturing machines for producing the integrated circuit. The processor 1802 is electrically coupled to the computer readable storage medium 1804 via a bus 1808. The processor 1802 is also electrically coupled to an I/O interface 1810 by bus 1808. A network interface 1812 is also electrically connected to the processor 1802 via bus 1808. Network interface 1812 is connected to a network 1814, so that processor 1802 and computer readable storage medium 1804 are capable of connecting to external elements via network 1814. The processor 1802 is configured to execute the computer program code 1806 (also referred to as “instructions” or “non-transitory instructions”) encoded in the computer readable storage medium 1804 in order to cause system 1800 to be usable for performing a portion or all of the operations as described in method 1600-1700.

In some embodiments, the processor 1802 is a central processing unit (CPU), a multi-processor, a distributed processing system, an application specific integrated circuit (ASIC), and/or a suitable processing unit.

In some embodiments, the computer readable storage medium 1804 is an electronic, magnetic, optical, electromagnetic, infrared, and/or a semiconductor system (or apparatus or device). For example, the computer readable storage medium 1804 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1804 includes a compact disk-read only memory (CD-ROM), a compact disk-read/write (CD-R/W), and/or a digital video disc (DVD).

In some embodiments, the computer readable storage medium 1804 stores the computer program code 1806 configured to cause system 1800 to perform method 1600-1700. In some embodiments, the computer readable storage medium 1804 also stores information needed for performing method 1600-1700 as well as information generated during performing method 1600-1700, such as layout design 1816, user interface 1818 and fabrication unit 1820, and/or a set of executable instructions to perform the operation of method 1600-1700. In some embodiments, layout design 1816 comprises one or more layout patterns similar to one or more features of at least memory circuit 100, 200A-200B, 400A-400C, 500A-500B, 600, 700A-700B, 800, 900, 1000, 1100, 1200, 1300 or 1400 or memory cells 300A-300B.

In some embodiments, the computer readable storage medium 1804 stores instructions (e.g., computer program code 1806) for interfacing with manufacturing machines. The instructions (e.g., computer program code 1806) enable processor 1802 to generate manufacturing instructions readable by the manufacturing machines to effectively implement method 1600-1700 during a manufacturing process.

System 1800 includes I/O interface 1810. I/O interface 1810 is coupled to external circuitry. In some embodiments, I/O interface 1810 includes a keyboard, keypad, mouse, trackball, trackpad, and/or cursor direction keys for communicating information and commands to processor 1802.

System 1800 also includes network interface 1812 coupled to the processor 1802. Network interface 1812 allows system 1800 to communicate with network 1814, to which one or more other computer systems are connected. Network interface 1812 includes wireless network interfaces such as BLUETOOTH, WIFI, WIMAX, GPRS, or WCDMA; or wired network interface such as ETHERNET, USB, or IEEE-2094. In some embodiments, method 1600-1700 is implemented in two or more systems 1800, and information such as layout design, and user interface are exchanged between different systems 1800 by network 1814.

System 1800 is configured to receive information related to a layout design through I/O interface 1810 or network interface 1812. The information is transferred to processor 1802 by bus 1808 to determine a layout design for producing at least memory circuit 100, 200A-200B, 400A-400C, 500A-500B, 600, 700A-700B, 800, 900, 1000, 1100, 1200, 1300 or 1400 or memory cells 300A-300B. The layout design is then stored in computer readable storage medium 1804 as layout design 1816. System 1800 is configured to receive information related to a user interface through I/O interface 1810 or network interface 1812. The information is stored in computer readable storage medium 1804 as user interface 1818. System 1800 is configured to receive information related to a fabrication unit 1820 through I/O interface 1810 or network interface 1812. The information is stored in computer readable storage medium 1804 as fabrication unit 1820. In some embodiments, the fabrication unit 1820 includes fabrication information utilized by system 1800. In some embodiments, the fabrication unit 1820 corresponds to mask fabrication 1934 of FIG. 19.

In some embodiments, method 1600-1700 is implemented as a standalone software application for execution by a processor. In some embodiments, method 1600-1700 is implemented as a software application that is a part of an additional software application. In some embodiments, method 1600-1700 is implemented as a plug-in to a software application. In some embodiments, method 1600-1700 is implemented as a software application that is a portion of an EDA tool. In some embodiments, method 1600-1700 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 1600-1700 is implemented by a manufacturing device to manufacture an integrated circuit using a set of masks manufactured based on one or more layout designs generated by system 1800. In some embodiments, system 1800 is a manufacturing device configured to manufacture an integrated circuit using a set of masks manufactured based on one or more layout designs of the present disclosure. In some embodiments, system 1800 of FIG. 18 generates layout designs of an integrated circuit that are smaller than other approaches. In some embodiments, system 1800 of FIG. 18 generates layout designs of integrated circuit structure that occupy less area and provide better routing resources than other approaches.

FIG. 19 is a block diagram of an integrated circuit (IC) manufacturing system 1900, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1900.

In FIG. 19, IC manufacturing system 1900 (hereinafter “system 1900”) includes entities, such as a design house 1920, a mask house 1930, and an IC manufacturer/fabricator (“fab”) 1940, that interact with one another in the design, development, and manufacturing cycles and/or services related to manufacturing an IC device 1960. The entities in system 1900 are connected by a communications network. In some embodiments, the communications network is a single network. In some embodiments, the communications network is a variety of different networks, such as an intranet and the Internet. The communications network includes wired and/or wireless communication channels.

Each entity interacts with one or more of the other entities and provides services to and/or receives services from one or more of the other entities. In some embodiments, one or more of design house 1920, mask house 1930, and IC fab 1940 is owned by a single larger company. In some embodiments, one or more of design house 1920, mask house 1930, and IC fab 1940 coexist in a common facility and use common resources.

Design house (or design team) 1920 generates an IC design layout 1922. IC design layout 1922 includes various geometrical patterns designed for an IC device 1960. The geometrical patterns correspond to patterns of metal, oxide, or semiconductor layers that make up the various components of IC device 1960 to be fabricated. The various layers combine to form various IC features. For example, a portion of IC design layout 1922 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1920 implements a proper design procedure to form IC design layout 1922. The design procedure includes one or more of logic design, physical design or place and route. IC design layout 1922 is presented in one or more data files having information of the geometrical patterns. For example, IC design layout 1922 can be expressed in a GDSII file format or DFII file format.

Mask house 1930 includes data preparation 1932 and mask fabrication 1934. Mask house 1930 uses IC design layout 1922 to manufacture one or more masks 1945 to be used for fabricating the various layers of IC device 1960 according to IC design layout 1922. Mask house 1930 performs mask data preparation 1932, where IC design layout 1922 is translated into a representative data file (RDF).

Mask data preparation 1932 provides the RDF to mask fabrication 1934. Mask fabrication 1934 includes a mask writer. A mask writer converts the RDF to an image on a substrate, such as a mask (reticle) 1945 or a semiconductor wafer 1942 (also referred to as “wafer 1942”). The IC design layout 1922 is manipulated by mask data preparation 1932 (also referred to as “data preparation 1932”) to comply with particular characteristics of the mask writer and/or requirements of IC fab 1940. In FIG. 19, mask data preparation 1932 and mask fabrication 1934 are illustrated as separate elements. In some embodiments, mask data preparation 1932 and mask fabrication 1934 can be collectively referred to as mask data preparation.

In some embodiments, mask data preparation 1932 includes optical proximity correction (OPC) which uses lithography enhancement techniques to compensate for image errors, such as those that can arise from diffraction, interference, other process effects and the like. OPC adjusts IC design layout 1922. In some embodiments, mask data preparation 1932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1934, which may undo part of the modifications performed by OPC in order to meet mask creation rules.

In some embodiments, mask data preparation 1932 includes lithography process checking (LPC) that simulates processing that will be implemented by IC fab 1940 to fabricate IC device 1960. LPC simulates this processing based on IC design layout 1922 to create a simulated manufactured device, such as IC device 1960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1922.

It should be understood that the above description of mask data preparation 1932 has been simplified for the purposes of clarity. In some embodiments, data preparation 1932 includes additional features such as a logic operation (LOP) to modify the IC design layout according to manufacturing rules. Additionally, the processes applied to IC design layout 1922 during data preparation 1932 may be executed in a variety of different orders.

After mask data preparation 1932 and during mask fabrication 1934, a mask 1945 or a group of masks 1945 are fabricated based on the modified IC design layout 1922. In some embodiments, mask fabrication 1934 includes performing one or more lithographic exposures based on IC design layout 1922. In some embodiments, an electron-beam (e-beam) or a mechanism of multiple e-beams is used to form a pattern on a mask (photomask or reticle) 1945 based on the modified IC design layout 1922. The mask 1945 can be formed in various technologies. In some embodiments, the mask 1945 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1945 includes a transparent substrate (e.g., fused quartz) and an opaque material (e.g., chromium) coated in the opaque regions of the binary mask. In another example, the mask 1945 is formed using a phase shift technology. In the phase shift mask (PSM) version of mask 1945, various features in the pattern formed on the mask are configured to have proper phase difference to enhance the resolution and imaging quality. In various examples, the phase shift mask can be attenuated PSM or alternating PSM. The mask(s) generated by mask fabrication 1934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1940 is an IC fabrication entity that includes one or more manufacturing facilities for the fabrication of a variety of different IC products. In some embodiments, IC Fab 1940 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1940 includes wafer fabrication tools 1952 (hereinafter “fabrication tools 1952”) configured to execute various manufacturing operations on semiconductor wafer 1942 such that IC device 1960 is fabricated in accordance with the mask(s), e.g., mask 1945. In various embodiments, fabrication tools 1952 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1940 uses mask(s) 1945 fabricated by mask house 1930 to fabricate IC device 1960. Thus, IC fab 1940 at least indirectly uses IC design layout 1922 to fabricate IC device 1960. In some embodiments, a semiconductor wafer 1942 is fabricated by IC fab 1940 using mask(s) 1945 to form IC device 1960. In some embodiments, the IC fabrication includes performing one or more lithographic exposures based at least indirectly on IC design layout 1922. Semiconductor wafer 1942 includes a silicon substrate or other proper substrate having material layers formed thereon. Semiconductor wafer 1942 further includes one or more of various doped regions, dielectric features, multilevel interconnects, and the like (formed at subsequent manufacturing steps).

System 1900 is shown as having design house 1920, mask house 1930 or IC fab 1940 as separate components or entities. However, it is understood that one or more of design house 1920, mask house 1930 or IC fab 1940 are part of the same component or entity.

One aspect of this description relates to an integrated circuit chip. In some embodiments, the integrated circuit chip includes a first memory cell array having a first width in a first direction and a first height in a second direction different from the first direction, each memory cell in the first memory cell array includes a first number of transistors. In some embodiments, the integrated circuit chip further includes a second memory cell array having a second width in the first direction and a second height in the second direction, each memory cell in the second memory cell array includes the first number of transistors. In some embodiments, the integrated circuit chip further includes a first bit line extending in the first direction, being coupled to the first memory cell array, overlapping the first memory cell array, and being on a first metal layer, the first metal layer being above a front-side of a substrate. In some embodiments, the integrated circuit chip further includes a second bit line extending in the first direction, being coupled to the second memory cell array, overlapping the second memory cell array, and being on the first metal layer. In some embodiments, at least the first width is different from the second width, or the first height is different from the second height.

Another aspect of this description relates to an integrated circuit chip. In some embodiments, the integrated circuit chip includes a first memory cell array having a first width in a first direction and a first height in a second direction different from the first direction.

In some embodiments, the integrated circuit chip further includes a second memory cell array having a second width in the first direction and a second height in the second direction. In some embodiments, the integrated circuit chip further includes a third memory cell array having a third width in the first direction and a third height in the second direction. In some embodiments, the integrated circuit chip further includes a first bit line extending in the first direction, being coupled to the first memory cell array, overlapping the first memory cell array, and being on a first metal layer, the first metal layer being above a front-side of a substrate. In some embodiments, the integrated circuit chip further includes a second bit line extending in the first direction, being coupled to the second memory cell array, overlapping the second memory cell array, and being on the first metal layer. In some embodiments, the integrated circuit chip further includes a third bit line extending in the first direction, being coupled to the third memory cell array, overlapping the third memory cell array, and being on the first metal layer. In some embodiments, at least the second width is different from the first width or the third width, or the second height is different from the first height or the third height.

Still another aspect of this description relates to a method of fabricating an integrated circuit chip. In some embodiments, the method includes fabricating a first set of memory cells in a first memory cell array, the first memory cell array having a first width in a first direction and a first height in a second direction different from the first direction, each memory cell in the first memory cell array including a first set of transistors in a front-side of a substrate, the first set of transistors including a first number of transistors. In some embodiments, the method further includes fabricating a second set of memory cells in a second memory cell array, the second memory cell array having a second width in the first direction and a second height in the second direction, each memory cell in the second memory cell array including a second set of transistors in the front-side of the substrate, the second set of transistors including a second number of transistors. In some embodiments, the method further includes fabricating a third set of memory cells in a third memory cell array, the third memory cell array having a third width in the first direction and a third height in the second direction, each memory cell in the third memory cell array including a third set of transistors in the front-side of the substrate, the third set of transistors including the first number of transistors or the second number of transistors.

In some embodiments, the method further includes fabricating a first set of vias and a second set of vias on the front-side of the substrate, the first set of vias and the second set of vias being electrically coupled to at least the first set of transistors, the second set of transistors or the third set of transistors. In some embodiments, the method further includes depositing a first conductive material on the front-side of the substrate on a first metal level thereby forming a first set of word lines, a second set of word lines and a third set of word lines, the first set of word lines being electrically coupled to the first set of transistors by the second set of vias, overlapping the first memory cell array, and extending in the second direction, the second set of word lines being electrically coupled to the second set of transistors by the second set of vias, overlapping the second memory cell array, and extending in the second direction. In some embodiments, the method further includes fabricating a third set of vias on the front-side of the substrate, the third set of vias being electrically coupled to at least the first set of transistors, the second set of transistors or the third set of transistors. In some embodiments, the method further includes depositing a second conductive material on the front-side of the substrate on a second metal level thereby forming a first set of bit lines, a second set of bit lines and a third set of bit lines, the first set of bit lines being electrically coupled to the first set of transistors by the first set of vias and the third set of vias, overlapping the first memory cell array, and extending in the first direction, the second set of bit lines being electrically coupled to the second set of transistors by the first set of vias and the third set of vias, overlapping the second memory cell array, and extending in the first direction, the second metal level being different from the first metal level. In some embodiments, at least the second width is different from the first width or the third width, or the second height is different from the first height or the third height.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit chip, comprising:
a first memory cell array having a first width in a first direction and a first height in a second direction different from the first direction, each memory cell in the first memory cell array includes a first number of transistors;
a second memory cell array having a second width in the first direction and a second height in the second direction, each memory cell in the second memory cell array includes the first number of transistors;
a first bit line extending in the first direction, being coupled to the first memory cell array, overlapping the first memory cell array, and being on a first metal layer, the first metal layer being above a front-side of a substrate; and
a second bit line extending in the first direction, being coupled to the second memory cell array, overlapping the second memory cell array, and being on the first metal layer, wherein at least the first width is different from the second width, or the first height is different from the second height.

2. The integrated circuit chip of claim 1, further comprising:
a first set of word lines extending in the second direction, being coupled to the first memory cell array, overlapping the first memory cell array, and being on a second metal layer different from the first metal layer; and
a second set of word lines extending in the second direction, being coupled to the second memory cell array, overlapping the second memory cell array, and being on the second metal layer.

3. The integrated circuit chip of claim 2, wherein
the first bit line has a first length in the first direction;
the first set of word lines have a second length in the second direction;
the second bit line has a third length in the first direction; and
the second set of word lines have a fourth length in the second direction.

4. The integrated circuit chip of claim 3, wherein at least one of
the first length is less than the second length, or
the third length is greater than the fourth length.

5. The integrated circuit chip of claim 3, wherein at least one of
the first length is less than the third length, or
the second length is greater than the fourth length.

6. The integrated circuit chip of claim 2, wherein
the second memory cell array comprises a first set of rows of memory cells extending in the first direction, and a first set of columns of memory cells extending in the second direction; and
the second set of word lines comprises:
a first word line of the second set of word lines overlaps each memory cell in a first column of the first set of columns of memory cells; and
a second word line of the second set of word lines overlaps each memory cell in the first column of the first set of columns of memory cells, the second word line is adjacent to the first word line; and
the first word line and the second word line are electrically coupled to interleaved memory cells in the first column of the first set of columns of memory cells.

7. The integrated circuit chip of claim 6, wherein the first set of rows of memory cells comprises:
a first row including a first memory cell;
a second row including a second memory cell;
a third row including a third memory cell; and
a fourth row including a fourth memory cell.

8. The integrated circuit chip of claim 7, wherein the first set of rows of memory cells is in the first column of the first set of columns of memory cells.

9. The integrated circuit chip of claim 1, wherein
each memory cell in the first memory cell array is a six transistor (6T) memory cell; and
each memory cell in the second memory cell array is a 6T memory cell.

10. The integrated circuit chip of claim 8, wherein
the second bit line is shared with neighboring rows of memory cells in the second memory cell array.

11. An integrated circuit chip, comprising:
a first memory cell array having a first width in a first direction and a first height in a second direction different from the first direction;
a second memory cell array having a second width in the first direction and a second height in the second direction;
a third memory cell array having a third width in the first direction and a third height in the second direction;
a first bit line extending in the first direction, being coupled to the first memory cell array, overlapping the first memory cell array, and being on a first metal layer, the first metal layer being above a front-side of a substrate;
a second bit line extending in the first direction, being coupled to the second memory cell array, overlapping the second memory cell array, and being on the first metal layer; and
a third bit line extending in the first direction, being coupled to the third memory cell array, overlapping the third memory cell array, and being on the first metal layer,
wherein at least the second width is different from the first width or the third width, or the second height is different from the first height or the third height.

12. The integrated circuit chip of claim 11, further comprising:
a first set of word lines extending in the second direction, being coupled to the first memory cell array, overlapping the first memory cell array, and being on a second metal layer different from the first metal layer;
a second set of word lines extending in the second direction, being coupled to the second memory cell array, overlapping the second memory cell array, and being on the second metal layer; and
a third set of word lines extending in the second direction, being coupled to the third memory cell array, overlapping the third memory cell array, and being on the second metal layer.

13. The integrated circuit chip of claim 12, wherein
the first bit line has a first length in the first direction;
the first set of word lines have a second length in the second direction;
the second bit line has a third length in the first direction;
the second set of word lines have a fourth length in the second direction.
the third bit line has a fifth length in the first direction; and
the third set of word lines have a sixth length in the second direction.

14. The integrated circuit chip of claim 13, wherein at least one of
the first length is less than the second length,
the third length is greater than the fourth length, or
the fifth length is less than the sixth length.

15. The integrated circuit chip of claim 13, wherein at least one of
the first length is less than at least one of the third length or the fifth length, or
the second length is greater than at least one of the fourth length or the sixth length.

16. The integrated circuit chip of claim 12, wherein
the second memory cell array comprises a first set of rows of memory cells extending in the first direction, and a first set of columns of memory cells extending in the second direction; and
the second set of word lines comprises:
a first word line of the second set of word lines overlaps each memory cell in a first column of the first set of columns of memory cells; and
a second word line of the second set of word lines overlaps each memory cell in the first column of the first set of columns of memory cells, the second word line is adjacent to the first word line; and
the first word line and the second word line are electrically coupled to interleaved memory cells in the first column of the first set of columns of memory cells.

17. The integrated circuit chip of claim 16, wherein the first set of rows of memory cells comprises:
a first row including a first memory cell;
a second row including a second memory cell;
a third row including a third memory cell; and
a fourth row including a fourth memory cell.
wherein the first set of rows of memory cells is in the first column of the first set of columns of memory cells;
the first word line is coupled to the first memory cell and the third memory cell; and
the second word line is coupled to the second memory cell and the fourth memory cell.

18. The integrated circuit chip of claim 16, wherein
the second memory cell array comprises a second set of rows of memory cells extending in the first direction, and a second set of columns of memory cells extending in the second direction; and
the first set of word lines comprises:
a third word line of the first set of word lines overlaps each memory cell in a second column of the second set of columns of memory cells; and
a fourth word line of the first set of word lines overlaps each memory cell in the second column of the second set of columns of memory cells, the fourth word line is adjacent to the third word line; and
the third word line and the fourth word line are electrically coupled to interleaved memory cells in the second column of the second set of columns of memory cells.

19. The integrated circuit chip of claim 18, wherein
the third memory cell array comprises a third set of rows of memory cells extending in the first direction, and a third set of columns of memory cells extending in the second direction; and
each word line of the third set of word lines overlaps and is electrically connected to each memory cell in a corresponding column of the third set of columns of memory cells.

20. A method of fabricating an integrated circuit chip, the method comprising:
fabricating a first set of memory cells in a first memory cell array, the first memory cell array having a first width in a first direction and a first height in a second direction different from the first direction, each memory cell in the first memory cell array including a first set of transistors in a front-side of a substrate, the first set of transistors including a first number of transistors;
fabricating a second set of memory cells in a second memory cell array, the second memory cell array having a second width in the first direction and a second height in the second direction, each memory cell in the second memory cell array including a second set of transistors in the front-side of the substrate, the second set of transistors including a second number of transistors;
fabricating a third set of memory cells in a third memory cell array, the third memory cell array having a third width in the first direction and a third height in the second direction, each memory cell in the third memory cell array including a third set of transistors in the front-side of the substrate, the third set of transistors including the first number of transistors or the second number of transistors;
fabricating a first set of vias and a second set of vias on the front-side of the substrate, the first set of vias and the second set of vias being electrically coupled to at least the first set of transistors, the second set of transistors or the third set of transistors;
depositing a first conductive material on the front-side of the substrate on a first metal level thereby forming a first set of word lines, a second set of word lines and a third set of word lines, the first set of word lines being electrically coupled to the first set of transistors by the second set of vias, overlapping the first memory cell array, and extending in the second direction, the second set of word lines being electrically coupled to the second set of transistors by the second set of vias, overlapping the second memory cell array, and extending in the second direction;
fabricating a third set of vias on the front-side of the substrate, the third set of vias being electrically coupled to at least the first set of transistors, the second set of transistors or the third set of transistors; and
depositing a second conductive material on the front-side of the substrate on a second metal level thereby forming a first set of bit lines, a second set of bit lines and a third set of bit lines, the first set of bit lines being electrically coupled to the first set of transistors by the first set of vias and the third set of vias, overlapping the first memory cell array, and extending in the first direction, the second set of bit lines being electrically coupled to the second set of transistors by the first set of vias and the third set of vias, overlapping the second memory cell array, and extending in the first direction, the second metal level being different from the first metal level,
wherein at least the second width is different from the first width or the third width, or the second height is different from the first height or the third height.
